(19) United States
(12) Patent Application Publication
(10) Pub. No.: US 2008/0106335 A1
(43) Pub. Date: May 8, 2008

(54) Differential circuit

(75) Inventor: Katsuji Kimura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/905,483

(22) Filed: Oct. 1, 2007

(30) Foreign Application Priority Data
Oct. 2, 2006 (JP) 2006-270690

(51) Int. Cl. H03F 3/45; G06G 7/12

(52) U.S. Cl. 330/253; 327/563

(57) ABSTRACT

Disclosed is a differential circuit including a first transistor pair including first and second transistors having gates for receiving a differential input signal; a second transistor pair including third and fourth transistors having gates for commonly receiving a common mode voltage of the differential input signal, having drains connected to drains of said first and second transistors, respectively, and having sources coupled together; a third transistor pair including fifth and sixth transistors having gates for receiving the differential input signal, and cascode-connected to said third and fourth transistors, respectively; and a fourth transistor pair including seventh and eighth transistors having gates for receiving the differential input signal in reverse phase, and cascode-connected to said fifth and sixth transistors, respectively; wherein coupled drains of the first and third transistors and coupled drains of the second and fourth transistors constitute a differential output pair; and sources of said first, second, seventh and eighth transistors are coupled together and driven by a constant current source.

### REFERENCE TO RELATED APPLICATION

This application is based upon and claims the benefit of the priority of Japanese patent application No. 2006-270690, filed on Oct. 2, 2006, the disclosure of which is incorporated herein in its entirety by reference thereto.

### FIELD OF THE INVENTION

This invention relates to a differential circuit and, more particularly, to a differential circuit with high linearity that is suited to be formed on a semiconductor integrated circuit.

### BACKGROUND OF THE INVENTION

[Patent Document 1]

JP Patent Kokai Publication No. JP-P2002-084145A

[Patent Document 2]

FIG. 3 of U.S. Pat. No. 6,557,170 (U.S. Pat. No. 6,577,170 B1, Jun. 10, 2003)

[Patent Document 3]

FIG. 7 of JP Patent Kokoku Publication No. JP-B-8-8457

[Patent Document 4]

JP Patent Kokai Publication No. JP-P2004-297631A

[Patent Document 5]

JP Patent Kokai Publication No. JP-P2005-328272A

[Non-Patent Document 1]

C. S. Kim, Y. H. Kim and S. B. Park, “New CMOS Linear Transconductor”, IEE Electronics Letters 8 Oct. 1992 Vol. 28 No. 21 pp. 1962-1964

[Non-Patent Document 2]

F. Krummenacher and N. Joehl, “A 4-MHz CMOS Continuous-Time Filter with On-Chip Automatic Tuning” IEEE J. Solid-State Circuits Vol. 23 No. 3 pp. 750-758, June 1988

The CMOS process has been miniaturized further and the frequency response of a MOS transistor has significantly been improved. The clock frequency of a desktop personal computer has now exceeded 3 GHz. The clock frequency of a notebook personal computer is not increased beyond the range of 1 to 2 GHz in consideration of the battery's durability.

The radio frequency of a mobile phone terminal, owned by everybody today, is not higher than 0.8 GHz to 2 GHz, meaning that the RF frequency order has now been reversed. The clock frequency of the Intel's Pentium (registered trade mark) processor exceeded 0.8 GHz, the radio frequency of an analog mobile phone, in 2000, that is, at the end of the twentieth century.

Nowadays, a wireless unit chip of a mobile phone and a wireless chip for 2.4 to 5 GHz wireless LAN are manufactured as LSI, based on the CMOS process, and are each supplied as one chip.

For such wireless unit chip for the mobile phone or the wireless LAN, multi-band wireless unit chips, adapted to cope with the radio frequency bands, allocated thereto, are routinely supplied, or are configured to cope with a variety of wireless systems, GSM, W-CDMA, CDMA2000 or IEEE802a, b or g, for instance.

In particular, with the band-selecting filter, mounted on-chip, it is necessary to change over frequency band, depending on the difference in the wireless systems.

The band-selecting filter unavoidably is subjected to variations, due to fabrication process, and hence needs to be tuned to obtain the desired frequency bandwidth with high accuracy.

As a method for constructing a filter, adapted to respond to these needs, a gm-C filter, employing a capacitance C and transconductance gm of an OTA, is thought to be the best solution. However,

(I) linearity of the OTA,

(II) a control method for controlling a common mode voltage in a differential circuit configuration, or

(III) a tuning method with high accuracy cannot be attained in design process. An overview of theses or Patent Documents by Broadcom, Atheros, Intel or Qualcom, that are vendors of these wireless unit chips, indicates that they apparently abandoned gm-C filters and are directing their efforts principally RC active filters.

It appears that, today, universities or organizations that are not vendors of wireless unit chips are conducting small-sized researches with an aim to practical application of the gm-C chips.

The present inventors have so far proposed

(II) a control method for controlling a common mode voltage for a differential configuration, and

(III) a method satisfactory as a high-accuracy tuning method.

As for (II) and (III), reference may be made to JP Patent Kokai Publication No. JP-P2004-297631A and JP Patent Kokai Publication No. JP-P2005-328272A, respectively.

As regards (I), our efforts for these twenty and odd years have failed to arrive at any satisfactory methods.

However, we have now arrived at a satisfactory method, which is to be the theme of the present specification.

The following three methods have so far been known for implementing an OTA circuit.

(1) a method employing a floating resistor;

(2) a method that, through analysis of a first-order approximation model of a MOS transistor, yields an input voltage range providing for a linear operation; and

(3) a method that yields, through analysis of a first-order approximation model of a MOS transistor, an input voltage range close to a linear operation, as an approximate solution.

An OTA circuit employing the floating resistor according to the method (I) may be exemplified by an OTA circuit in which the Caprio's quad (Raimond Caprio, “Precision Differential Voltage-To-Current Convertor”, IEE Electronics Letters 22 Mar. 1973 Vol. 9 No. 6 pp. 147-148) is replaced by MOS transistors.

The Caprio's quad is so called because the circuit includes four transistors in which there is a cross-coupled connection. For this reason, the Caprio's MOS-quad tends to become unstable in operation in case the impedance of the two transistors has a value of R and the source side includes some reactance component.

On the other hand, a high power supply voltage is needed due to cascoded or vertically stacked transistors. If the low power supply voltage is used for the operation, it becomes difficult to secure a desired linear operating input voltage range. Hence, the circuit is now used only on extremely rare occasions.

Afterwards, two circuits, shown in FIGS. 1A and 1B, have become known.

The circuit shown in FIG. 1(a) has been known from rather old times. The first inventors seem to be Marco Siligoni and Pietro Consislio who used bipolar transistors in a circuit topology of FIG. 1A (‘High Precision Voltage-Current Converter for Low Voltage’ in JP Patent Kokai Publication No. JP-A-59-181710) and Marco Siligoni and Pietro Consislio, ‘High Precision Voltage-to-Current Converter, Particularly for Low Supply Voltages” in U.S. Pat. No. 4,647,839 (Mar. 3, 1987). The circuit has become well-known by a thesis by Willingham et al. (S. D. Willingham, K. W. Martin and A. Ganesan, “A BiCMOS Low-Distortion 8-MHz Low-Pass Filter”, IEEE Journal of Solid-State Circuits, Vol. 28, No. 12, pp. 1234-1245, December 1993).

On the other hand, the circuit topology of FIG. 1B presumably was first proposed by Katsumi Nagano (Katsumi Nagano, ‘Voltage-to-Current Converter Circuit” in JP Patent Kokai Publication No. JP-A-58-9409), or by K. Nagano, “Voltage-to-Current Converter Circuit”, U.S. Pat. No. 4,442,400 (Apr. 10, 1984).

In general, the circuit topology has been known by Welland's MOS OTA (I. Mehr and D. R. Welland, ‘A CMOS Continuous-Time Gm-C Filter for PRML Read Channel Applications at 150 Mb/s and Beyond”, IEEE J. Solid-State Circuits, Vol. 32, No. 4, pp. 499-513, April 1997, or D. W. Welland, “Transconductance Amplifiers and Exponential Variable Gain Amplifiers Using the Same”, U.S. Pat. No. 5,451,901 (Sep. 19, 1995).

The signal path is constituted solely by NMOS transistors, so that high-frequency operations may be expected to be achieved.

With the OTA circuits, employing floating resistors, it is difficult to vary the conductance. Thus, to vary the conductance, a differential active load or a current squaring circuit need to be used.

The geometrical analysis of an OTA circuit, that is linear on first-order approximation, is now made for scrutiny of a circuit that has a input voltage range in which a linear operation is ensured in the analysis of a first-order approximation model of a MOS transistor shown in the method (2).

In an analysis employing a first-order approximation model of a MOS transistor, the transistor is caused to operate in the saturation region or in the linear region and the square characteristic of the MOS transistor is exploited to linearize the transconductance.

If the square characteristic can be completely canceled out, an OTA circuit according to the method (2) that has the input voltage range in which the linear operation is ensured may be obtained, whereas, if the square characteristic cannot completely be canceled out, transconductance has equi-ripple characteristics, thus yielding an OTA circuit according to the method (3).

The OTA circuits according to the methods (1) and (2) are termed linear transconductance amplifiers, sometimes abbreviated to ‘LTA’.

For implementing the OTA circuit according to the method (2),

(a) a class AB circuit that can realize linearization by subtracting a parabolic characteristic from a parabolic characteristics (FIG. 2) is well-known.

However, the present inventor has already clarified that

(b) it is possible to implement a class A circuit that can realize linearization by adding the square (parabolic) characteristic to the parabolic characteristic (FIG. 3A), and that

(c) it is also possible to implement a linear class AB circuit that can realize linearization by subtracting the square (parabolic) characteristic from the parabolic characteristic (FIG. 3B).

There are also a method employing an adaptive bias differential pair (d) and a method a employing a multiplier core circuit (e).

The method (2) is apparently superior to the method (3).

However, with progress in process miniaturization or with the continuous shrinking of transistor size, in the first-order approximation model of the MOS transistor, for example, the square-law model in the saturation region has a tendency to adopt the decreased value of the exponent from the square characteristic to 1.5-1.8 power characteristic, such that, strictly speaking, the difference between the method (2) and the method (3) tends to cease to exist.

Nevertheless, the method (2) is still effective as a method for implementing an OTA circuit having transconductance of high linearity, whilst the method (3) is still effective as a method for implementing an OTA circuit having the transconductance of moderate linearity.

In particular, among the implementing methods to come under the method (2), there is a method of using a multiplier core circuit in the OTA circuit.

By the multiplier core circuit is meant a core circuit for implementing a multiplication circuit. This multiplication circuit inherently has a 2-input 1-output circuit configuration.

Hence, the multiplier core circuit inherently operates in four quadrants. The multiplication circuit can be used as a variable gain amplifier circuit by supplying a signal to one of two inputs of the multiplication circuit and by using the other input for a fixed bias signal, as may readily be understood from the case of an AGC (Auto Gain Control) circuit.

The following two circuits are well-known as OTA circuits employing a multiplier core circuit:

(1) An OTA circuit employing a multiplier core circuit made up of four composite transistors (FIG. 4A), and

(2) an OTA circuit employing a multiplier core circuit made up of four transistors (FIG. 4B).

The well-known OTA circuit by Wang of FIG. 4B (Z. Wang, “Novel Linearisation Technique for Implementing Large-Signal MOS Tunable Transconductor”, IEE Electronics Letters 18 Jan. 1990 Vol. 26 No. 2, pp. 138-139) is a typical example of an OTA circuit employing a multiplier core circuit made up of four transistors.

This OTA circuit is a modification of the multiplier core circuit of the four-quadrant multiplication circuit, proposed by K. Bult, into a two-quadrant multiplication circuit.

However, with this OTA circuit, employing the multiplier core circuit, the linear input voltage range is distributed to respective two inputs of the multiplier core circuit. Thus, as the OTA circuit, the linear input voltage range becomes narrow, thus restricting its application.

Among the implementing methods, classified as belonging to the method (2), a method of driving the MOS differential pair with the square current to implement a linear operation has been known as an adaptive bias differential pair.

In a well-known manner, the balanced MOS differential pair, driven by the constant current, is not linear in its characteristic.

This results because the common source voltage of two transistors, making up the differential pair, is varied responsive to changes in the input voltage.

Hence, the linear operation becomes possible if the balanced MOS differential pair is driven with the current adapted to the input voltage to maintain the common source voltage at a constant value.

The resulting MOS differential pair is termed an “adaptively biased differential pair” or an “adaptive-biasing differential pair”.

From a different perspective, the adaptively biased MOS differential pair may be said to be a subtraction unit because the differential output current is proportionate to a voltage difference applied across the input terminals. From a still different perspective, it may be said to be an adder because the common source voltage is a voltage value corresponding to the sum of voltages applied to the input terminals less a constant voltage.

FIG. 5A depicts a schematic circuit diagram of the adaptively biased MOS differential pair. The current is adapted to the input voltage to provide a current having a square characteristic with respect to the input voltage.

A differential output current ΔI_{D} of the MOS differential pair, driven by a tail current I_{SS}, is given by the difference between the drain currents ID1 and ID2 of M1 and M2, such that

$$\begin{matrix}Δ {I}_{D} = {I}_{D 1} - {I}_{D 2} \\ = \{ \begin{matrix}β {V}_{i} \sqrt{\frac{2 {I}_{ss}}{β} - {V}_{in}^{2}} & ( \vert {V}_{in} \vert \leq \sqrt{\frac{{I}_{ss}}{β}} ) \\ {I}_{ss} sgn ( {V}_{in} ) & ( \sqrt{\frac{{I}_{ss}}{β}} \leq \vert {V}_{in} \vert )\end{matrix}\end{matrix} \qquad ( 1 )$$

The condition for the tail current I_{SS} for the MOS differential pair to perform a linear operation is that the term within √ of the equation (1) is a constant at all times. Hence,

$$\begin{matrix}{I}_{ss} = {I}_{0} + \frac{1}{2} β {V}_{in}^{2} & ( \vert {V}_{in} \vert \leq \sqrt{\frac{{I}_{0}}{β}} ) .\end{matrix} \qquad ( 2 )$$

Substitution of (2) in (1) gives

$$\begin{matrix}Δ {I}_{D} = \sqrt{2 β {I}_{0}} {V}_{in} & ( \vert {V}_{in} \vert \leq \sqrt{\frac{{I}_{0}}{β}} ) .\end{matrix} \qquad ( 3 )$$

thus obtaining a linear differential output current.

FIG. 5B depicts an input/output characteristic of the adaptively biased MOS differential pair represented by the equation (3) and an input/output characteristic of a control MOS differential pair driven by a constant current.

The linear input voltage range of the adaptively biased MOS differential pair is the operating input voltage range of the MOS differential pair times 1/\sqrt{2}.

The transconductance is found by differentiating ΔI_{D} with the input voltage Vᵢₙ, that is, by

$$\begin{matrix}\frac{ⅆ ( Δ {I}_{D} )}{ⅆ {V}_{in}} = \sqrt{2 β {I}_{0}} & ( \vert {V}_{in} \vert \leq \sqrt{\frac{{I}_{0}}{β}} ) .\end{matrix} \qquad ( 4 )$$

That is, for the input voltage range of ±\sqrt{I₀/β}, the transconductance is of a constant value \sqrt{2βI₀}.

Thus, by driving the MOS differential pair with the tail current, having a square characteristic with respect to the input voltage, the two transistors that make up the differential pair operate as floating transistors.

That is, the common source voltage becomes constant and is not changed even though the input voltage is changed.

In the foregoing, a general circuit of the adaptively biased MOS differential pair has been described. To implement the adaptively biased MOS differential pair, how to implement the current having square characteristics as shown in equation (2) is at issue.

As a matter of course, if the input voltage range exhibiting the square characteristic is narrower than
±\sqrt{I₀/β}
the linear operating input voltage range, operating as the adaptively biased MOS differential pair, becomes correspondingly narrower.

Since the current having square characteristic with respect to the input voltage is generated, the operating speed of the circuit is affected to deteriorate the frequency characteristic.

Thus, in the adaptively biased MOS differential pair, the squaring circuit outputting the current having the square characteristic becomes crucial. The adaptively biased MOS differential pair may, for example, be implemented by using a quadritail cell, described later, as a squaring circuit.

As the MOS OTA, often used for the method (3), the OTA circuit by Krummenacher and Jodehl (“A 4-MHz CMOS Continuous-Time Filter with On-Chip Automatic Tuning”, IEEE J. Solid-State Circuits, Vol. 23, No. 3, pp. 750-758, June 1988) is well-known.

So far, parameter optimization was difficult because of an error in a circuit analysis equation. The present inventor has been the first to correct the error, as shown below.

In the saturation region, the characteristic of the MOS transistors is given as follows.
I_{D}=β(V_{GS}−V_{TH})² (5).

In the linear region, the characteristic of the MOS transistors is given as follows.
I_{D}=2β{(V_{GS}−V_{TH})V_{DS}−V_{DS}²/2} (6).

In the above equations, β is a transconductance parameter and may be expressed as β=μ(Cox/2)(W/L), where μ is an effective mobility of the carrier, Cox is the gate oxide capacitance per unit area, W is the gate width and L is the gate length.

The OTA circuit of the Krummenacher and Joehl, shown in FIG. 6, assumes three regions, depending on whether the MOS transistors are operating in the linear region or in the saturation region. The input/output characteristic may be expressed,
i) in case

$$\frac{a}{\sqrt{{2}_{a}^{2} - 2 a + 1}} \sqrt{\frac{2 {I}_{0}}{β}} \geq \vert {V}_{in} \vert \\ Δ {I}_{D} = \frac{2 \sqrt{β {I}_{0}}}{a} {V}_{in} \sqrt{1 - \frac{β {V}_{in}^{2}}{{4 }_{a}^{2} {I}_{0}}} . \qquad ( 7 )$$

Here, both the transistors M3 and M4 are operating in the linear region.

The Input/output characteristic may be expressed,
ii) in case

$$\vert {V}_{in} \vert > \frac{a}{\sqrt{{2}_{a}^{2} - 2 a + 1}} \sqrt{\frac{2 {I}_{0}}{β}} \\ Δ {I}_{D} = {\{ \frac{2 \vert {V}_{in} \vert \sqrt{β ( 2 a - 1 )} + \sqrt{( 8 a - 2 ) {I}_{0} - 2 β {V}_{in}^{2}}}{4 a - 1 } \}}^{2} sgn ( {V}_{in} ) . \qquad ( 8 )$$

Here, in case
Vᵢₙ>α\sqrt{2I₀}/\sqrt{(2α²−2α+1)β}
the transistor M3 operates in the linear region, whereas the transistor M4 operates in the saturation region.

In case
−α\sqrt{2I₀}/\sqrt{(2α²−2α+1)β}>Vᵢₙ
the transistor M3 operates in the saturation region, whereas the transistor M4 operates in the linear region.

In the above expressions, a is set to
a=1+β/(2β′).

FIG. 7A shows the transmission characteristic, with a as parameter.

However, caution should be exercised so that, in the results of circuit analysis, shown in the original Publication, transconductance characteristic become discontinuous.

Transconductance is obtained on differentiating the equations (7) and (8):
i) In case

$$\frac{a}{\sqrt{{2}_{a}^{2} - 2 a + 1}} \sqrt{\frac{2 {I}_{0}}{β}} \geq \vert {V}_{in} \vert$$

we obtain the following equation:

$$\frac{ⅆ ( Δ {I}_{D} )}{ⅆ {V}_{i n}} = \frac{2 \sqrt{β {I}_{0}}}{a} \sqrt{1 - \frac{β {V}_{in}^{2}}{{4}_{a}^{2} {I}_{0}}} - \frac{β \sqrt{β } {V}_{in}^{2}}{{2}_{a}^{3} \sqrt{{I}_{0}} \sqrt{1 - \frac{β {V}_{in}^{2}}{{4}_{a}^{2} {I}_{0}}}} . \qquad ( 9 )$$

If Vᵢₙ is set to zero (Vᵢₙ=0), we have

$${g}_{m 0} = \frac{2 \sqrt{β {I}_{0 }}}{a}$$

from which it is seen that the transconductance of OTA is proportional to the root (√) of the driving current (tail current).
ii) In case

$$\begin{matrix}\vert {V}_{in} \vert > \frac{a}{\sqrt{{2}_{a}^{2} - 2 a + 1}} \sqrt{\frac{2 {I}_{0}}{β}} we have & \\ \frac{ⅆ Δ {I}_{D}}{ⅆ {V}_{in}} = 2 \{ \frac{2 \vert {V}_{in} \vert \sqrt{β ( 2 a - 1 )} + \sqrt{( 8 a - 2 ) {I}_{0} - 2 β {V}_{in}^{2}}}{4 a - 1} \} \{ \frac{2 \sqrt{β ( 2 a - 1 ) }}{4 a - 1} + \frac{2 β \vert {V}_{in} \vert}{( 4 a - 1 ) \sqrt{( 8 a - 2 ) {I}_{0} - 2 β {V}_{in}^{2}}} \} & ( 10 )\end{matrix}$$

The transconductance characteristic is shown in FIG. 7B. It may be seen that this OTA circuit by Krummenacher and Johel operates so that transconductance increases when the amplitude increases.

The OTA circuit, proposed by Toyoda and nominated by the present inventor as ‘Toyoda OTA circuit’, is now described.

In connection with this OTA circuit, the present inventor has now verified that a linearized class A OTA circuit may be implemented by adding the square (parabolic) characteristic to the parabolic characteristic.

The Toyoda OTA circuit is made up of an inverting amplifier circuit and an output circuit, as shown in FIG. 8. The inverting amplifier circuit is made up of a MOS differential pair, including, as a load, a transistor connected in diode configuration, whereas the output circuit is constituted by a quadritail cell comprised of four transistors driven by a single tail current.

The MOS differential pair, connected to the load constituted by transistors, connected in the diode configuration, serves as a linear inverting amplifier. If transistors M5 and M6, making up a MOS differential pair, and load transistors M7 and M8, are transistors of the same size, the relationship between the differential input voltage Vᵢₙ to the MOS differential pair and the differential output voltage V₀ (=V₂−V₁) is such that Vᵢₙ=−V₀, because the gate-to-source voltages of transistors, flown through by the equal current, are equal to one another. It is therefore apparent that the above MOS differential pair represents a linear inverting amplifier circuit.

If, in FIG. 8, the transistors M5 to M9 are unit transistors, and the tail current of the MOS differential pair is I_{O}/2, the drain currents of the transistors M5, M6 respectively become

$$\begin{matrix}\begin{matrix}{I}_{D 5} = \frac{{I}_{0}}{4} + \frac{β}{2} {V}_{in} \sqrt{\frac{{I}_{0}}{β} - {V}_{in}^{2}} & ( \vert {V}_{in} \vert \leq \sqrt{\frac{{I}_{0}}{2 β}} )\end{matrix} \\ and & ( 11 ) \\ \begin{matrix}{I}_{ D 6} = \frac{ {I}_{ 0}}{ 4} - \frac{β}{ 2} {V}_{in} \sqrt{\frac{{I}_{0}}{β} - {V}_{in}^{2}} & ( \vert {V}_{in} \vert \leq \sqrt{\frac{{I}_{0}}{2 β}} ) .\end{matrix} & ( 12 )\end{matrix}$$

On the other hand, the common source voltage V_{S1} of the MOS differential pair is

$$\begin{matrix}{V}_{ S 1} = {V}_{CM} - {V}_{TH} - \frac{1}{ 2} \sqrt{ \frac{ {I}_{ 0}}{ β} - {V}_{in}^{ 2}} & ( \vert {V}_{in} \vert \leq \sqrt{\frac{{I}_{0}}{2 β}} )\end{matrix} \qquad ( 13 )$$

where V_{CM} is the common mode voltage of the differential input voltage. The source voltages of the load transistors M7 and M8 become output voltages and may be found respectively by

$$\begin{matrix}\begin{matrix}{V}_{1} = {V}_{B} - {V}_{GSB} = {V}_{B} - \sqrt{\frac{{I}_{D 6}}{β}} - {V}_{TH} & ( \vert {V}_{in} \vert \leq \sqrt{\frac{{I}_{0}}{2 β}} )\end{matrix} & ( 14 ) \\ and & \\ \begin{matrix}{V}_{2} = {V}_{B} - {V}_{GS 7} = {V}_{B} - \sqrt{\frac{{I}_{D 5}}{β}} - {V}_{TH} & ( \vert {V}_{in} \vert \leq \sqrt{\frac{{I}_{0 }}{2 β}} ) .\end{matrix} & ( 15 )\end{matrix}$$

In the above equations, V_{B} is a constant voltage.

Hence, although V₃ is a level-shifted constant voltage, V₁ and V₂ are varied with changes in the differential input voltage Vᵢₙ.

The linear operation is ensured by the following identity:

$$ⅆ ( \sqrt{c + \sqrt{ 2 x } \sqrt{c - \frac{{x}^{2}}{2}}} - \sqrt{c - \sqrt{2 x} \sqrt{c - \frac{{x}^{2}}{2}}} ) = ⅆ \sqrt{2 x} . \qquad ( 16 )$$

If we set so that

$$\begin{matrix}C = 1 , \\ ⅆ = \sqrt{{I}_{0}} / 2 and x = {V}_{in} / \sqrt{{I}_{0} / ( 2 β )} \\ then we have & \\ \begin{matrix}\sqrt{{I}_{D 5}} - \sqrt{{I}_{D 6}} = \sqrt{β} x & ( \vert {V}_{in} \vert \leq \sqrt{\frac{{I}_{0}}{2 β}} ) .\end{matrix} & ( 17 )\end{matrix}$$

Hence, the differential output voltage V_{O} becomes
V_{O}=V₂−V₁=−V₁ (18).

Since the differential output current of the MOS differential pair is given by

$$\begin{matrix}Δ {I}_{D} = {I}_{D 5} - {I}_{D 6} = ( \sqrt{{I}_{D 5}} - \sqrt{{I}_{D 6}} ) ( \sqrt{{I}_{D 5}} + \sqrt{{I}_{D 6}} ) \\ = \begin{matrix}β {V}_{in} \sqrt{\frac{{I}_{0}}{β} - {V}_{in}^{2}} & ( \vert {V}_{in} \vert \leq \sqrt{\frac{{I}_{0}}{2 β}} )\end{matrix}\end{matrix} \qquad ( 19 )$$

we have

$$\begin{matrix}\sqrt{ {I}_{D 5}} + \sqrt{ {I}_{D 6}} = \sqrt{β} \sqrt{ \frac{ {I}_{0}}{ β} - {V}_{in}^{ 2}} & ( \vert {V}_{in} \vert \leq \sqrt{\frac{{I}_{0}}{2 β}} )\end{matrix} \qquad ( 20 )$$

such that the common mode voltage V_{CMO} of the output voltage may be found by

$$\begin{matrix}{V}_{CM 0} = \frac{{V}_{1} {V}_{2}}{2} = {V}_{B} - {V}_{TH} - \frac{1}{2} ( \sqrt{\frac{{I}_{D 5}}{β}} - \sqrt{\frac{{I}_{D 6}}{β}} ) \\ = \begin{matrix}{V}_{B} - {V}_{TH} - \frac{1}{2} \sqrt{\frac{{I}_{0}}{β} - {V}_{in}^{2}} & ( \vert {V}_{in} \vert \leq \sqrt{\frac{{I}_{0}}{2 β}} ) .\end{matrix}\end{matrix} \qquad ( 21 )$$

Hence, from the equations (14) and (15), we have

$$\begin{matrix}\begin{matrix}{V}_{1} = {V}_{B} - {V}_{TH} - \frac{1}{2} \sqrt{\frac{{I}_{0}}{β} - {V}_{in}^{2}} + \frac{{V}_{in}}{2} & ( \vert {V}_{in} \vert \leq \sqrt{\frac{{I}_{0}}{2 β}} )\end{matrix} & ( 22 ) \\ \begin{matrix}{V}_{2} = {V}_{B} - {V}_{TH} - \frac{1}{2} \sqrt{\frac{{I}_{0}}{β} - {V}_{in}^{2}} - \frac{{V}_{in}}{2} & ( \vert {V}_{in} \vert \leq \sqrt{\frac{{I}_{0}}{2 β}} )\end{matrix} & ( 23 ) \\ and & \\ \begin{matrix}{V}_{3} = {V}_{B} - {V}_{TH} - \frac{1}{2} \sqrt{\frac{{I}_{0}}{β}} & ( \vert {V}_{in} \vert \leq \sqrt{\frac{{I}_{0}}{2 β}} )\end{matrix} & ( 24 )\end{matrix}$$

From the equation (21), the common mode voltage V_{CMO} becomes progressively higher with increase in the differential input voltage Vᵢₙ. The term of the root √ is equal to the non-linear term of the MOS differential pair.

Since the common mode voltage V_{CM} of the differential input voltage and V_{B} are constant voltages, the common mode voltage V_{CMO} of the output voltage is merely a level-shifted version of the common source voltage V_{S1} of the MOS differential pair.

On the other hand, since V₃ is a constant voltage, the relationship between the differential input voltages (V₂, V₁) and the constant voltage V₃ differs from the relationship between the differential input voltage Vᵢₙ and the constant voltage V_{CM} and contains variations in the common source voltage V_{S1} that is responsible for the non-linear term of the MOS differential pair.

Consequently, the non-linear term of the MOS differential pair may be cancelled out by taking advantage of the variations of the common source voltage V_{S1}.

However, the differential input voltage Vᵢₙ and the constant voltage V_{CM} can be received by differential input terminals (two terminals), whereas the differential voltages (V₂, V₁) and the constant voltage V₃ need to be received by three terminals.

This is why the quadritail cell is used. The point that should be noted is that driving currents for the MOS differential pair, its load transistors, the transistor M9 and the quadritail cell are set so that, with the transistors being of the same size, the respective driving currents are set so that the current densities of the respective transistors will be equal to one another in the absence of a signal.

Thus, the drain currents of the transistors, making up the quadritail cell, may be expressed as

$$\begin{matrix}\begin{matrix}{I}_{D 1} = {β ( {V}_{B} - \frac{1}{2} \sqrt{\frac{{I}_{0}}{β} - {V}_{in}^{2}} + \frac{{V}_{in}}{2} - {V}_{S} - 2 {V}_{TH} )}^{2} & ( \vert {V}_{in} \vert \leq \sqrt{\frac{{I}_{0}}{2 β}} )\end{matrix} & ( 25 ) \\ \begin{matrix}{I}_{D 2} = {β ( {V}_{B} - \frac{1}{2} \sqrt{\frac{{I}_{0}}{β} - {V}_{in}^{2}} - \frac{{V}_{in}}{2} - {V}_{S} - 2 {V}_{TH} )}^{2} & ( \vert {V}_{in} \vert \leq \sqrt{\frac{{I}_{0}}{2 β}} )\end{matrix} & ( 26 ) \\ \begin{matrix}and & \end{matrix} & \\ \begin{matrix}{I}_{D 3} = {I}_{D 4} = {β ( {V}_{B} - \frac{1}{2} \sqrt{\frac{{I}_{0}}{β}} - {V}_{S} - 2 {V}_{TH} )}^{2} & ( \vert {V}_{in} \vert \leq \sqrt{\frac{{I}_{0}}{2 β}} ) .\end{matrix} & ( 27 )\end{matrix}$$

From the condition of the tail current,
I_{D1}+I_{D2}+I_{D3}+I_{D4}=I₀ (28)

Solving the equation (28) from the equation (25), we have

$${V}_{B} - {V}_{s} - 2 {V}_{TH} = \frac{1}{2} ( \sqrt{\frac{{I}_{0}}{β}} - \sqrt{\frac{{I}_{0}}{β} - {V}_{i n}^{2}} ) ( \vert {V}_{i n} \vert \leq \sqrt{\frac{{I}_{0}}{2 β}} ) . \qquad ( 29 )$$

Substitution of the equation (29) in the equations (24)-(27) gives as respective drain currents

$$\begin{matrix}{I}_{D 1} = \frac{β}{4} {( {V}_{i n} + \sqrt{\frac{{I}_{0}}{β}} )}^{2} ( \vert {V}_{i n} \vert \leq \sqrt{\frac{{I}_{0}}{2 β}} ) & ( 30 ) \\ {I}_{D 2} = \frac{β}{4} {( {V}_{i n} - \sqrt{\frac{{I}_{0}}{β}} )}^{2} ( \vert {V}_{i n} \vert \leq \sqrt{\frac{{I}_{0}}{2 β}} ) \\ and & ( 31 ) \\ {I}_{D 3} = {I}_{D 4} = \frac{β}{4} ( \frac{{I}_{0}}{4} - {V}_{i n}^{2} ) ( \vert {V}_{i n} \vert \leq \sqrt{\frac{{I}_{0}}{2 β}} ) . \\ Hence , we have & ( 32 ) \\ {I}^{+} = {I}_{DI} + {I}_{D 3} = \frac{{I}_{0}}{2} + \frac{\sqrt{β {I}_{0}}}{2} {V}_{i n} ( \vert {V}_{i n} \vert \leq \sqrt{\frac{{I}_{0}}{2 β}} ) \\ and & ( 33 ) \\ {I}^{-} {I}_{D 2} + {I}_{D 4} = \frac{{I}_{0}}{2} - \frac{\sqrt{β {I}_{0}}}{2} {V}_{i n} ( \vert {V}_{i n} \vert \leq \sqrt{\frac{{I}_{0}}{2 β}} ) & ( 34 )\end{matrix}$$

so that, by summing two parabolic curves, the OTA circuit of the class A operation, shown in FIG. 9, may be implemented.

### SUMMARY OF THE DISCLOSURE

An OTA circuit by Kim² and Park (C. S. Kim, Y. H. Kim and S. B. Park, “New CMOS Linear Transconductor”, IEE Electronics Letters 8 Oct. 1992, Vol. 28, No. 21, pp. 1962-1964), that gave a suggestion to the present invention, is now described.

In FIG. 10, let the size of the transistors M1 and M2 be K (<1). The drain currents ID1 to ID6 of the transistors M1 to M6 may be expressed by

$$\begin{matrix}{I}_{D 1} = K {β ( {V}_{CM} + \frac{{V}_{i n}}{2} - {V}_{S} - {V}_{TH} )}^{2} & ( 35 ) \\ {I}_{D 2} = K {β ( {V}_{CM} - \frac{{V}_{i n}}{2} - {V}_{S} - {V}_{TH} )}^{2} & ( 36 ) \\ {I}_{D 3} = {β ( {V}_{CM} + \frac{{V}_{i n}}{2} - {V}_{1} - {V}_{TH} )}^{2} & ( 37 ) \\ {I}_{D 4} = {β ( {V}_{CM} - \frac{{V}_{i n}}{2} {V}_{2} - {V}_{TH} )}^{2} & ( 38 ) \\ {I}_{D 5} = 2 β ( {V}_{CM} - \frac{{V}_{i n }}{2} - {V}_{s} - {V}_{TH} - \frac{{V}_{1} - {V}_{s}}{2} ) ( {V}_{1} - {V}_{s} ) \\ and & ( 39 ) \\ {I}_{D 6} = 2 β ( {V}_{CM} + \frac{{V}_{i n}}{2} - {V}_{S} - {V}_{TH} - \frac{{V}_{21} - {V}_{s}}{2} ) ( {V}_{2} - {V}_{S} ) . \\ If we set & ( 40 ) \\ α = {V}_{CM} - {V}_{S} - {V}_{TH} & ( 41 )\end{matrix}$$

the above equations may be rewritten to

$$\begin{matrix}{I}_{D 1} = {Kβ ( \frac{{V}_{i n}}{2} + α )}^{2} & ( 42 ) \\ {I}_{D 2} = K {β ( - \frac{{V}_{i n}}{2} + α )}^{2} & ( 43 ) \\ {I}_{D 3} = β {\{ \frac{{V}_{i n}}{2} - ( {V}_{1} - {V}_{S} ) + α \}}^{2} & ( 44 ) \\ {I}_{D 4} = β {\{ - \frac{{V}_{i n}}{2} - ( {V}_{2} - {V}_{S} ) + α \}}^{2} & ( 45 ) \\ {I}_{D 5} = 2 β ( - \frac{{V}_{i n}}{2} + α - \frac{{V}_{1} - {V}_{s}}{2} ) ( {V}_{1} - {V}_{s} ) \\ and & ( 46 ) \\ {I}_{D 6} = 2 β ( \frac{{V}_{i n}}{2} + α - \frac{{V}_{2} - {V}_{s}}{2} ) ( {V}_{2} - {V}_{s} ) . \\ Hence , we have & ( 47 ) \\ {I}_{D 1} + {I}_{D 2} = 2 K β \{ {( \frac{{V}_{i n}}{2} )}^{2} + {α}^{2} \} . & ( 48 )\end{matrix}$$

Since I_{D3}=I_{D5}, we have

$$\begin{matrix}\frac{{V}_{i n}^{2}}{4} + {( {V}_{1} - {V}_{S} )}^{2} + {α}^{2} - 2 \frac{{V}_{i n}}{2} ( {V}_{1} - {V}_{s} ) - 2 α ( {V}_{1} - {V}_{s} ) + 2 \frac{{V}_{i n}}{2} α = - 2 \frac{{V}_{i n}}{2} ( {V}_{1} - {V}_{s} ) + 2 α ( {V}_{1} - {V}_{s} ) - {( {V}_{1} - {V}_{s} )}^{2} . & ( 49 ) \\ 2 {( {V}_{1} - {V}_{S} )}^{2} - 4 α ( {V}_{1} - {V}_{S} ) + \frac{{V}_{i n}^{2}}{4} + 2 \frac{{V}_{i n}}{2} α + {α}^{2} = 0. & ( 50 )\end{matrix}$$

Solving the equation (50) with respect to (V₁−V_{S}), we have

$${V}_{1} - {V}_{s} = α - \sqrt{\frac{1}{2} ( {α}^{2} - \frac{{V}_{i n}^{2}}{4} - 2 \frac{{V}_{i n}}{2} α )} \\ = α - \frac{α}{\sqrt{2}} \sqrt{1 - \frac{{V}_{i n}^{2}}{4 {α}^{2}} - 2 \frac{{V}_{i n}}{2 α}} .$$

Also, since I_{D4}=I_{D6}, we have

$$\frac{{V}_{i n}^{2}}{4} + {( {V}_{2} - {V}_{S} )}^{2} + {α}^{2} + 2 \frac{{V}_{i n}}{2} ( {V}_{2} - {V}_{s} ) - 2 α ( {V}_{2} - {V}_{s} ) - 2 \frac{{V}_{i n}}{2} α = 2 \frac{{V}_{i n}}{2} ( {V}_{2} - {V}_{s} ) + 2 α ( {V}_{2} - {V}_{s} ) - {( {V}_{2} - {V}_{s} )}^{2} . \qquad ( 52 )$$

That is,

$$2 {( {V}_{2} - {V}_{S} )}^{2} - 4 α ( {V}_{1} - {V}_{s} ) + \frac{{V}_{i n}^{2}}{4} - 2 \frac{{V}_{i n}}{2} α + {α}^{2} = 0. \qquad ( 53 )$$

Solving the equation (53) for (V₂−V_{S}), we have

$${V}_{2} - {V}_{s} = α - \sqrt{\frac{1}{2} ( {α}^{2} - \frac{{V}_{i n}^{2}}{4} + 2 \frac{{V}_{i n}}{2} α )} = α - \frac{α}{\sqrt{2}} \sqrt{1 - \frac{{V}_{i n}^{2}}{4 {α}^{2}} + 2 \frac{{V}_{i n}}{2 α}} . \qquad ( 54 )$$

The equations (51) and (54) have now been found, such that V₁ and V₂ can be eliminated. However, V_{S} is included in α and hence has not been eliminated.
At this time,

$$\begin{matrix}{I}_{D 3} = β {\{ \frac{{V}_{i n}}{2} + \frac{α}{\sqrt{2}} \sqrt{1 - \frac{{V}_{i n}^{2}}{4 {α}^{2}} - 2 \frac{{V}_{i n}}{2 α}} \}}^{2} \\ = β [ {( \frac{{V}_{i n}}{2} )}^{2} + \sqrt{2} α \frac{{V}_{i n}}{2} \sqrt{1 - \frac{{V}_{i n}^{2}}{4 {α}^{2}} - 2 \frac{{V}_{i n}}{2 α}} + \\ \frac{1}{2} ( {α}^{2} - \frac{{V}_{i n}^{2}}{4} - 2 \frac{{V}_{i n}}{2} α ) ] .\end{matrix} \qquad ( 55 )$$

Here, the root √ is removed by first-order approximation. However, the approximation is subject to the condition

$$( \frac{{V}_{in}^{2}}{{4}_{{α}^{2}}} + 2 \frac{{V}_{in}}{2 α} ) << 1$$

and, in general, cannot be applied to an OTA where the input signal is not necessarily a small signal.

However, the original literature is here to be followed:

$$\sqrt{1 - \frac{{V}_{in}^{2}}{{4}_{{α}^{2}}} - 2 \frac{{V}_{in}}{2 α}} \approx 1 - \frac{1}{2} ( \frac{{V}_{in}^{2}}{{4}_{{α}^{2}}} + 2 \frac{{V}_{in}}{2 α} ) . \qquad ( 56 )$$

The equation (55) may be approximated by

$$\begin{matrix}{I}_{D 3} = β [ {( \frac{{V}_{in}}{2} )}^{2} + \sqrt{2} α \frac{{V}_{in}}{2} \sqrt{1 - \frac{{V}_{in}^{2}}{{4}_{{α}^{2}}} - 2 \frac{{V}_{in}}{2 α}} + \\ \frac{1}{2} ( {α}^{2} - \frac{{V}_{in}^{2}}{4} - 2 \frac{{V}_{in}}{2} α ) ] \\ \approx β [ {( \frac{{V}_{in}}{2} )}^{2} + \sqrt{2} α \frac{{V}_{in}}{2} \{ 1 - \frac{1}{2} ( \frac{{V}_{in}^{2}}{{4}_{{α}^{2}}} - 2 \frac{{V}_{in}}{2 α} ) \} + \\ \frac{1}{2} ( {α}^{2} - \frac{{V}_{in}^{2}}{4} - 2 \frac{{V}_{in}}{2} α ) ] .\end{matrix} \qquad ( 57 )$$

By similar approximation, we have

$$\begin{matrix}{I}_{D 4} = β {\{ - \frac{{V}_{in}}{2} + \frac{α}{\sqrt{2}} \sqrt{1 - \frac{{V}_{in}^{2}}{4 {α}^{2}}} + 2 \frac{{V}_{in}}{2 α} \}}^{2} \\ = β [ {( \frac{{V}_{in}}{2} )}^{2} - \sqrt{2} α \frac{{V}_{in}}{2} \sqrt{1 - \frac{{V}_{in}^{2}}{{4}_{{α}^{2}}} + 2 \frac{{V}_{in}}{2 α}} + \\ \frac{1}{2} ( {α}^{2} - \frac{{V}_{in}^{2}}{4} + 2 \frac{{V}_{in}}{2} α ) ] \\ \approx β [ {( \frac{{V}_{in}}{2} )}^{2} + \sqrt{2} α \frac{{V}_{in}}{2} \{ 1 + \frac{1}{2} ( - \frac{{V}_{in}^{2}}{{4}_{{α}^{2}}} + 2 \frac{{V}_{in}}{2 α} ) \} + \\ \frac{1}{2} ( {α}^{2} - \frac{{V}_{in}^{2}}{4} + 2 \frac{{V}_{in}}{2} α ) ] .\end{matrix} \qquad ( 58 )$$

From the condition of the tail current, we have the following expression:

$$\begin{matrix}{I}_{0} = {I}_{D 1} + {I}_{D 2} + {I}_{D 3} + {I}_{D 4} \\ = β [ ( 1 + 2 K ) \frac{{V}_{in}^{2}}{4} + ( 1 + 2 K ) {α}^{2} + 2 \frac{{V}_{in}}{2} \\ \{ \sqrt{{α}^{2} - \frac{{( \frac{{V}_{in}}{2} + α )}^{2}}{2}} - \sqrt{{α}^{2} - \frac{{( \frac{{V}_{in}}{2} - α )}^{2}}{2}} \} ] \\ \approx β [ \{ ( 1 - 2 \sqrt{2} ) + 2 K \} \frac{{V}_{in}^{2}}{4} + ( 1 + 2 K ) {α}^{2} ] .\end{matrix} \qquad ( 59 )$$

It is noted that, in addition to constants V_{CM} and V_{TH}, a variable V_{S} is contained in α, this variable V_{S} being a variable of the input voltage Vᵢₙ.

However, if assumed that, as in the conventional OTA, V_{S} becomes constant regardless of the input signal Vᵢₙ, in case the OTA performs a linear operation, the term of Vᵢₙ² in the equation (49) should be zero, because the tail current I_{O} is constant at all times.

Hence, the following equation holds:

$$K = \frac{2 \sqrt{2} - 1}{2} \qquad ( 60 )$$

In this case,

$$α = {V}_{CM} - {V}_{S} - {V}_{TH} = \sqrt{\frac{{I}_{0}}{( 2 K + 1 ) β}} \qquad ( 61 )$$

and the differential output current ΔI may be expressed as

$$\begin{matrix}Δ I = {I}_{D 1} - {I}_{D 2} \\ = K \sqrt{\frac{β {I}_{0}}{( 2 K + 1 ) β}} {V}_{in} .\end{matrix} \qquad ( 62 )$$

Also, when the OTA performs the linear operation, as described above, the drain currents may be given by

$$\begin{matrix}\begin{matrix}{I}_{D 1} = K {β ( \sqrt{\frac{{I}_{0}}{( 2 K + 1 ) β}} + \frac{{V}_{in}}{2} )}^{2} = \frac{K}{2 K + 1} {I}_{0} + \\ K \sqrt{\frac{β {I}_{0}}{2 K + 1}} {V}_{in} + K β \frac{{V}_{in}^{2}}{4} and\end{matrix} & ( 63 ) \\ \begin{matrix}{I}_{D 2} = K {β ( \sqrt{\frac{{I}_{0}}{( 2 K + 1 ) β}} + \frac{{V}_{in}}{2} )}^{2} \\ = \frac{K}{ 2 K + 1} {I}_{ 0} - K \sqrt{\frac{β {I}_{0}}{2 K + 1}} {V}_{in} + K β \frac{{V}_{in}^{2}}{4} .\end{matrix} & ( 64 )\end{matrix}$$

However, for any optional value of K other than

$$K = \frac{2 \sqrt{2} - 1}{2} ( = 0 \text{.} 9142 )$$

the equations (63) and (64) hold, and an OTA is obtained for which the equation (62) holds and which performs a linear operation.

This is ascribable to the fact that approximation such as Taylor expansion for small signals is invalid for this sort of the OTA circuit.

Further, this circuit fails to provide for differential outputs and hence may not be used for a full differential circuit having a high current efficiency.

The foregoing is the overview of the OTA circuit so far proposed.

The general conditions for OTA circuits, emerging from the foregoing, may be enumerated by

(1) linear input voltage range;

(2) low-voltage operation;

(3) output current efficiency;

(4) class A operation;

(5) differential output;

(6) variable gm; and

(7) small circuit scale.

As regards the linear input voltage range of (1), it is of course crucial that a desired linear input voltage range, such as an input voltage range for which the gm value is comprised within the variations of ±1%, or an input voltage range for which a distortion factor of 40 dB may be secured, but it is also crucial that the linear input voltage range accounts for the major portion of the operating input voltage range.

For the output current efficiency of (3), if the current flowing through e.g. the control circuit is decreased, the proportion of the output current at the time of the maximum linear input voltage to the output current at the time of the maximum operating input voltage is reached. If the value of this proportion cannot be made larger, it is difficult to decrease the current consumption.

To cite an instance, the Wang's OTA circuit has a low output current efficiency.

That is, the OTA circuit, which the present inventor regards to be an ideal circuit, is such an OTA circuit which is small in circuit size like the OTA circuit of Krummenacher and Johel and which is higher in linearity than the OTA circuit of Krummenacher and Johel.

The following is the description on newly found Patent Documents that seems to bear similarity to the present application.

FIG. 11A shows an OTA circuit by V. Prodanov. This circuit was described first of all in U.S. Pat. No. 6,577,170 B1 (Jun. 10, 2003) as an independent invention.

However, the circuit diagram shown in FIG. 11A and the graph of transconductance characteristic shown in FIG. 11B have been copied from a thesis of which V. Prodanov is a co-author (J. Aris, P. Kiss, V. Prodanov, V. Boccuzzi, M. Banu, D. Bisbal, J. S. Pablo, L. Quintanilla and J. Barbolla, “A 32-mW 320-MHz Continuous-Time Complex Delta-Sigma ADC for Multi-Mode Wireless-LAN Receivers”, IEEE Journal of Solid-State Circuits, Vol. 41, No. 2, pp. 339-351, February 2006).

This circuit bears certain similarity to the aforementioned OTA circuit by KIM² and Park. The Patent Document and even three publicized theses stating the Prodanov's OTA circuit lack in circuit analyses.

Among other co-authors are notable professors of universities so that circuit analyses by them should have been possible

These theses recite the thesis by Krummenacher and Johel as reference material and state that the circuit disclosed in the theses is the OTA circuit by Krummenacher and Johel in which a π-type constant current source unit is changed to a T-type constant current source unit, with the operation being similar to the OTA circuit by Krummenacher and Johel.

The description of the patent specification lacks in circuit analyses and represents the technical disclosure of only marginal quality. It may be presumed that V. Prodanov himself has not seen circuit analyses of the OTA circuit by Krummenacher and Johel and has not understood its circuit operation.

Detailed circuit analyses of the OTA circuit by Krummenacher and Johel were made in the description of the conventional circuit in the specification of the present application. Although the expressions for the circuit analyses were publicized before the filing data of the application for the Prodanov's Patent, those expressions were publicized only in Japanese and hence it may be that they were not noticed by V. Prodanov or, if they were, they could not be understood by him because of linguistic limitations.

In actuality, the Prodanov's circuit is similar in operation to a degeneration circuit of the OTA circuit by Krummenacher and Johel. In the Prodanov's circuit, transistors M3, M5 and transistors M4, M6, corresponding to degeneration resistors, are operating in the linear region. As in the operation of the transistors M3 and M4, equivalent to the degeneration resistors of the OTA circuit (FIG. 6) by Krummenacher and Johel, transition from the operation in the linear region to that in the saturation region occurs when the differential input voltage increases.

However, equivalently, the differential input voltage is received by transistors M3, M5 and M4, M6, equivalent to the two degeneration resistors, and hence the level of the amplitude applied is about one-half, thus further improving the linearity.

It is now undertaken to analyze the Prodanov's OTA circuit.

The MOS transistor characteristic is set so that, in the saturation region of the MOS transistor characteristic, the condition
V_{DS}≧V_{GS}−V_{TH} (65)
holds, and
I_{D}=β(V_{GS}−V_{TH})² (66).

The MOS transistor characteristic is also set so that, in the linear region, the condition
V_{DS}≧V_{GS}−V_{TH}
holds, and
I_{D}=2β{(V_{GS}−V_{TH})V_{DS}−V_{DS}²/2} (67)

It is noted that β is the transconductance parameter and may be expressed by β=μ(C_{OX}/2)(W/L), where is carrier mobility, Cox is the gate oxide capacitance per unit area, W is the channel width and L is a channel length).

(1) If, in FIG. 11A, the size of the transistors M1, M2 is K, and the transistors M3, M4, M5 and M6 are all operating in the linear region,
I_{D1}=Kβ(V_{CM}+Vᵢₙ/2−V_{S1}−V_{TH})² (68)
I_{D2}=Kβ(V_{CM}−Vᵢₙ/2−V_{S2}−V_{TH})² (69)
I_{D3}=2β{V_{CM}+Vᵢₙ/2−V_{S0}−V_{TH}−(V_{S1}−V_{S0})/2}(V_{S1}−V_{S0}) (70)
I_{D4}=2β{V_{CM}+Vᵢₙ/2−V_{S0}−V_{TH}−(V_{S2}−V_{S0})/2}(V_{S2}−V_{S0}) (71)
I_{D5}=2β{V_{CM}−Vᵢₙ/2−V_{S0}−V_{TH}−(V_{S1}−V_{S0})/2}(V_{S1}−V_{S0}) (72)
and
I_{D6}=β{V_{CM}−Vᵢₙ/2−V_{S0}−V_{TH}−(V_{S2}−V_{S0})/2}(V_{S2}−V_{S0}) (73).

If we put
α₁=V_{CM}−V_{S1}−V_{TH} (74)
and
α₂=V_{CM}−Vₛ₂−V_{TH} (75)
the equations (67) to (72) may be rewritten to as follows.

$$\begin{matrix}{I}_{D 1} = K {β ( {V}_{in} 2 / + {α}_{1} )}^{2} & ( 76 ) \\ {I}_{D 2} = K {β ( - {V}_{in} / 2 + {α}_{2} )}^{2} & ( 77 ) \\ \begin{matrix}{I}_{D 3} = 2 β \{ {V}_{in} / 2 + {α}_{1} + ( {V}_{S 1} - {V}_{S 0} ) - ( {V}_{S 1} - {V}_{S 0} ) / 2 \} \\ ( {V}_{S 1} - {V}_{S 0} ) \\ = 2 β \{ {V}_{in} / 2 + {α}_{1} + ( {V}_{S 1} - {V}_{S 0} ) / 2 \} ( {V}_{S 1} - {V}_{S 0} )\end{matrix} & ( 78 ) \\ {I}_{D 4} = 2 β \{ {V}_{in} / 2 + {α}_{2} + ( {V}_{S 2} - {V}_{S 0} ) / 2 \} ( {V}_{S 2} - {V}_{S 0} ) & ( 79 ) \\ {I}_{D 5} = 2 β \{ - {V}_{in} / 2 + {α}_{1} + ( {V}_{S 1} - {V}_{S 0} ) / 2 \} ( {V}_{S 1} - {V}_{S 0} ) & ( 80 ) \\ {I}_{D 6} = 2 β \{ - {V}_{in} / 2 + {α}_{2} + ( {V}_{S 2} - {V}_{S 0} ) / 2 \} ( {V}_{S 2} - {V}_{S 0} ) . & ( 81 )\end{matrix}$$

Since
I_{D1}=I_{D3}+I_{D5}
we have
(V_{S1}−V_{S0})²+2α₁(V_{S1}−V_{S0})−K(Vᵢₙ/2+α₁)²/2=0 (82).

Solving the above equation for (V_{S1}−V_{S0}),

$${V}_{S 1} - {V}_{S 0} = {α}_{1} + \sqrt{{α}_{1}^{2} + \frac{K}{2} {( \frac{{V}_{in}}{2} + {α}_{1} )}^{2}} . \qquad ( 83 )$$

In similar manner, since I_{D2}=I_{D4}+I_{D6}, we have
(V_{S2}−V_{S0})²+2α₂(V_{S2}−V_{S0})−K(−Vin/2+α₂)²/2=0 (84).

Solving the above equation for V_{S2}=V_{S0}, we have

$${V}_{S 2} - {V}_{S 0} = - {α}_{2} + \sqrt{{α}_{2}^{2} + \frac{K}{2} {( - \frac{{V}_{in}}{2} + {α}_{2} )}^{2}} . \qquad ( 85 )$$

Subtracting the equation (85) from the equation (83), since
α₁−α₂=−(V_{S1}−V_{S2}) (86).
we have

$$\sqrt{{α}_{1}^{2} + \frac{K}{2} {( \frac{{V}_{in}}{2} + {α}_{1} )}^{2}} = \sqrt{{α}_{2}^{2} + \frac{K}{2} {( - \frac{{V}_{in}}{2} + {α}_{2} )}^{2}} \qquad ( 87 )$$

Squaring both sides of the equation (87), we have

$${α}_{1}^{2} + \frac{K}{2} {( \frac{{V}_{in}}{2} + {α}_{1} )}^{2} = {α}_{2}^{2} + \frac{K}{2} {( - \frac{{V}_{in}}{2} + {α}_{2} )}^{2} . \qquad ( 88 )$$

Thus, from the equation (88), we have
(α₁+α₂)[(α₁−α₂)+(K/2){Vᵢₙ+(α₁−α₂)}]=0 (89).

Since α₁−α₂≠0, we have
[(α₁−α₂)+(K/2){Vᵢₙ+(α₁−α₂)}]=0 (90).

From the equation (90), we have
α₁−α₂=−KVᵢₙ/(K+2) (91).

In similar manner, from the equation (86), the following equation (92)
V_{S1}−V_{S2}=KVᵢₙ/(K+2) (92)
holds.

Under the condition for the tail current,
I_{D1}+I_{D2}=I_{bias}=I_{O} (93)
so that, substitution of the equations (75), (76), (91) and (92) in the equation (93) gives

$$2 {α}_{1}^{2} + \frac{2 K}{K + 2} {V}_{in} {α}_{1} + \frac{{K}^{2} + 4}{2 {( K + 2 )}^{2}} {V}_{in}^{2} - \frac{{I}_{0}}{K β} = 0. \qquad ( 94 )$$

Solving the equation (94) for α1, we have

$${α}_{1} = - \frac{K}{2 ( K + 2 )} {V}_{in} + \sqrt{\frac{{I}_{0}}{2 K β} - \frac{1}{{( K + 2 )}^{2}} {V}_{in}^{2}} . \qquad ( 95 )$$

α2 is given by

$${α}_{2} = \frac{K}{2 ( K + 2 )} {V}_{in} + \sqrt{\frac{{I}_{0}}{2 K β} - \frac{1}{{( K + 2 )}^{2}} {V}_{in}^{2}} . \qquad ( 96 )$$

α1 and α2 have now been found. At this time, I_{D1} and I_{D2} are respectively expressed by

$$\begin{matrix}{I}_{D 1} = K β [ \frac{{I}_{0}}{2 K β} + \frac{2}{K + 2} {V}_{in} \sqrt{\frac{{I}_{0}}{2 K β} - \frac{1}{{( K + 2 )}^{2}} {V}_{in}^{2}} ] and by \\ & ( 97 ) \\ {I}_{D 2} = K β [ \frac{{I}_{0}}{2 K β} - \frac{2}{K + 2} {V}_{in} \sqrt{\frac{{I}_{0}}{2 K β} - \frac{1}{{( K + 2 )}^{2}} {V}_{in}^{2}} ] . & ( 98 )\end{matrix}$$

The case where the transistors M3, M4, M5 and M6 transition to the operation in the saturation region is now described. This case may be divided into a situation where the differential input voltage is positive and a situation where the differential input voltage is negative.

In case the input voltage is of a higher amplitude (Vin>0), only the transistor M5 transitions to the operation in the saturation region. Here, the equation (99) is applied, for the aforementioned reason, to express the drain currents as follows:
I_{D1}=Kβ(V_{CM}+Vᵢₙ/2−V_{S1}−V_{TH})² (99)
I_{D2}=Kβ(V_{CM}−Vᵢₙ/2−V_{S2}−V_{TH})² (100)
I_{D3}=2β{V_{CM}+Vᵢₙ/2−V_{S0}−V_{TH}−(V_{S1}−V_{S0})/2}(V_{S1}−V_{S0}) (101)
I_{D4}=2β{V_{CM}+Vᵢₙ/2−V_{S0}−V_{TH}−(V_{S2}−V_{S0})/2}(V_{S2}−V_{S0}) (102)
I_{D5}=β(V_{CM}−Vᵢₙ/2−V_{S0}−V_{TH})² (103)
I_{D6}=2β{V_{CM}−Vᵢₙ/2−V_{S0}−V_{TH}−(V_{S2}−V_{S0})/2}(V_{S2}−V_{S0}) (104).

If we put
α₁=V_{CM}−V_{S1}−V_{TH} (105)
and
α₂=V_{CM}−V_{S2}−V_{TH} (106)
the equations (99) to (104) may be rewritten to as follows:

$$\begin{matrix}{I}_{D 1} = K {β ( {V}_{in} / 2 + {α}_{1} )}^{2} & ( 107 ) \\ {I}_{D 2} = K {β ( - {V}_{in} / 2 + {α}_{2} )}^{2} & ( 108 ) \\ \begin{matrix}{I}_{D 3} = 2 β \{ {V}_{in} / 2 + {α}_{1} + ( {V}_{S 1} - {V}_{S 0} ) - ( {V}_{S 1} - {V}_{S 0} ) / 2 \} \\ ( {V}_{S 1} - {V}_{S 0} ) \\ = 2 β \{ {V}_{in} / 2 + {α}_{1} + ( {V}_{S 1} - {V}_{S 0} ) / 2 \} ( {V}_{S 1} - {V}_{S 0} )\end{matrix} & ( 109 ) \\ {I}_{D 4} = 2 β \{ {V}_{in} / 2 + {α}_{2} + ( {V}_{S 2} - {V}_{S 0} ) / 2 \} ( {V}_{S 2} - {V}_{S 0} ) & ( 110 ) \\ {I}_{D 5} = β {\{ - {V}_{in} / 2 + {α}_{1} + ( {V}_{S 1} - {V}_{S 0} ) \}}^{2} and & ( 111 ) \\ {I}_{D 6} = 2 β \{ - {V}_{in} / 2 + {α}_{2} + ( {V}_{S 2} - {V}_{S 0} ) / 2 \} ( {V}_{S 2} - {V}_{S 0} ) & ( 112 )\end{matrix}$$

Since
I_{D1}=I_{D3}+I_{D5}
we have
(V_{S1}−V_{S0})²+2α₁(V_{S1}−V_{S0})−α₁Vᵢₙ=0 (113).

Solving the above equation with respect to (V_{S1}−V_{S0}), we have

$${V}_{S 1} - {V}_{S 0} = - {α}_{1} + \sqrt{\frac{1 + K}{2} {α}_{1}^{2} + \frac{1 + K}{2} {α}_{1} {V}_{in} - \frac{1 - K}{8} {V}_{in}^{2}} . \qquad ( 114 )$$

In similar manner, since
I_{D2}=I_{D4}+I_{D6}
we have
(V_{S2}−V_{S0})²+2α₂(V_{S2}−V_{S0})−(−Vᵢₙ/2+α₂)²/2=0 (115).

Solving the above equation with respect to (V_{S2}−V_{S0}), we have

$${V}_{S 1} - {V}_{S 0} = - {α}_{2} + \sqrt{\frac{1 + K}{2} {α}_{1}^{2} - \frac{K}{2} {α}_{2} {V}_{in} + \frac{K}{8} {V}_{in}^{2}} . \qquad ( 116 )$$

Subtracting the equation (116) from the equation (114), we have

$$\sqrt{\frac{1 + K}{2} {α}_{1}^{2} + \frac{1 + K}{2} {α}_{1} {V}_{in} - \frac{1 - K}{8} {V}_{in}^{2}} = \sqrt{\frac{K + 2}{2} {α}_{2}^{2} - \frac{K}{2} {α}_{2} {V}_{in} + \frac{K}{8} {V}_{in}^{2}} \qquad ( 118 )$$

Because
α₁−α₂=−(V_{S1}−V_{S2}) (117).

Squaring both sides of the equation (118), we have

$$\frac{1 + K}{2} {α}_{1}^{2} + \frac{1 + K}{2} {α}_{1} {V}_{in} - \frac{1 - K}{8} {V}_{in}^{2} = \frac{K + 2}{2} {α}_{2}^{2} - \frac{K}{2} {α}_{2} {V}_{in} + \frac{K}{8} {V}_{in}^{2} . \qquad ( 119 )$$

Hence, from the equation (119), we have
(1+K)α₁²+(1+K)Vᵢₙα₁−Vᵢₙ²/4+Kα₂Vᵢₙ−(K+3)α₂²=0 (120)

Solving the above equation with respect to α₁, we have

$${α}_{1} = - \frac{{V}_{in}}{2} + \sqrt{\frac{K + 2}{4 ( K + 1 )} {V}_{in}^{2} - \frac{K}{K + 1} {α}_{2} {V}_{in} + \frac{K + 2}{K + 1} {α}_{2}^{2}} . \qquad ( 121 )$$

From the condition for the tail current,
I_{D1}+I_{D2}=I_{bias}=I₀ (122)
so that, substitution of the equations (107), (108) and (121) in the equation (122) gives

$$\frac{2 K + 3}{K + 1} {α}_{2}^{2} - \frac{2 K + 1}{K + 1} {V}_{in} {α}_{2} + \frac{2 K + 3}{4 ( K + 1 )} {V}_{in}^{2} - \frac{{I}_{0}}{K β} = 0. \qquad ( 123 )$$

Solving the equation (123) with respect to α₁ we have

$${α}_{2} = \frac{2 K + 1}{2 ( 2 K + 3 ) } {V}_{in} + \frac{1}{2 K + 3} \sqrt{\frac{( K + 1 ) ( 2 K + 3 )}{K} \frac{{I}_{0}}{β} - 2 ( K + 1 ) {V}_{in}^{2}} . \qquad ( 124 )$$

Substitution of the equation (124) in the equation (121) gives

$${α}_{1} = - \frac{{V}_{in}}{2} + \sqrt{\begin{matrix}\frac{K + 2}{K ( 2 K + 3 )} \frac{{I}_{0}}{β} + \frac{2 K + 1}{{( 2 K + 3 )}^{2}} {V}_{in}^{2} + \\ \frac{2}{{( 2 K + 3 )}^{2}} {V}_{in} \sqrt{\frac{( K + 1 ) ( 2 K + 3 )}{K} \frac{{I}_{0}}{β} - 2 ( K + 1 ) {V}_{in}^{2}}\end{matrix}} . \qquad ( 125 )$$

α₁ and α₂ have now been found. Thus, I_{D1} and I_{D2} are given by the following equations:

$$\begin{matrix}{I}_{D 1} = \frac{K + 2}{2 K + 3} {I}_{0} + \frac{K ( 2 K + 1 )}{{( 2 K + 3 )}^{2}} β {V}_{in}^{2} + \frac{2 K}{{( 2 K + 3 )}^{2}} β {V}_{in} \sqrt{\frac{( K + 1 ) ( 2 K + 3 )}{K} \frac{{I}_{0}}{β} - 2 ( K + 1 ) {V}_{in}^{2}} and & ( 126 ) \\ {I}_{D 2} = \frac{K + 1}{2 K + 3} {I}_{0} - \frac{K ( 2 K + 1 )}{{( 2 K + 3 )}^{2}} β {V}_{in}^{2} - \frac{2 K}{{( 2 K + 3 )}^{2}} β {V}_{in} \sqrt{\frac{( K + 1 ) ( 2 K + 3 )}{K} \frac{{I}_{0}}{β} - 2 ( K + 1 ) {V}_{in}^{2}} . & ( 127 )\end{matrix}$$

In the transistor M5, the condition which gives V_{DS}=V_{GS}−V_{TH} is

$${V}_{in} = \sqrt{\begin{matrix}\frac{K + 2}{K ( 2 K + 3 )} \frac{{I}_{0}}{β} + \frac{2 K + 1}{{( 2 K + 3 )}^{2}} {V}_{in}^{2} + \\ \frac{2}{{( 2 K + 3 )}^{2}} {V}_{in} \sqrt{\frac{( K + 1 ) ( 2 K + 3 )}{K} \frac{{I}_{0}}{β} - 2 ( K + 1 ) {V}_{in}^{2}}\end{matrix}} \qquad ( 128 )$$

so that, by squaring both sides of the equation (128), we have

$$\frac{2 ( 2 {K}^{2} + 5 K + 4 )}{{( 2 K + 3 )}^{2}} {V}_{i n}^{2} - \frac{K + 2}{K ( 2 K + 3 )} \frac{{I}_{0}}{β} = \frac{2}{{( 2 K + 3 )}^{2}} {V}_{i n} \sqrt{\frac{( K + 1 ) ( 2 K + 3 )}{K} \frac{{I}_{0}}{β} - 2 ( K + 1 ) {V}_{i n}^{2}} . \qquad ( 129 )$$

By squaring both sides of the equation (129) and division by (2K+3)², we have

$$4 ( {K}^{2} + 2 K + 2 ) {V}_{i n}^{4} - \frac{4 ( {K}^{2} + 3 K + 3 ) \}}{K} \frac{{I}_{0}}{β} {V}_{i n}^{2} + \frac{{( K + 2 )}^{2}}{{K}^{2}} \frac{{I}_{0}^{2}}{{β}^{2}} = 0. \qquad ( 130 )$$

Solving the equation (130),

$$\begin{matrix}{V}_{i n}^{2} = \frac{{( K + 2 )}^{2}}{2 K ( {K}^{2} + 2 K + 2 )} \frac{{I}_{0}}{β} , \frac{{I}_{0}}{2 K β} . \\ Hence , & ( 131 ) \\ {V}_{i n} = \pm \frac{K + 2}{\sqrt{2 K ( {K}^{2} + 2 K + 2 )}} \sqrt{\frac{{I}_{0}}{β}} , \pm \sqrt{\frac{{I}_{0}}{2 K β}} . & ( 132 )\end{matrix}$$

Since I_{D1} is continuous, Vᵢₙ for which the equations (92) and (126) become equal to each other is to be found. Thus, we have

$${V}_{i n} = \frac{K + 2}{\sqrt{2 K ( {K}^{2} + 2 K + 2 )}} \sqrt{\frac{{I}_{0}}{β}} . \qquad ( 133 )$$

(3) In case the input voltage is of a high amplitude (Vᵢₙ<0), only the transistor M4 transitions to the operation in the saturation region.

The drain currents may be expressed as follows:
I_{D1}=Kβ(V_{CM}+Vᵢₙ/2−V_{S1}−V_{TH})² (134)
I_{D2}=Kβ(V_{CM}−Vᵢₙ/2−V_{S2}−V_{TH})² (135)
I_{D3}=2β{V_{CM}+Vᵢₙ/2−V_{S0}−V_{TH}−(V_{S1}−V_{S0})/2}(V_{S1}−V_{S0}) (136)
I_{D4}=β{V_{CM}+Vᵢₙ/2−V_{S0}−V_{TH}−(V_{S2}−V_{S0})}² (137)
I_{D5}=2 β{V_{CM}−Vᵢₙ/2−V_{S0}−V_{TH}−(V_{S1}−V_{S0})/2}(V_{S1}−V_{S0}) (138)
and
I_{D6}=2 β{V_{CM}−Vᵢₙ/2−V_{S0}−V_{TH}−(V_{S2}−V_{S0})/2}(V_{S2}−V_{S0}) (139)

If we put
α₁=V_{CM}−V_{S1}−V_{TH} (140)
α₂=V_{CM}−V_{S2}−V_{TH} (141)
the equation (141) may, from the equation (134), be rewritten to as follows.
I_{D1}=Kβ(Vᵢₙ/2+α₁)² (142)
I_{D2}=Kβ(−Vᵢₙ/2+α₂)² (143)
I_{D3}=2β{Vᵢₙ/2+α₁+(V_{S1}−V_{S0})−(V_{S1}−V_{S0})/2}(V_{S1}−V_{S0})=2β{Vᵢₙ/2+α₁+(V_{S1}−V_{S0})/2}(V_{S1}−V_{S0}) (144)
I_{D4}=β{Vᵢₙ/2+α₂+(V_{S2}−V_{S0})}² (145)
I_{D5}=2β{−Vᵢₙ/2+α₁+(V_{S1}−V_{S0})2}(V_{S1}V_{S0}) (146)
and
I_{D6}=2β{−Vᵢₙ/2+α₂+(V_{S2}−V_{S0})/2}(V_{S2}−V_{S0}) (147).

Since I_{D1}=I_{D3}+I_{D5} we have
(V_{S1}−V_{S0})²+2α₁(V_{S1}−V_{S0})−K(Vᵢₙ/2+α₁)²/2=0 (148).

Solving the above equation for V_{S1}−V_{S0}, we have

$${V}_{S 1} - {V}_{S 0} = - {α}_{1} + \sqrt{{α}_{1}^{2} + \frac{K}{2} {( \frac{{V}_{i n}}{2} + {α}_{1} )}^{2}} . \qquad ( 149 )$$

In similar manner, since I_{D2}=I_{D4}+I_{D6}, we have
(V_{S2}−V_{S0})²+2α₂(V_{S2}−V_{S0})+(1−K)Vin²/8+(1+K)α₂Vin/2+(1−K)α₂²/2=0 (150).

Solving the above equation for (V_{S2}−V_{S0}), we have

$${V}_{S 2} - {V}_{S 0} = - {α}_{2} + \sqrt{\frac{K + 1}{2} {α}_{2}^{2} - \frac{K + 1}{2} {α}_{2} {V}_{i n} + \frac{K - 1}{8} {V}_{i n}^{2}} . \qquad ( 151 )$$

Subtracting the equation (151) from the equation (149),
α₁−α₂=−(V_{S1}−V_{S2}) (152)
so that

$$\sqrt{{α}_{i}^{2} + \frac{K}{2} {( \frac{{V}_{i n}}{2} + {α}_{1} )}^{2}} = \sqrt{\begin{matrix}\frac{K + 1}{2} {α}_{2}^{2} - \frac{K + 1}{2} {α}_{2} {V}_{i n} + \\ \frac{K - 1}{8} {V}_{i n}^{2}\end{matrix}} . \qquad ( 153 )$$

By squaring both sides of the equation (153),

$${α}_{1}^{2} + \frac{K}{2} {( \frac{{V}_{i n}}{2} + {α}_{1} )}^{2} = \frac{K + 1}{2} {α}_{2}^{2} - \frac{K + 1}{2} {α}_{2} {V}_{i n} + \frac{K - 1}{8} {V}_{i n}^{2} . \qquad ( 154 )$$

Hence, from the equation (154), we have

$$\frac{K + 1}{2} {α}_{2}^{2} - \frac{K + 1}{2} {α}_{2} {V}_{i n} + \frac{K - 1}{8} {V}_{i n}^{2} - {α}_{1}^{2} - \frac{K}{2} {( \frac{{V}_{i n}}{2} + {α}_{1} )}^{2} = 0. \qquad ( 155 )$$

Solving the above equation for α₂ gives

$${α}_{2} = \frac{1}{2} {V}_{i n} + \sqrt{\frac{K + 2}{4 ( K + 1 )} {V}_{i n}^{2} + \frac{K}{K + 1} {α}_{1} {V}_{i n} + \frac{K + 2}{K + 1} {α}_{1}^{2}} . \qquad ( 156 )$$

From the condition of the tail current,
I_{D1}+I_{D2}=I_{bias}=I₀ (157)
so that, substitution of the equations (142) and (143) in the equation (157) gives

$$\frac{2 K + 3}{K + 1} {α}_{1}^{2} + \frac{2 K + 1}{K + 1} {V}_{i n} {α}_{1} + \frac{2 K + 3}{4 ( K + 1 )} {V}_{i n}^{2} - \frac{{I}_{0}}{K β} = 0. \qquad ( 158 )$$

Solving the above equation with respect to (α₁, we have

$${α}_{1} = - \frac{2 K + 1}{2 ( 2 K + 3 )} {V}_{i n} + \frac{\sqrt{\begin{matrix}\frac{( K + 1 ) ( 2 K + 3 )}{K} \frac{{I}_{0}}{β} - \\ 2 ( K + 1 ) {V}_{i n}^{2}\end{matrix}}}{2 K + 3} . \qquad ( 159 )$$

Substitution of the above equation (159) in the equation (156) gives

$${α}_{2} = \frac{{V}_{i n}}{2} + \sqrt{\begin{matrix}\frac{K + 2}{K ( 2 K + 3 )} \frac{{I}_{0}}{β} + \frac{2 K + 1}{{( 2 K + 3 )}^{2}} {V}_{i n}^{2} - \frac{2}{{( 2 K + 3 )}^{2}} {V}_{i n} \\ \sqrt{\frac{( K + 1 ) ( 2 K + 3 )}{K} \frac{{I}_{0}}{β} - 2 ( K + 1 ) {V}_{i n}^{2}}\end{matrix}} . \qquad ( 160 )$$

α₁ and α₂ have now been determined. Thus, I_{D1} and I_{D2} are

$$\begin{matrix}{I}_{D 1} = \frac{K + 1}{2 K + 3} {I}_{0} - \frac{2 K + 1}{{( 2 K + 3 )}^{2}} β {V}_{i n}^{2} + \frac{2}{{( 2 K + 3 )}^{2}} β {V}_{i n} \sqrt{\begin{matrix}\frac{( K + 1 ) ( 2 K + 3 )}{K} \frac{{I}_{0}}{β} - \\ 2 ( K + 1 ) {V}_{i n}^{2}\end{matrix}} , \\ and & ( 161 ) \\ {I}_{D 2} = \frac{K + 2}{2 K + 3} {I}_{0} + \frac{2 K + 1}{{( 2 K + 3 )}^{2}} β {V}_{i n}^{2} - \frac{2}{{( 2 K + 3 )}^{2}} β {V}_{i n} \sqrt{\begin{matrix}\frac{( K + 1 ) ( 2 K + 3 )}{K} \frac{{I}_{0}}{β} - \\ 2 ( K + 1 ) {V}_{i n}^{2}\end{matrix}} & ( 162 )\end{matrix}$$

respectively.

In the transistor M4, the condition for V_{DS}=V_{GS}−V_{TH} is

$$- {V}_{i n} = \sqrt{\begin{matrix}\frac{K + 2}{K ( 2 K + 3 )} \frac{{I}_{0}}{β} + \frac{2 K + 1}{{( 2 K + 3 )}^{2}} {V}_{i n}^{2} - \frac{2}{{( 2 K + 3 )}^{2}} {V}_{i n} \\ \sqrt{\frac{( K + 1 ) ( 2 K + 3 )}{K} \frac{{I}_{0}}{β} - 2 ( K + 1 ) {V}_{i n}^{2}}\end{matrix}} . \qquad ( 163 )$$

Thus, squaring both sides of the equation (163), we have

$$\frac{K + 2}{K ( 2 K + 3 )} \frac{{I}_{0}}{β} - \frac{2 ( 2 {K}^{2} + 5 K + 4 )}{{( 2 K + 3 )}^{2}} {V}_{i n}^{2} = \frac{2}{{( 2 K + 3 )}^{2}} {V}_{i n} \sqrt{\begin{matrix}\frac{( K + 1 ) ( 2 K + 3 )}{K} \frac{{I}_{0}}{β} - \\ 2 ( K + 1 ) {V}_{i n}^{2}\end{matrix}} . \qquad ( 164 )$$

By further squaring both sides of the equation (164) and the division by (2K+3)²,

$$4 ( {K}^{2} + 2 K + 2 ) {V}_{i n}^{4} - \frac{4 ( {K}^{2} + 3 K + 3 ) \}}{K} \frac{{I}_{0}}{β} {V}_{i n}^{2} + \frac{{( K + 2 )}^{2}}{{K}^{2}} \frac{{I}_{0}^{2}}{{β}^{2}} = 0. \qquad ( 165 )$$

Solving the equation (165), we have

$${V}_{i n}^{2} = \frac{{( K + 2 )}^{2}}{2 K ( {K}^{2} + 2 K + 2 )} \frac{{I}_{0}}{β} , \frac{{I}_{0}}{2 K β} . \qquad ( 166 )$$

Hence, we have

$${V}_{i n} = \pm \frac{K + 2}{\sqrt{2 K ( {K}^{2} + 2 K + 2 )}} \sqrt{\frac{{I}_{0}}{β}} , \pm \sqrt{\frac{{I}_{0}}{2 K β}} . \qquad ( 167 )$$

Since I_{D1} is continuous, Vᵢₙ for which the equations (92) and (126) become equal to each other is given by

$${V}_{i n} = - \frac{K + 2}{\sqrt{2 K ( {K}^{2} + 2 K + 2 )}} \sqrt{\frac{{I}_{0}}{β}} . \qquad ( 168 )$$

It should be noted however that the values of I_{D1} and I_{D2} solved under the condition of K=1 and under the conditions (2) and (3) become approximately equal to the values solved under the condition of K=1 and under the condition (1), such that transconductance having equi-ripple characteristic, as shown in FIG. 11B, may not be obtained. That is, the values of I_{D1} and I_{D2} are those represented by the equations (97) and (98) and the actual linearity is equivalent to that of the MOS differential pair. This may be confirmed from values of the SPICE simulation.

On the other hand, V. Pendanov (U.S. Pat. No. 6,577,170B1) states that K is to be 2 (K=2). However, with this value, linearity may scarcely be improved.

That is, Patent Document 2 (U.S. Pat. No. 6,577,170 B1) contains only insufficient technical disclosure and cannot be said to have disclosed a differential circuit improved in linearity.

The above-described conventional circuit suffers the following problems:

The first problem is insufficient linearity. The reason for this is that, in the Krummenacher and Johel circuit, the operating range of the transistor transitions from the linear region to the saturation region responsive to an input voltage.

The second problem is that the control circuit is large in size and it is difficult to carry out a low voltage operation. The reason is that an inverting amplifier is included in an input stage of the Toyoda OTA circuit.

The third problem is difficulty in use. The reason is that the OTA circuit by Kim² and Park delivers a class AB output.

It is therefore an object of the present invention to provide a circuit that realizes a high linearity OTA circuit operated in class A operation.

It is another object of the present invention to provide a circuit improved in output current efficiency.

According to the first aspect of the present invention (claim 1), there is provided a differential circuit that includes:

a first transistor pair (first and second transistors) supplied with differential input signal;

a third transistor supplied with a common mode voltage of the differential input signal and connected to a constant current source as a load;

an inverting amplifier supplied with an output signal of the third transistor,

the third transistor having its source connected to the sources of the first and second transistors; and

a second transistor pair (fourth and fifth transistors) connected in parallel with the first transistor pair (first and second transistors) and supplied with an output signal of the inverting amplifier. The coupled drains of the first and second transistor pairs constitute a differential output, and the coupled sources of the first to fifth transistors are driven by another constant current source.

In a differential circuit according to the second aspect of the present invention (claim 2), the inverting amplifier is constituted by a sixth transistor having a constant current source as a load.

A differential circuit according to the third aspect of the present invention (claim 3) includes:

a first transistor pair (first and second transistors) supplied with differential input signal;

a second transistor pair (third and fourth transistors) supplied with the differential input signal and connected in parallel with outputs of the first transistor pair (first and second transistors); and

a third transistor pair (fifth and sixth transistors) cascode-connected to said second transistor pair (third and fourth transistors) so that the differential signal supplied to the gates of the third transistor pair is reverse phased with respect to the differential input signal supplied to the gates of said second transistor pair (third and fourth transistors). The coupled sources of the first and third transistor pairs (first, second, fifth and sixth transistors) are driven by a constant current source.

A differential circuit according to the fourth aspect of the present invention (claim 4) includes:

a first transistor pair (first and second transistors) supplied with differential input signal;

a second transistor pair (third and fourth transistors) supplied with the differential input signal and connected in parallel with outputs of the first transistor pair (first and second transistors);

a third transistor pair (fifth and sixth transistors) supplied with the differential input signal and cross-coupled to outputs of the first transistor pair (first and second transistors); and

a fourth transistor pair (seventh and eighth transistors) cascode-connected to the third transistor pair so that the differential input signal supplied to the gates of the fourth transistor pair is reverse-phased to the differential input signal supplied to the gates of the first, second and third transistor pairs. The sources of the second and third transistor pairs are coupled together and the coupled sources of the first and fourth transistor pair (first, second, seventh and eighth transistors) are driven by a constant current source.

A differential circuit according to the fifth aspect of the present invention (claim 5) includes:

a first transistor pair (first and second transistors) supplied with differential input signal; and

a second transistor pair (third and fourth transistors), supplied with a common mode signal of said differential input signal and connected in parallel with outputs of the first transistor pair (first and second transistors). The sources of the third and fourth transistors are connected together.

The differential circuit further includes:

a third transistor pair (fifth and sixth transistors) supplied with said differential input signal and cascode-connected to the second transistor pair (third and fourth transistors);

a fourth transistor pair (seventh and eighth transistors) supplied with said differential input signal and cascode-connected to the third transistor pair so that the differential input signal supplied to the gates of the fourth transistor pair is reverse-phased with respect to the differential input signal supplied to the gates of said third transistor pair (fifth and sixth transistors). The coupled sources of the first and fourth transistor pair (first, second, seventh and eighth transistors) are driven by a constant current source.

A differential circuit according to the sixth aspect of the present invention (claim 6) includes:

a first transistor pair (first and second transistors) supplied with differential input signal;

a second transistor pair (third and fourth transistors) supplied with the differential input signal and connected in parallel with outputs of the first transistor pair (first and second transistors);

a third transistor pair (fifth and sixth transistors) supplied with the differential input signal and cross-coupled to the outputs of said first transistor pair (first and second transistors);

a fourth transistor pair (seventh and eighth transistors) supplied with the differential input signal; and

a fifth transistor pair (ninth and tenth transistors) also supplied with the differential input signal and having sources coupled together. The first, second and third transistor pairs are cascode-connected to the fourth transistor pair so that the input signal to the gates of the fourth transistor pair is reverse phased to the input signal supplied to the gates of the first, second and third transistor pairs. The fourth transistor pair is cascode-connected to the fifth transistor pair so that the input signal to the gates of the fourth transistor pair is reverse phased to the input signal to the gates of the fifth transistor pair. The coupled sources of the first and fifth transistor pairs (first, second, ninth and tenth transistors) are driven by a constant current source.

A differential circuit according to the seventh aspect of the present invention (claim 7) includes:

a first transistor pair (first and second transistors) supplied with the differential input signal;

a second transistor pair (third and fourth transistors) supplied with the differential input signal and connected in parallel with outputs of the first transistor pair (first and second transistors);

a third transistor pair (fifth and sixth transistors) supplied with the differential input signal and cross-coupled to outputs of said first transistor pair (first and second transistors). The sources of the second and third transistor pairs (third, fourth, fifth and sixth transistors) are coupled together. The differential circuit also includes:

a fourth transistor pair (seventh and eighth transistors), supplied with the differential input signal, and cascode-connected to the third transistor pair; and

a fifth transistor pair (ninth and tenth transistors), also supplied with the differential input signal, and cascode-connected to the fourth transistor pair (seventh and eighth transistors) so that the differential input signal to the gates of the fifth transistor pair is reverse-phased with respect to the differential input signal supplied to the gates of said fourth transistor pair (seventh and eighth transistors). The coupled sources of the first and fifth transistor pairs (first, second, ninth and tenth transistors) are driven by a constant current source.

A differential circuit according to the eighth aspect of the present invention (claim 8) includes:

a first transistor pair (first and second transistors) supplied with the differential input signal;

a second transistor pair (third and fourth transistors) supplied with a common mode signal of the differential input signal and connected in parallel with outputs of the first transistor pair (first and second transistors). The sources of the third and fourth transistor pairs are connected together. The differential circuit also includes:

a third transistor pair (fifth and sixth transistors), supplied with the differential input signal, and cascode-connected to the second transistor pair (third and fourth transistors);

a fourth transistor pair (seventh and eighth transistors), supplied with the differential input signal, and connected to the third transistor pair (fifth and sixth transistors) in cascode, so that the differential input signal supplied to the gates of the fourth transistor pair is reverse-phased with respect to the differential input signal supplied to the gates of said third transistor pair (fifth and sixth transistors); and

a fifth transistor pair (ninth and tenth transistors), supplied with the differential input signal, and connected to the fourth transistor pair (seventh and eighth transistors) in cascode, so that the differential input signal supplied to the gates of the fifth transistor pair (ninth and tenth transistors) is reverse-phased with respect to the differential input signal supplied to the gates of said fourth transistor pair (seventh and eighth transistors). The coupled sources of the first and fifth transistor pairs (first, second, ninth and tenth transistors) are driven by a constant current source.

A differential circuit according to the ninth aspect of the present invention (claim 9) includes:

a first transistor pair (first and second transistors) supplied with the differential input signal;

a second transistor pair (third and fourth transistors) supplied with the differential input signal and connected in parallel with outputs of the first transistor pair (first and second transistors);

a third transistor pair (fifth and sixth transistors) supplied with the differential input signal and cross-coupled to outputs of the first transistor pair;

a fourth transistor pair (seventh and eighth transistors) supplied with the differential input signal; and

a fifth transistor pair (ninth and tenth transistors) also supplied with the differential input signal and having sources coupled together. The first, second and third transistor pairs are cascode-connected to the fourth transistor pair so that the input signal to the gates of the fourth transistor pair is reverse-phased with respect to the input signal supplied to the gates of the first, second and third transistor pairs. The fourth transistor pair is cascode-connected to the fifth transistor pair so that the input signal to the gates of the fourth transistor pair is reverse-phased with respect to the input signal supplied to the gates of the fifth transistor pair. The coupled sources of the first and fifth transistor pairs (first, second, ninth and tenth transistors) are driven by a constant current source.

A differential circuit according to the tenth aspect of the present invention (claim 10) includes:

a first transistor pair (first and second transistors) supplied with the differential input signal;

a second transistor pair (third and fourth transistors) supplied with the differential input signal and connected in parallel with outputs of the first transistor pair (first and second transistors);

a third transistor pair (fifth and sixth transistors) supplied with the differential input signal and cross-coupled to outputs of said first transistor pair (first and second transistors). The sources of the second and third transistor pairs (third, fourth, fifth and sixth transistors) are coupled together. The differential circuit also includes:

a fourth transistor pair (seventh and eighth transistors), supplied with the differential input signal, and cascode-connected to the third transistor pair; and

a fifth transistor pair (ninth and tenth transistors), also supplied with the differential input signal, and cascode-connected to the fourth transistor pair (seventh and eighth transistors) so that the differential input signal to the gates of the fifth transistor pair is reverse-phased with respect to the differential input signal supplied to the gates of said fourth transistor pair (seventh and eighth transistors). The coupled sources of the first and fifth transistor pairs (first, second, ninth and tenth transistors) are driven by a constant current source.

In a differential circuit according to an eleventh aspect of the present invention (claim 11), one or more transistor pairs above the fifth transistor pair are sequentially cascode-connected so that relating plural cascode-connected transistor pairs, in case one of two neighboring transistor pairs cascode-connected upside down, respectively, receives the differential input signal, the other transistor pair receives the differential input signal in reverse phase, and the coupled sources of said first transistor pair and the coupled sources of the transistor pair located at the top among said plural cascode connected transistor pairs are connected, and the coupled sources are driven by a constant current source.

According to a twelfth aspect of the present invention (claim 12), for a differential circuit comprising:

a first transistor pair (first and second transistors) supplied with the differential input signal;

a second transistor pair (third and fourth transistors) supplied with the differential input signal and cascode-connected below the first transistor pair (first and second transistors); and

a third transistor pair (fifth and sixth transistors) supplied with the differential input signal and connected in parallel with the second transistor pair so that the output of the third transistor pair is reversed to the output of the second transistor pair (third and fourth transistors). The coupled sources of the second and third transistors (second, third, fifth and sixth transistors) are driven by a constant current source and the transistor size of the first transistor pair (first and second transistors) is thrice or four times as large as that of the second transistor pair (third and fourth transistors).

In a differential circuit according to the thirteenth aspect of the present invention (claim 13), the transistor size of the third transistor pair (fifth and sixth transistors) is smaller than that of the second transistor pair (third and fourth transistors) and is approximately 1 or ⅓ times the size of the second transistor pair (third and fourth transistors).

The meritorious effects of the present invention are summarized as follows.

The meritorious effect of the present invention is that the linearity of the differential circuit may be improved. The reason is that in the present invention, the operation close to that of the class A operation has been implemented.

The another meritorious effect of the present invention is that the output current efficiency of the differential circuit may be improved. The reason is that in the present invention a constant current is distributed and summed to a parabolic current that conforms to the positive phase input and the negative phase input and to the square current that decreases responsive to the increase in the amplitude value of the input voltage.

Still other features and advantages of the present invention will become readily apparent to those skilled in this art from the following detailed description in conjunction with the accompanying drawings wherein examples of the invention are shown and described, simply by way of illustration of the mode contemplated of carrying out this invention. As will be realized, the invention is capable of other and different examples, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIGS. 1A and 1B are diagrams showing the constitution of a conventional circuit stated in a related Non-Patent Document.

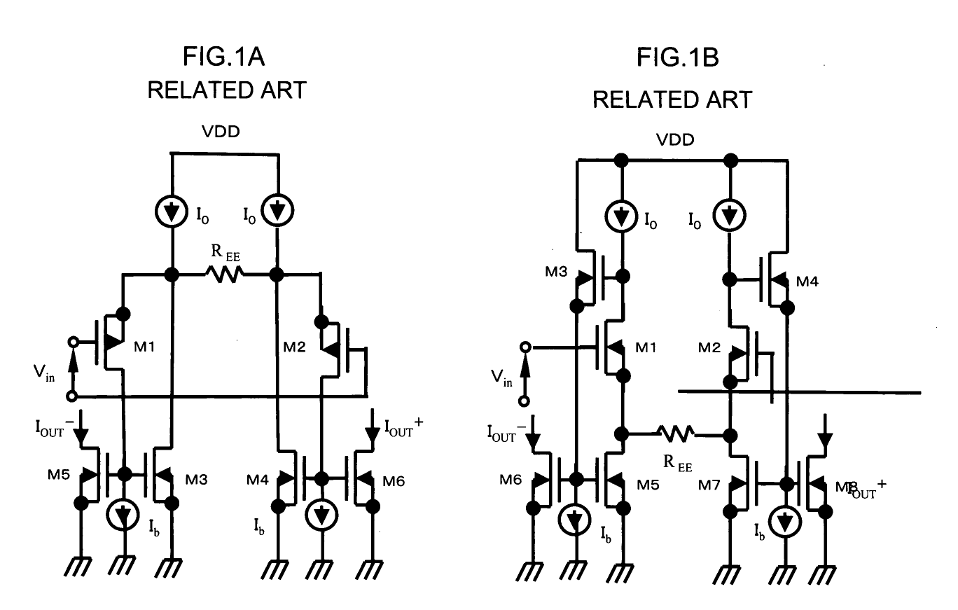

FIG. 2 is a graph showing characteristic of the conventional circuit stated in the related Non-Patent Document.

FIGS. 3A and 3B are graphs showing other characteristic of a conventional circuit stated in a related Patent Document.

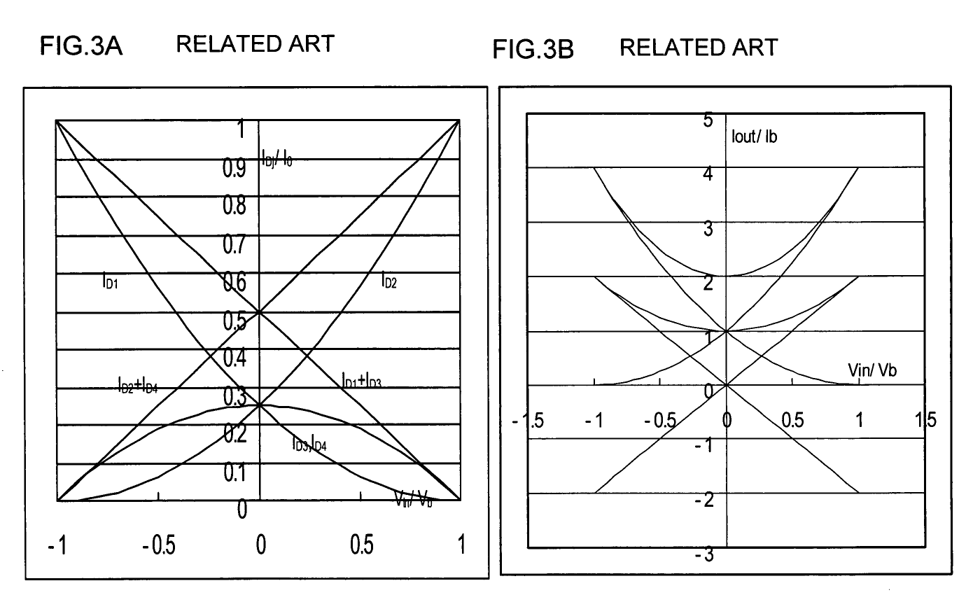

FIGS. 4A and 4B are diagrams showing an illustrative constitution of another conventional circuit stated in the related Non-Patent Document.

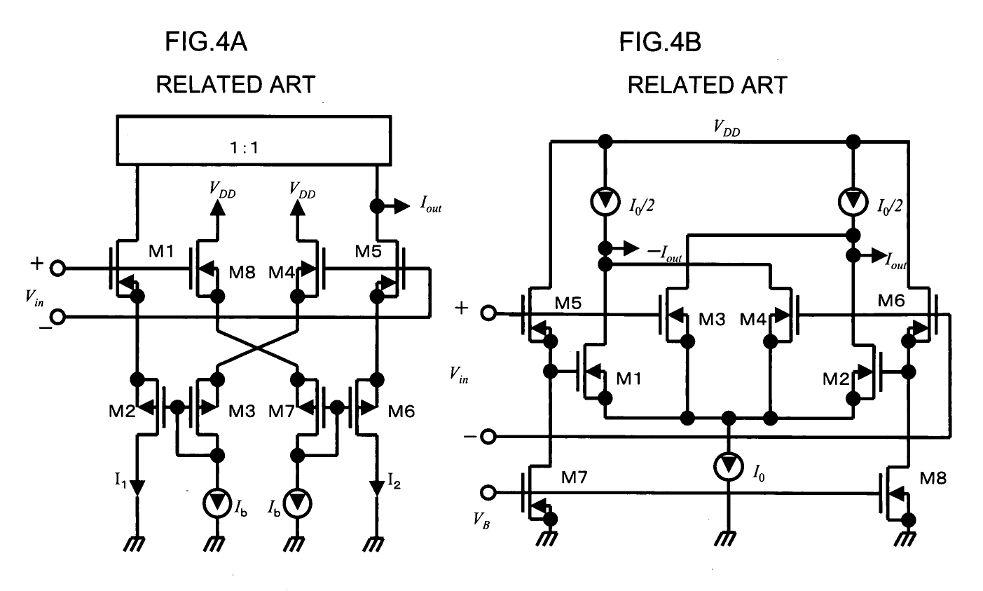

FIG. 5A is a diagram showing another conventional circuit stated in the Non-Patent Document and FIG. 5B is a graph showing characteristic thereof.

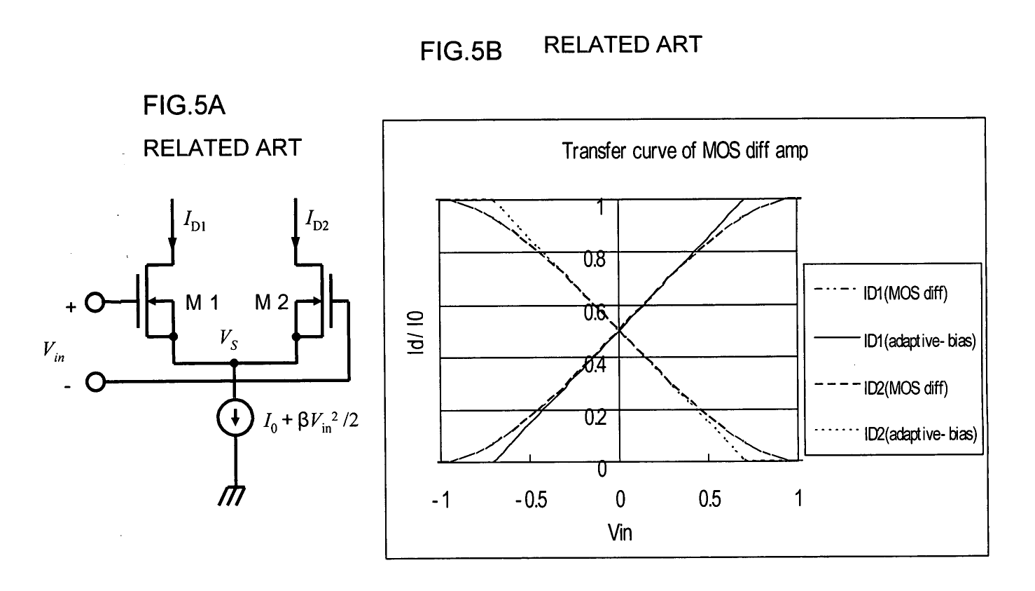

FIG. 6 is a diagram showing an illustrative constitution of the other conventional circuit stated in the related Non-Patent Document.

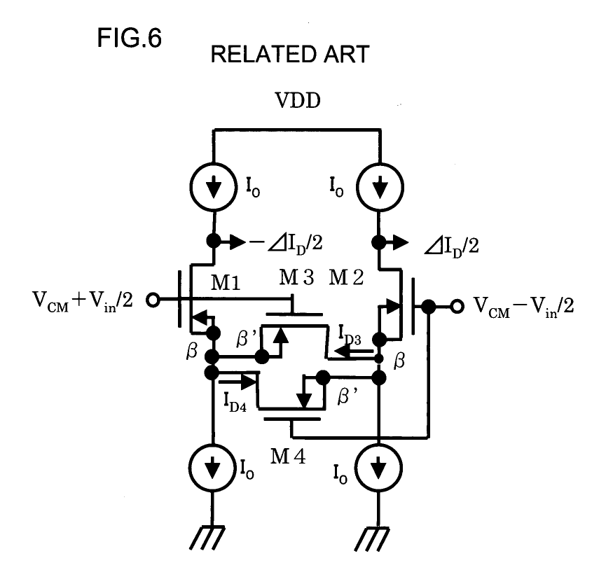

FIGS. 7A and 7B are graphs showing characteristic of the other conventional circuit stated in the related Patent Document.

FIG. 8 shows a diagram showing an illustrative constitution of another conventional circuit stated in a related Patent Document.

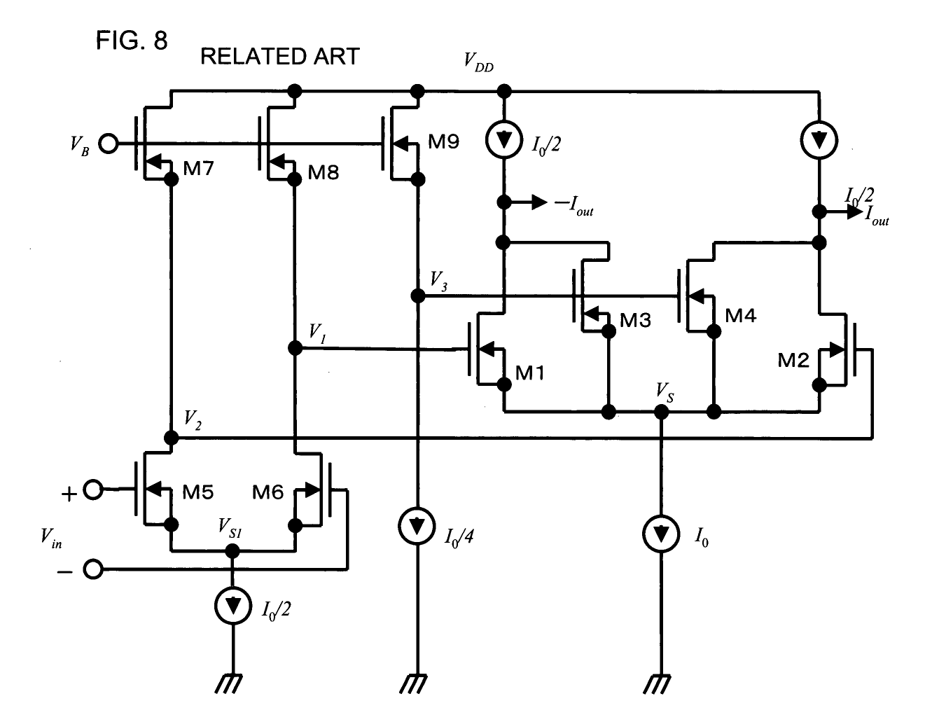

FIG. 9 is a graph showing characteristic of the illustrative constitution of the other conventional circuit stated in a related Patent Document.

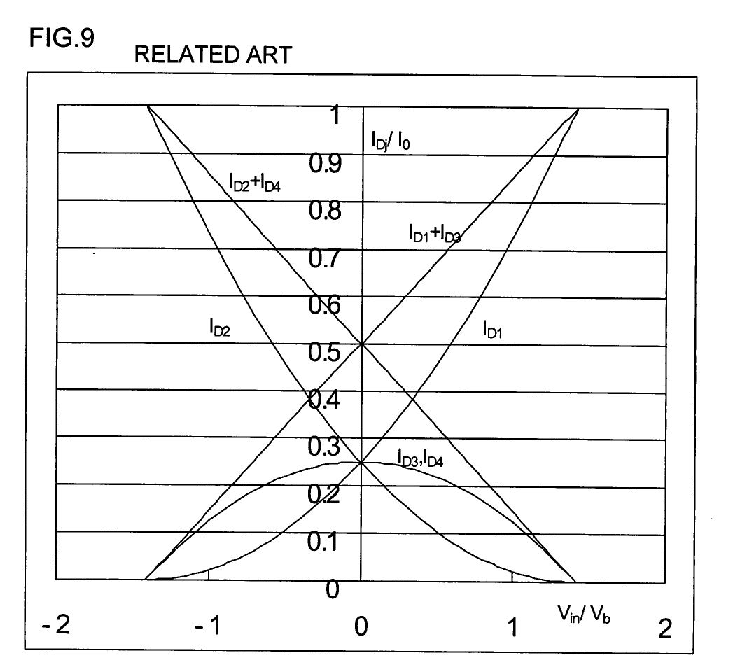

FIG. 10 is a diagram showing an illustrative constitution of a further conventional circuit stated in a related Non-Patent Document.

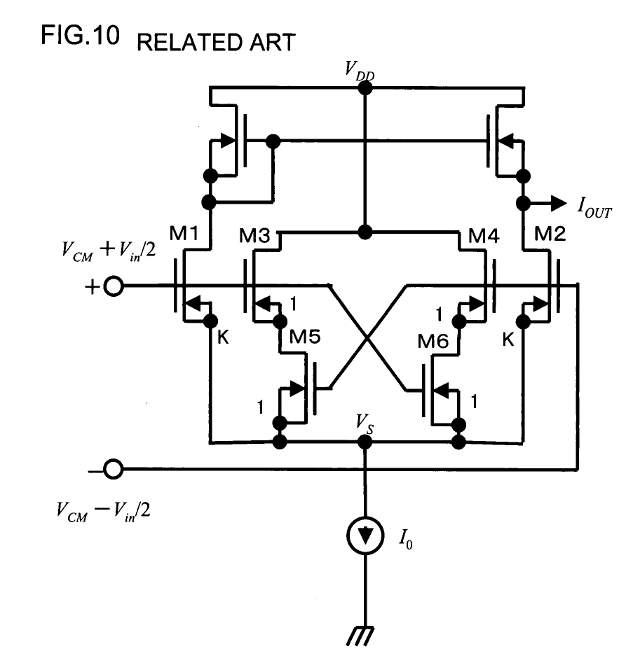

FIG. 11A is a diagram showing an illustrative constitution of a further conventional circuit stated in a related Non-Patent Document and FIG. 11B is a graph showing characteristic thereof.

FIG. 12 is a diagram showing a circuit configuration of an embodiment of the present invention (claim 1).

FIG. 13 is a graph showing current characteristic of the embodiment of the present invention (claim 1).

FIG. 14 is a diagram showing a circuit configuration of another embodiment of the present invention (claim 2).

FIG. 15 is a graph showing the results of SPICE simulation of the embodiment of the present invention (claim 2).

FIG. 16 is a diagram showing a circuit configuration of another embodiment of the present invention (claim 3).

FIG. 17 is a graph showing the results of SPICE simulation of the embodiment of the present invention (claim 3).

FIG. 18 is a graph showing current characteristic of a further embodiment of the present invention (claim 3).

FIG. 19 is a diagram showing a circuit configuration of another embodiment of the present invention (claim 4).

FIG. 20 is a graph showing the results of SPICE simulation of the embodiment of the present invention (claim 4).

FIG. 21 is a diagram showing a circuit configuration of a further embodiment of the present invention (claim 5).

FIGS. 22A, 22B, 22C and 22D are graphs showing the results of circuit analyses of the further embodiment of the present invention (claim 5).

FIGS. 23A and 23B are diagrams for illustrating the Toyoda OTA circuit and the embodiment of the present invention (claim 5).

FIG. 24 is a graph showing current characteristic of the circuit of the embodiment of the present invention (claim 5).

FIG. 25 is a graph showing first SPICE simulation values of the circuit of the further embodiment of the present invention (claim 5).

FIG. 26 is a graph showing second SPICE simulation values of the circuit of the embodiment of the present invention (claim 5).

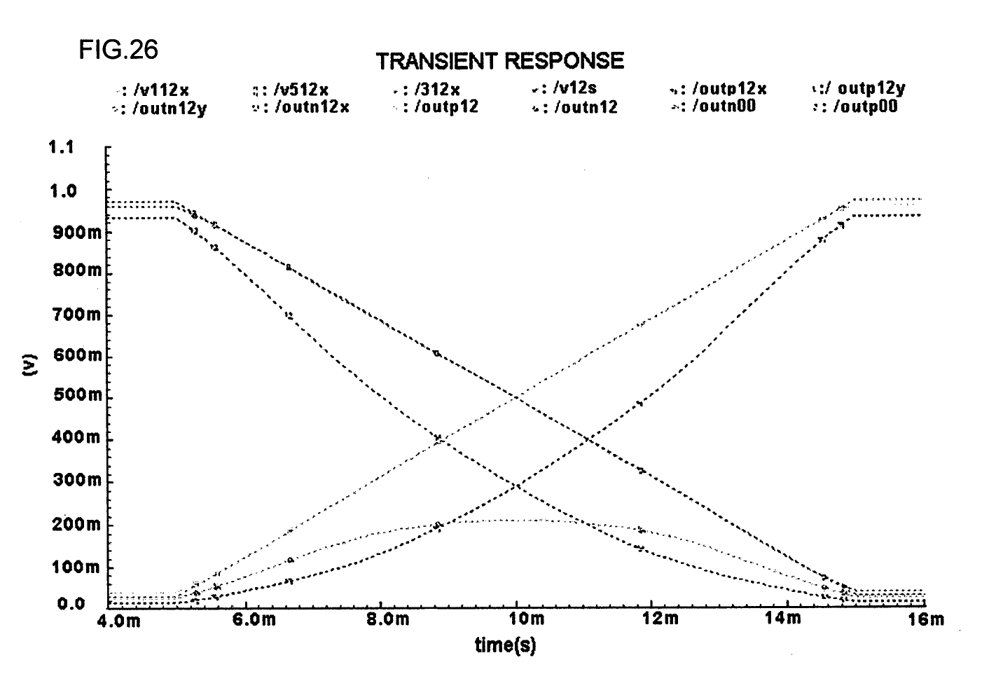

FIG. 27 is a diagram showing the circuit configuration of a further embodiment of the present invention (claim 6).

FIG. 28 is a graph showing the results of SPICE simulation of the circuit of the embodiment of the present invention (claim 6).

FIG. 29 is a diagram showing the circuit configuration of a further embodiment of the present invention (claim 7).

FIG. 30 is a graph showing the results of SPICE simulation of the circuit of the embodiment of the present invention (claim 7).

FIG. 31 is a diagram showing the circuit configuration of a further embodiment of the present invention (claim 8).

FIG. 32 is a graph showing the results of SPICE simulation of the circuit of the embodiment of the present invention (claim 8).

FIG. 33 is a diagram showing the circuit configuration of a further embodiment of the present invention (claim 9).

FIG. 34 is a graph showing the results of SPICE simulation of the circuit of the embodiment of the present invention (claim 9).

FIG. 35 is a diagram showing the circuit configuration of a further embodiment of the present invention (claim 10).

FIG. 36 is a graph showing the results of SPICE simulation of the circuit of the embodiment of the present invention (claim 10).

FIG. 37 is a diagram showing the circuit configuration of a further embodiment of the present invention (claim 12).

FIG. 38 is a graph showing input/output characteristic (calculated values) of the embodiment of the present invention (claim 12).

FIG. 39 is a graph showing transconductance characteristic (calculated values) of the embodiment of the present invention (claim 12).

### PREFERRED MODES OF THE INVENTION

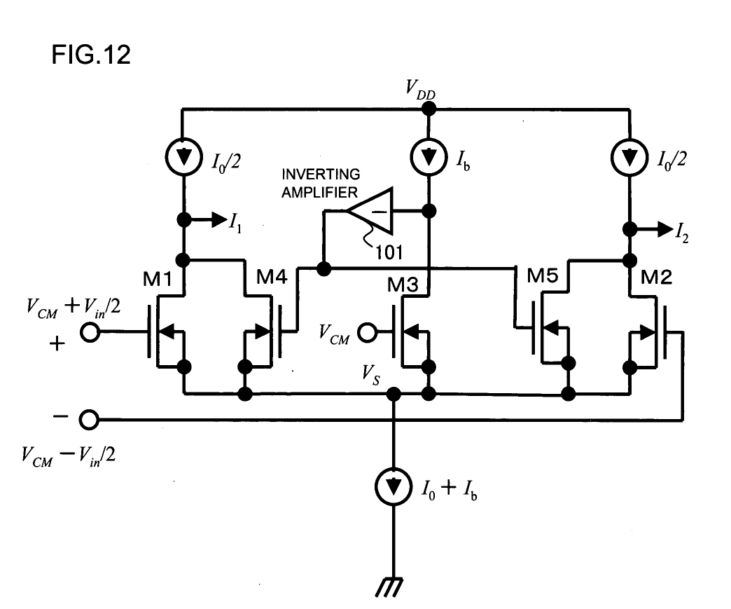

Examples of the present invention are now described with reference to the accompanying drawings. FIG. 12 depicts a diagram showing the circuit configuration of a differential circuit according to an embodiment of the present invention.

Referring to FIG. 12, NMOS transistors M1 and M2 constitute a first transistor pair. To the gates of the transistors M1 and M2 is supplied a differential input signal (V_{CM}+Vᵢₙ/2, V_{CM}−Vᵢₙ/2). Vᵢₙ is an input signal voltage supplied differentially across a non-inverting input terminal (+) and an inverting input terminal (−) and V_{CM} is a common mode voltage of the differential input signal Vᵢₙ. There is provided an NMOS transistor M3 that has a gate supplied with the common mode voltage V_{CM} of the differential input signal Vᵢₙ. To the drain of the NMOS transistor M3 is connected a constant current source I_{b} as a load. The drain of the NMOS transistor M3 is connected to an input end of an inverting amplifier 101, an output end of which is connected to the gates of the NMOS transistors M4 and M5 that constitute a second transistor pair. Outputs of the first transistor pair (M1, M2) and the second transistor pair (M4, M5) are connected in parallel to constitute a differential output pair. That is, coupled drains of the transistors M1 and M4 and coupled drains of the transistors M2 and M5 constitute a differential output pair.

The sources of the first and second transistor pairs (M1, M2) and (M4, M5) and the transistor M3 are coupled together and driven by a constant current source (Iₒ+I_{b}).

The operation of the present embodiment is now described. In FIG. 12, since the transistor M3 is driven by the constant current I_{b}, the gate-to-source voltage V_{GS3} is constant. Since the common mode voltage V_{CM} is applied to the gate, the voltage Vₛ of coupled sources is constant.

Let the transistor sizes of the first transistor pair (M1, M2) and the transistor M3 be equal to one another, and let the constant current I_{b} driving the transistor M3 be equal to one-fifth of the constant current source (I₀+I_{b}) that drive the first and second transistor pairs (M1, M2) and (M4, M5) and the transistor M3. Then,

$$\begin{matrix}{I}_{b} = {I}_{0} / 4 & ( 169 ) \\ so that {V}_{S} = {V}_{CM} - \frac{1}{2} \sqrt{\frac{{I}_{0}}{β}} . & ( 170 )\end{matrix}$$

where β is a transconductance parameter of the MOS transistor.

The drain currents of the paired transistors (M1, M2) may be expressed by:

$$\begin{matrix}\begin{matrix}{I}_{D 1} = {β ( {V}_{CM} + \frac{{V}_{i n}}{2} - {V}_{S} - {V}_{TH} )}^{2} \\ = {β ( \frac{{V}_{i n}}{2} + \frac{1}{2} \sqrt{\frac{{I}_{0}}{β}} )}^{2} \\ = \frac{{I}_{0}}{4} + \frac{1}{2} \sqrt{β {I}_{0}} {V}_{i n} + β \frac{{V}_{i n}^{2}}{4}\end{matrix} \\ and & ( 171 ) \\ \begin{matrix}{I}_{D 2} = {β ( {V}_{CM} - \frac{{V}_{i n}}{2} - {V}_{S} - {V}_{TH} )}^{2} \\ = {β ( - \frac{{V}_{i n}}{2} + \frac{1}{2} \sqrt{\frac{{I}_{0}}{β}} )}^{2} \\ = \frac{{I}_{0}}{4} - \frac{1}{2} \sqrt{β {I}_{0}} {V}_{i n} + β \frac{{V}_{i n}^{2}}{4} .\end{matrix} & ( 172 )\end{matrix}$$

The inverting amplifier 101 operates to maintain the equation (66) and divides the remaining current ((Iₐ+I_{b})−I_{D1}−I_{D2}−I_{D3}) from the constant current source (Iₐ+I_{b}) (=5I/4) into two parts for respective transistors (M4, M5) of the second transistor pair.

Hence, we have

$${I}_{D 4} = {I}_{D 5} = \frac{1}{2} ( \frac{5 {I}_{0}}{4} - {I}_{D 1} - {I}_{D 2} - {I}_{D 3} ) = \frac{{I}_{0}}{4} - β \frac{{V}_{i n}^{2}}{4} \qquad ( 173 )$$

without regard to the sizes of the transistors M4 and M5.

$$\begin{matrix}Hence , \\ {I}_{1} = \frac{{I}_{0}}{2} - ( {I}_{D 1} + {I}_{D 4} ) = - \frac{1}{2} \sqrt{β {I}_{0}} {V}_{i n} \\ and & ( 174 ) \\ {I}_{2} = \frac{{I}_{0}}{2} - ( {I}_{D 2} + {I}_{D 5} ) = \frac{1}{2} \sqrt{β {I}_{0}} {V}_{i n} . & ( 175 )\end{matrix}$$

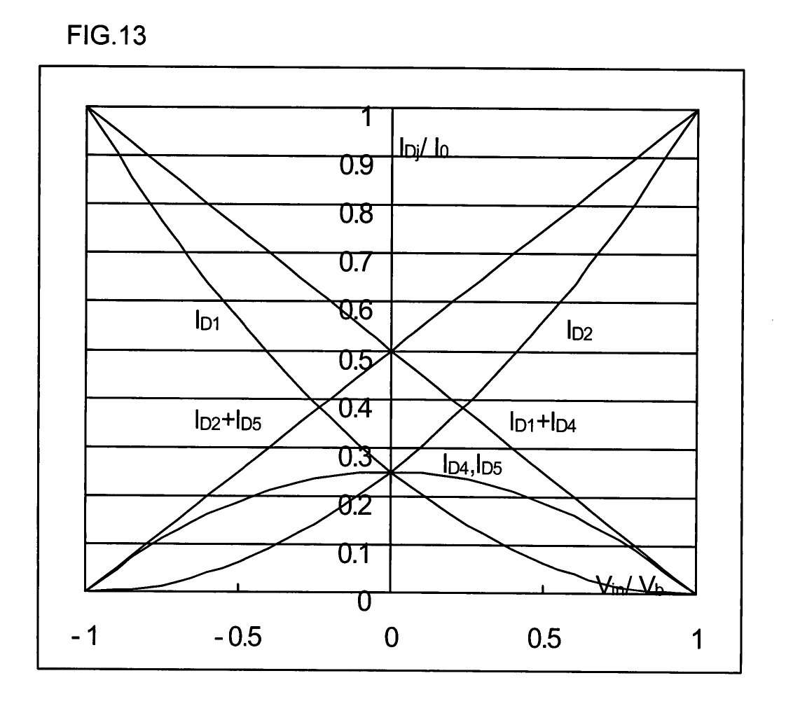

The drain currents ID1 to ID5 of the transistors M1 to M5 are shown in FIG. 13. A linear OTA performing a class A operation, is obtained, as shown in FIG. 13 showing the input/output characteristic of Vin/Vb (abscissa) and ID1+ID4 (=I1) as well as ID2+ID5 (=I2), provided, that V_{b}=\sqrt{I₀/β}/2.

### FIRST EXAMPLE

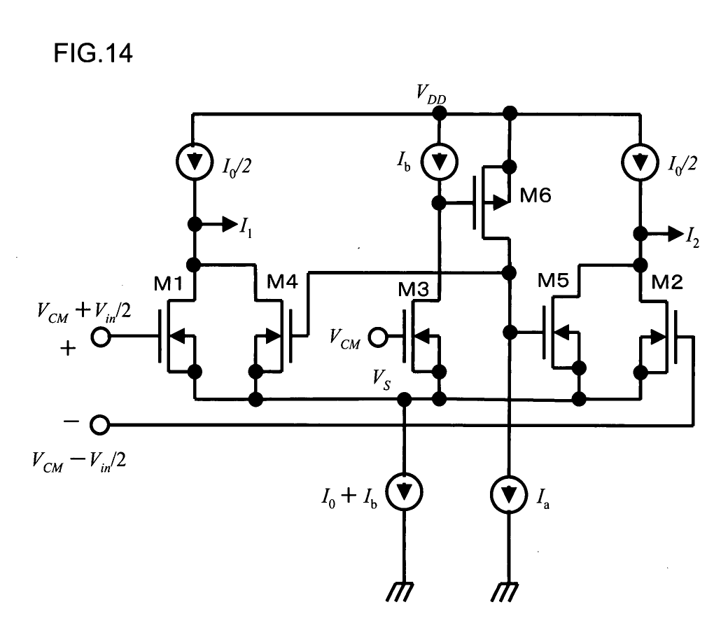

FIG. 14 shows a circuit configuration of an example of a differential circuit corresponding of the present invention (corresponding to claim 2). In FIG. 14, the inverting amplifier 101 of FIG. 12 includes a PMOS transistor M6 and a constant current source Iₐ that operates as its load. The source of the PMOS transistor M6 is connected to a power supply VDD, while its drain is connected to the gates of the NMOS transistors M4 and M5 and to one end of the constant current source Iₐ, the other end of which is connected to GND. The gate of the PMOS transistor M6 is connected to the drain of the NMOS transistor M3.

The operation of the present example is now described. In FIG. 14, the PMOS transistor M6 and the constant current source Iₐ, operating as its load, make up an inverting amplifier that controls the gate voltage of the paired transistors (M4, M5) so that the current flowing through the transistor M3 will be I_{b} at all times.

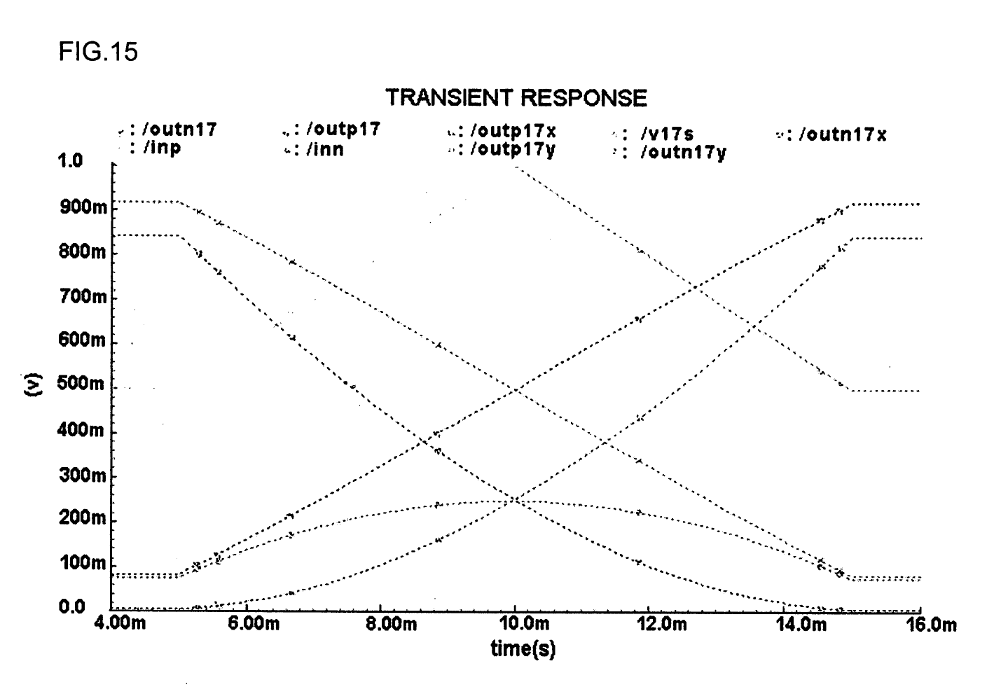

Hence, the remaining current of the constant current source (Iₒ+I_{b}) (=5Iₒ/4) is divided into two portions for the paired transistors (M4, M5). Thus, the drain currents, shown by the equations (67) to (69), flow through the respective transistors, thus generating a linear differential current, as shown in FIG. 15.

SPICE simulation was carried out to confirm the characteristic of the circuit. Here, device parameters of the 0.35 μm rule are used. It is noted that, to reduce the substrate effect, a P-ch transistor, whose back gate and source are connected, is used. Iₒ=100 μA, I_{b1}=I_{b2}=25 μA, and W/L of each transistor is set to 10 μm/2 μm.

Here, TRAN (transient) analysis was conducted and, as a differential input voltage, the voltage was linearly changed from 0.5V@5 mS to 1.5V@15 mS on the (+) side input terminal and from 1.5V@5 mS to 0.5V@15 mS on the (−) side input terminal. The current was converted via 10 kΩ resistor into a voltage, which is illustrated.

It may be seen that the output current characteristic is overlapped with a straight line shown.

### SECOND EXAMPLE

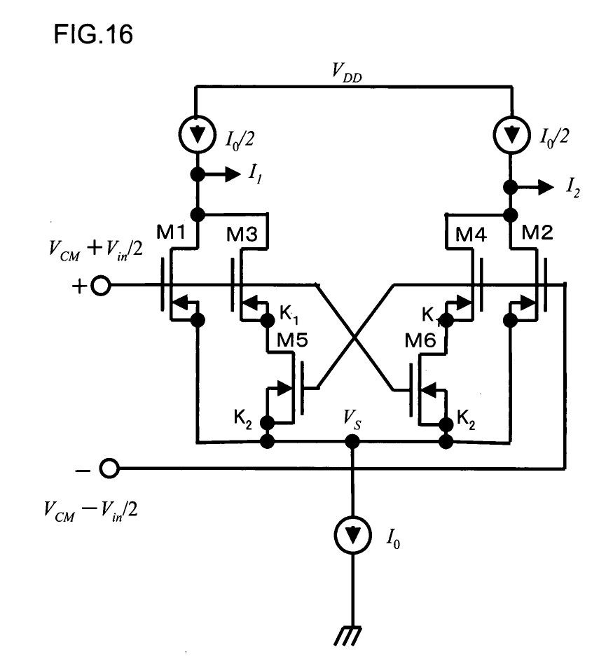

FIG. 16 shows a circuit configuration of an example of a differential circuit of the present invention (corresponding to claim 3). Referring to FIG. 16, NMOS transistors M1 and M2 constitute a first transistor pair. To the gates of the transistors M1 and M2 is supplied a differential input signal (V_{CM}+Vᵢₙ/2, V_{CM}−Vᵢₙ/2). To the gates of NMOS transistors M3 and M4, constituting a second transistor pair, is also supplied the differential input signal (V_{CM}+Vᵢₙ/2, V_{CM}−Vᵢₙ/2).

Outputs of the first transistor pair (M1, M2) and the second transistor pair (M3 and M4) are connected in parallel to constitute an output pair. The drains of the transistors M1 and M3 are coupled together, while the drains of the transistors M2 and M4 are coupled together, with the coupled drains constituting a differential output pair.

There are also provided a third transistor pair constituted by NMOS transistors M5 and M6, that are cascode-connected to the second transistor pair (M3 and M4) and have gates supplied with the differential input signal (V_{CM}−Vᵢₙ/2, V_{CM}+Vᵢₙ/2) that is in reverse phase with respect to the differential input signal (V_{CM}+Vᵢₙ/2, V_{CM}−Vᵢₙ/2) supplied to the first transistor pair (M1, M2).

The sources of the first and third transistor pair (M1, M2) and (M5, M6) are coupled together and driven by a constant current source Iₒ.

The operation of the present example is now described. It is assumed that, in FIG. 16, the transistor size of the second transistor pair (M3, M4) is K₁ (>1) times the transistor size of the first transistor pair (M1, M2). Since K₁>1, the gate-to-source voltage sufficient to permit cascode connection of the third transistor pair (M5, M6) has now been created between the first transistor pair (M1, M2) and the second transistor pair (M3, M4). It is assumed that the transistor size of the third transistor pair (M5, M6) is K₁ times the transistor size of the first transistor pair (M1, M2).

The drain currents of the respective transistors may be expressed as

$$\begin{matrix}{I}_{D 1} = β {( {V}_{CM} + \frac{{V}_{i n}}{2} - {V}_{S} - {V}_{TH} )}^{2} & ( 176 ) \\ {I}_{D 2} = β {( {V}_{CM} - \frac{{V}_{i n}}{2} - {V}_{S} - {V}_{TH} )}^{2} & ( 117 ) \\ {I}_{D 3} = {K}_{1} {β ( {V}_{CM} + \frac{{V}_{i n}}{2} - {V}_{1} - {V}_{TH} )}^{2} & ( 178 ) \\ {I}_{D 4} = {K}_{1} {β ( {V}_{CM} - \frac{{V}_{i n}}{2} - {V}_{2} - {V}_{TH} )}^{2} & ( 179 ) \\ {I}_{D 5} = 2 {K}_{2} β ( {V}_{CM} - \frac{{V}_{i n}}{2} - {V}_{S} - {V}_{TH} - \frac{{V}_{1} - {V}_{S}}{2} ) ( {V}_{1} - {V}_{S} ) \\ and & ( 180 ) \\ {I}_{D 6} = 2 {K}_{2} β ( {V}_{CM} + \frac{{V}_{i n}}{2} - {V}_{S} - {V}_{TH} - \frac{{V}_{21} - {V}_{S}}{2} ) ( {V}_{2} - {V}_{S} ) . & ( 181 )\end{matrix}$$

If we set
α=V_{CM}−V_{S}−V_{TH} (182)
the equations may be rewritten to

$$\begin{matrix}{I}_{D 1} = {β ( \frac{{V}_{i n}}{2} + α )}^{2} & ( 183 ) \\ {I}_{D 2} = {β ( - \frac{{V}_{i n}}{2} + α )}^{2} & ( 184 ) \\ {I}_{D 3} = {K}_{1} β {\{ \frac{{V}_{i n}}{2} - ( {V}_{1} - {V}_{S} ) + α \}}^{2} & ( 185 ) \\ {I}_{D 4} = {K}_{1} β {\{ - \frac{{V}_{i n}}{2} - ( {V}_{2} - {V}_{S} ) + α \}}^{2} & ( 186 ) \\ {I}_{D 5} = 2 {K}_{2} β ( - \frac{{V}_{i n}}{2} + α - \frac{{V}_{1} - {V}_{S}}{2} ) ( {V}_{1} - {V}_{S} ) \\ and & ( 187 ) \\ {I}_{D 6} = 2 {K}_{2} β ( \frac{{V}_{i n}}{2} + α - \frac{{V}_{2} - {V}_{S}}{2} ) ( {V}_{2} - {V}_{S} ) \\ Hence , & ( 188 ) \\ {I}_{D 1} + {I}_{D 2} = 2 β \{ {( \frac{{V}_{i n}}{2} )}^{2} + {α}^{2} \} . & ( 189 )\end{matrix}$$

Since I_{D3}=I_{D5}, we have

$${K}_{1} \{ \frac{{V}_{i n}^{2}}{4} + {( {V}_{1} + {V}_{S} )}^{2} + {α}^{2} - 2 \frac{{V}_{i n}}{2} ( {V}_{1} - {V}_{s} ) - 2 α ( {V}_{1} - {V}_{s} ) + 2 \frac{{V}_{i n}}{2} α \} = {K}_{2} \{ - 2 \frac{{V}_{i n}}{2} ( {V}_{1} - {V}_{s} ) + 2 α ( {V}_{1} - {V}_{s} ) - {( {V}_{1} - {V}_{S} )}^{2} \} . \qquad ( 190 )$$

That is,

$$( {K}_{1} + {K}_{2} ) {( {V}_{1} - {V}_{S} )}^{2} - 2 \{ ( {K}_{1} - {K}_{2} ) \frac{{V}_{i n}}{2} + ( {K}_{1} + {K}_{2} ) α \} ( {V}_{1} - {V}_{S} ) + {K}_{1} ( \frac{{V}_{i n}^{2}}{4} + 2 \frac{{V}_{i n}}{2} α + {α}^{2} ) = 0. \qquad ( 191 )$$

If we solve the equation (191) for (V₁−Vₛ), we have:

$${V}_{1} - {V}_{S} = \frac{{K}_{1} - {K}_{2}}{{K}_{1} + {K}_{2}} \frac{{V}_{i n}}{2} + α - \frac{\sqrt{{K}_{2} ( {K}_{1} + {K}_{2} ) {α}^{2} - {K}_{2} ( 3 {K}_{1} - {K}_{2} ) \frac{{V}_{i n}^{2}}{4} - 2 {K}_{2} ( {K}_{1} + {K}_{2} ) \frac{{V}_{i n}}{2} α}}{{K}_{1} + {K}_{2}} = \\ \frac{{K}_{1} - {K}_{2}}{{K}_{1} + {K}_{2}} \frac{{V}_{i n}}{2} + α - \\ \sqrt{\frac{{K}_{2}}{{K}_{1} + {K}_{2}}} α \sqrt{1 - \frac{3 {K}_{1} - {K}_{2}}{{K}_{1} + {K}_{2}} \frac{{V}_{i n}^{2}}{4 {α}^{2}} - \frac{2}{{K}_{1} + {K}_{2}} \frac{{V}_{i n}}{2 α}} . \qquad ( 192 )$$

Also, since I_{D4}=I_{D6}, we have

$${K}_{1} \{ \frac{{V}_{i n}^{2}}{4} + {( {V}_{2} - {V}_{S} )}^{2} + {α}^{2} + 2 \frac{{V}_{i n}}{2} ( {V}_{2} - {V}_{s} ) - 2 α ( {V}_{2} - {V}_{s} ) - 2 \frac{{V}_{i n}}{2} α \} = {K}_{2} \{ 2 \frac{{V}_{i n}}{2} ( {V}_{2} - {V}_{s} ) + 2 α ( {V}_{2} - {V}_{s} ) - {( {V}_{2} - {V}_{s} )}^{2} \} . \qquad ( 193 )$$

That is,

$$( {K}_{1} + {K}_{2} ) {( {V}_{2} - {V}_{S} )}^{2} + 2 \{ ( {K}_{1} - {K}_{2} ) \frac{{V}_{i n}}{2} - ( {K}_{1} + {K}_{2} ) α \} ( {V}_{1} - {V}_{S} ) + {K}_{1} ( \frac{{V}_{i n}^{2}}{4} - 2 \frac{{V}_{i n}}{2} α + {α}^{2} ) = 0 \qquad ( 194 )$$

Solving the equation for (V₂−Vₛ), we have

$${V}_{2} - {V}_{S} = - \frac{{K}_{1} - {K}_{2}}{{K}_{1} + {K}_{2}} \frac{{V}_{i n}}{2} + α - \frac{\sqrt{\begin{matrix}{K}_{2} ( {K}_{1} + {K}_{2} ) {α}^{2} - {K}_{2} ( 3 {K}_{1} - {K}_{2} ) \\ \frac{{V}_{i n}^{2}}{4} + 2 {K}_{2} ( {K}_{1} + {K}_{2} ) \frac{{V}_{i n}}{2} α\end{matrix}}}{{K}_{1} + {K}_{2}} = - \frac{{K}_{1} - {K}_{2}}{{K}_{1} + {K}_{2}} \frac{{V}_{i n}}{2} + α - \sqrt{\frac{{K}_{2}}{{K}_{1} + {K}_{2}}} α \sqrt{1 - \frac{3 {K}_{1} - {K}_{2}}{{K}_{1} + {K}_{2}} \frac{{V}_{i n}^{2}}{4 {α}^{2}} + \frac{2}{{K}_{1} + {K}_{2}} \frac{{V}_{i n}}{2 α}} . \qquad ( 195 )$$

The equations (192) and (195) have been found, and V₁ and V₂ may be eliminated. However, Vₛ is included in α and hence has not been eliminated.

At this time,

$${I}_{D 3} = {K}_{1} β {\{ \begin{matrix}\frac{2 {K}_{ 2}}{ {K}_{ 1} + {K}_{ 2}} \frac{ {V}_{ i n}}{ 2} + \\ \sqrt{ \frac{ {K}_{ 2}}{ {K}_{ 1} + {K}_{ 2}}} α \sqrt{1 - \begin{matrix}\frac{3 {K}_{ 1} - {K}_{ 2}}{ {K}_{ 1} + {K}_{ 2}} \frac{ {V}_{ i n}^{ 2}}{ 4 {α}^{ 2}} - \\ \frac{2}{ {K}_{ 1} + {K}_{ 2}} \frac{ {V}_{ i n }}{2 α}\end{matrix} }\end{matrix} \}}^{2} = {K}_{1} β [ {( \frac{2 {K}_{2}}{{K}_{1} + {K}_{2}} )}^{2} {( \frac{{V}_{i n}}{2} )}^{2} + \frac{4 {K}_{2}}{{K}_{1} + {K}_{2}} α \frac{{V}_{i n}}{2} \sqrt{\frac{{K}_{2}}{{K}_{1} + {K}_{2}}} \sqrt{1 - \begin{matrix} \frac{3 {K}_{ 1} - {K}_{ 2}}{ {K}_{ 1} + {K}_{ 2}} \frac{ {V}_{ i n}^{ 2}}{ 4 {α}^{ 2}} - \\ \frac{2}{ {K}_{ 1} + {K}_{ 2}} \frac{ {V}_{ i n}}{ 2 α}\end{matrix}} + \frac{{K}_{2}}{{K}_{1} + {K}_{2}} {α}^{2} - \frac{{K}_{2} ( 3 {K}_{1} - {K}_{2} )}{{( {K}_{1} + {K}_{2} )}^{2}} \frac{{V}_{i n}^{2}}{4} - \frac{2 {K}_{2}}{{( {K}_{1} + {K}_{2} )}^{2}} \frac{{V}_{i n}}{2} α ) ] . \qquad ( 196 )$$

Here, first-order approximation is made, and a root symbol √ is eliminated, provided that the approximation is subject to the condition

$$\frac{3 {K}_{1} - {K}_{2}}{{K}_{1} + {K}_{2}} \frac{{V}_{i n}^{2}}{4 {α}^{2}} + \frac{2}{{K}_{1} + {K}_{2}} \frac{{V}_{i n}}{2 α} << 1$$

such that, in general, such approximation cannot be applied to an OTA in which an input signal is not limited to a small signal.

However, if the approximation is applied, somewhat forcedly,

$$\sqrt{1 - \frac{3 {K}_{1} - {K}_{2}}{{K}_{1} + {K}_{2}} \frac{{V}_{i n}^{2}}{4 {α}^{2}} - \frac{2}{{K}_{1} + {K}_{2}} \frac{{V}_{i n}}{2 α}} \approx 1 - \frac{1}{2} ( \frac{3 {K}_{1} - {K}_{2}}{{K}_{1} + {K}_{2}} \frac{{V}_{i n}^{2}}{4 {α}^{2}} + \frac{2}{{K}_{1} + {K}_{2}} \frac{{V}_{i n}}{2 α} ) . \qquad ( 197 )$$

Then, the equation (196) may be approximated by

$${I}_{D 3} = {K}_{1} β [ \begin{matrix}{( \frac{2 {K}_{2}}{{K}_{1} + {K}_{2}} )}^{2} {( \frac{{V}_{i n}}{2} )}^{2} + \frac{4 {K}_{2}}{{K}_{1} + {K}_{2}} α \frac{{V}_{i n}}{2} \\ \sqrt{\frac{{K}_{2}}{{K}_{1} + {K}_{2}}} \sqrt{1 - \frac{3 {K}_{1} - {K}_{2}}{{K}_{1} + {K}_{2}} \frac{{V}_{i n}^{2}}{4 {α}^{2}} - \frac{2}{{K}_{1} + {K}_{2}} \frac{{V}_{i n}}{2 α}} + \\ \frac{{K}_{2}}{{K}_{1} + {K}_{2}} {α}^{2} - \frac{{K}_{2} ( 3 {K}_{1} - {K}_{2} )}{{( {K}_{1} + {K}_{2} )}^{2}} \frac{{V}_{i n}^{2}}{4} - \frac{2 {K}_{2}}{( {K}_{1} + {K}_{2} )} \frac{{V}_{i n}}{2} α )\end{matrix} ] \approx {K}_{1} β [ \begin{matrix}{( \frac{2 {K}_{2}}{{K}_{1} + {K}_{2}} )}^{2} {( \frac{{V}_{i n}}{2} )}^{2} + \frac{4 {K}_{2}}{{K}_{1} + {K}_{2}} α \frac{{V}_{i n}}{2} \\ \sqrt{\frac{{K}_{2}}{{K}_{1} + {K}_{2}}} \{ 1 - \frac{1}{2} ( \frac{3 {K}_{1} - {K}_{2}}{{K}_{1} + {K}_{2}} \frac{{V}_{i n}^{2}}{4 {α}^{2}} + \frac{2}{{K}_{1} + {K}_{2}} \frac{{V}_{i n}}{2 α} ) \} + \\ \frac{{K}_{2}}{{K}_{1} + {K}_{2}} {α}^{2} - \frac{{K}_{2} ( 3 {K}_{1} - {K}_{2} )}{{( {K}_{1} + {K}_{2} )}^{2}} \frac{{V}_{i n}^{2}}{4} - \frac{2 {K}_{2}}{{( {K}_{1} + {K}_{2} )}^{2}} \frac{{V}_{i n}}{2} α )\end{matrix} ] . \qquad ( 198 )$$

In similar manner, I_{D4} may be approximated by

$${I}_{D 4} = {K}_{1} β {\{ \begin{matrix}- \frac{2 {K}_{ 2}}{ {K}_{ 1} + {K}_{ 2}} \frac{ {V}_{ i n}}{ 2} + \sqrt{ \frac{ {K}_{ 2}}{ {K}_{ 1} + {K}_{ 2}}} α \\ \sqrt{1 - \frac{3 {K}_{ 1} - {K}_{ 2}}{ {K}_{ 1} + {K}_{ 2}} \frac{ {V}_{ i n}^{ 2}}{ 4 {α}^{ 2}} + \frac{2}{ {K}_{ 1} + {K}_{ 2}} \frac{ {V}_{ i n}}{ 2 α}}\end{matrix} \}}^{2} = {K}_{1} β [ {( \frac{2 {K}_{2}}{{K}_{1} + {K}_{2}} )}^{2} {( \frac{{V}_{i n}}{2} )}^{2} - \frac{4 {K}_{2}}{{K}_{1} + {K}_{2}} α \frac{{V}_{i n}}{2} \sqrt{\frac{{K}_{2}}{{K}_{1} + {K}_{2}}} \sqrt{1 - \frac{3 {K}_{1} - {K}_{2}}{{K}_{1} + {K}_{2}} \frac{{V}_{i n}^{2}}{4 {α}^{2}} + \frac{2}{{K}_{1} + {K}_{2}} \frac{{V}_{i n}}{2 α}} + \frac{{K}_{2}}{{K}_{1} + {K}_{2}} {α}^{2} - \frac{{K}_{2} ( 3 {K}_{1} - {K}_{2} )}{{( {K}_{1} + {K}_{2} )}^{2}} \frac{{V}_{i n}^{2}}{4} + \frac{2 {K}_{2}}{{( {K}_{1} + {K}_{2} )}^{2}} \frac{{V}_{i n}}{2} α ) ] \approx {K}_{1} β [ {( \frac{2 {K}_{2}}{{K}_{1} + {K}_{2}} )}^{2} {( \frac{{V}_{i n}}{2} )}^{2} - \frac{4 {K}_{2}}{{K}_{1} + {K}_{2}} α \frac{{V}_{i n}}{2} \sqrt{\frac{{K}_{2}}{{K}_{1} + {K}_{2}}} \{ 1 - \frac{1}{2} ( \frac{3 {K}_{1} - {K}_{2}}{{K}_{1} + {K}_{2}} \frac{{V}_{i n}^{2}}{4 {α}^{2}} - \frac{2}{{K}_{1} + {K}_{2}} \frac{{V}_{i n}}{2 α} ) \} + \frac{{K}_{2}}{{K}_{1} + {K}_{2}} {α}^{2} - \frac{{K}_{2} ( 3 {K}_{1} - {K}_{2} )}{{( {K}_{1} + {K}_{2} )}^{2}} \frac{{V}_{i n}^{2}}{4} + \frac{2 {K}_{2}}{{( {K}_{1} + {K}_{2} )}^{2}} \frac{{V}_{i n}}{2} α ) ] . \qquad ( 199 )$$

Then, from the condition of the tail current, we have the following expression:

$${I}_{0} = {I}_{D 1} + {I}_{D 2} + {I}_{D 3} + {I}_{D 4} = β [ 2 \{ 1 - \frac{{K}_{2} ( 3 {K}_{1} - 5 {K}_{2} )}{{( {K}_{1} + {K}_{2} )}^{2}} \} \frac{{V}_{i n}^{2}}{4} + 2 \{ 1 + \frac{{K}_{2}}{{K}_{1} + {K}_{2}} \} {α}^{2} + \frac{4 {K}_{2}}{{( {K}_{1} + {K}_{2} )}^{2}} \frac{{V}_{i n}}{2} \{ \sqrt{{K}_{2} ( {K}_{1} + {K}_{2} ) {α}^{2} - {K}_{2} ( 3 {K}_{1} - {K}_{2} ) \frac{{V}_{i n}^{2}}{4} + 2 {K}_{2} ( {K}_{1} + {K}_{2} ) \frac{{V}_{i n}}{2} α} - \sqrt{{K}_{2} ( {K}_{1} + {K}_{2} ) {α}^{2} - {K}_{2} ( 3 {K}_{1} - {K}_{2} ) \frac{{V}_{i n}^{2}}{4} + 2 {K}_{2} ( {K}_{1} + {K}_{2} ) \frac{{V}_{i n}}{2} α} \} ] \approx β [ 2 \{ 1 - \frac{{K}_{2} ( 3 {K}_{1} - 5 {K}_{2} )}{{( {K}_{1} + {K}_{2} )}^{2}} - \frac{4 {K}_{2}}{{( {K}_{1} + {K}_{2} )}^{2}} \sqrt{\frac{{K}_{2}}{{K}_{1} + {K}_{2}}} \} \frac{{V}_{i n}^{2}}{4} + 2 \{ 1 + \frac{{K}_{2}}{{K}_{1} + {K}_{2}} \} {α}^{2} ] . \qquad ( 200 )$$

From the equation (182), the variable V_{S} is contained, in addition to VCN and VTH, in α, this variable V_{S} being a variable of the input voltage Vᵢₙ. However, if assumed that, in case the OTA performs a linear operation, V_{S} becomes constant irrespective of the input signal Vᵢₙ as in conventional OTAs, the term Vᵢₙ² in the equation (200) should be zero, because the tail current IO is constant at all times.

Hence, the following equation:

$$1 = \frac{{K}_{2} ( 3 {K}_{1} - 5 {K}_{2} )}{{( {K}_{1} + {K}_{2} )}^{2}} + \frac{4 {K}_{2}}{{( {K}_{1} + {K}_{2} )}^{2}} \sqrt{\frac{{K}_{2}}{{K}_{1} + {K}_{2}}} \qquad ( 201 )$$

holds.

Further analysis is difficult or may even fail to be reasonable.

It is now undertaken to confirm the characteristic of the circuit by SPICE simulation. In similar manner, device parameters of 0.35 μm are used, provided that a back gate and a source a P-channel transistor are connected together to reduce the substrate effect.

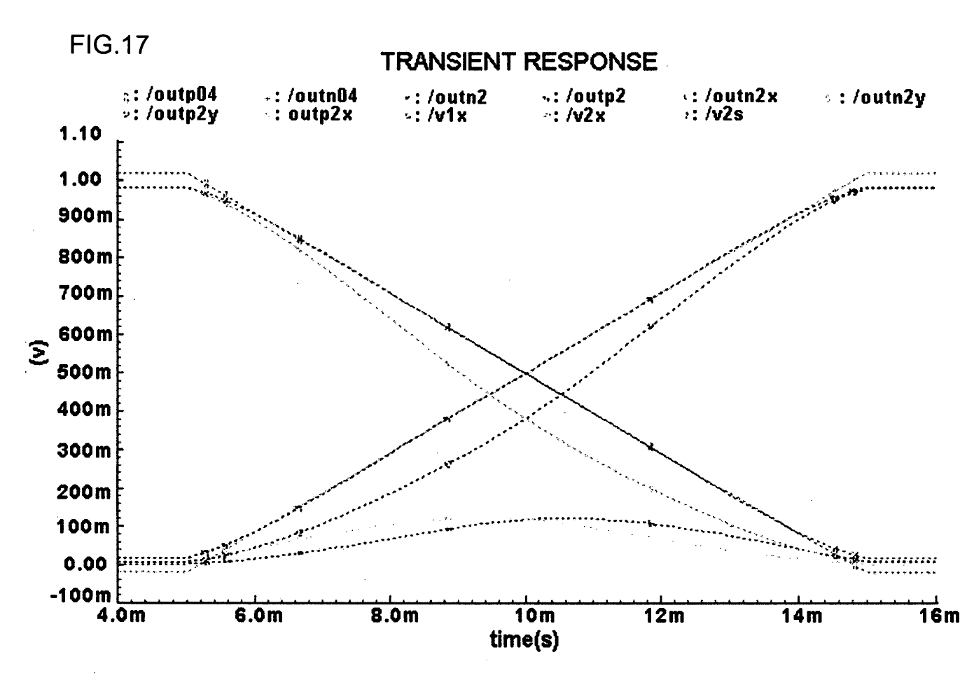

FIG. 17 shows SPICE simulation values. Thus, I₀ is set to 100 μA (I₀=100 μA), W/L of the transistors M1 and M2 is set to 6 μm/1 μm, W/L of the transistors M3 and M4 is set to 10 μm/1 μm and W/L of the transistors M3 and M4 is set to 2.5 μm/1 μm.

This is equivalent to K₁=1.67 and K₂=0.42. Here, TRAN analysis is conducted and, as differential input voltages, in which an input voltage at the (+) side input terminal was linearly changed from 0.5V@5 mS to 1.5V@5 mS, whist an input voltage at the (−) side input terminal was linearly changed from 1.5V@5 mS to 0.5V@15 mS. The current was transformed via 10 kΩ resistor into the voltage which is illustrated.

An input offset of the order of 100 mV is generated in the square currents generated by the transistors M5 and M6. However, the output current characteristic show high linearity and may be confirmed to substantially overlap with a straight line, with the deviation from the straight line being on the order of −4% at the maximum (Vᵢₙ=0.5V@5 mS, 1.5V@15 mS, 1.5V@5 mS and 0.5V@15 mS).

The technique for linearization will be discussed in the below. With

$$α = {V}_{CM} - {V}_{S} - {V}_{TH} = \sqrt{\frac{{I}_{0}}{( K + 2 ) β}} \qquad ( 202 )$$

for a given constant K, the class A operation is implemented. In case the OTA performs the linear operation, the drain currents may be represented by

$$\begin{matrix}{I}_{D 1} = {β ( \sqrt{\frac{{I}_{0}}{( K + 2 ) β}} + \frac{{V}_{i n}}{2} )}^{2} = \frac{{I}_{0}}{K + 2} + \sqrt{\frac{β {I}_{0}}{K + 2}} {V}_{i n} + β \frac{{V}_{i n}^{2}}{4} & ( 203 ) \\ {I}_{D 2} = {β ( \sqrt{\frac{{I}_{0}}{( K + 2 ) β}} + \frac{{V}_{i n}}{2} )}^{2} = \frac{{I}_{0}}{K + 2} + \sqrt{\frac{β {I}_{0}}{K + 2}} {V}_{i n} + β \frac{{V}_{i n}^{2}}{4} & ( 204 ) \\ {I}_{D 3} = {I}_{D 5} = \frac{{KI}_{0}}{2 ( K + 2 )} - β \frac{{V}_{i n}^{2}}{4} \\ and & ( 205 ) \\ {I}_{D 4} = {I}_{D 6} = \frac{{KI}_{0}}{2 ( K + 2 )} - β \frac{{V}_{i n}^{2}}{4} . & ( 206 ) \\ Hence , \\ {I}_{1} = {I}_{D 1} + {I}_{D 3} - \frac{{I}_{0}}{2} = \sqrt{\frac{β {I}_{0}}{K + 2}} {V}_{i n} \\ and & ( 207 ) \\ {I}_{2} = {I}_{D 2} + {I}_{D 4} - \frac{{I}_{0}}{2} = - \sqrt{\frac{β {I}_{0}}{K + 2}} {V}_{i n} . & ( 208 )\end{matrix}$$

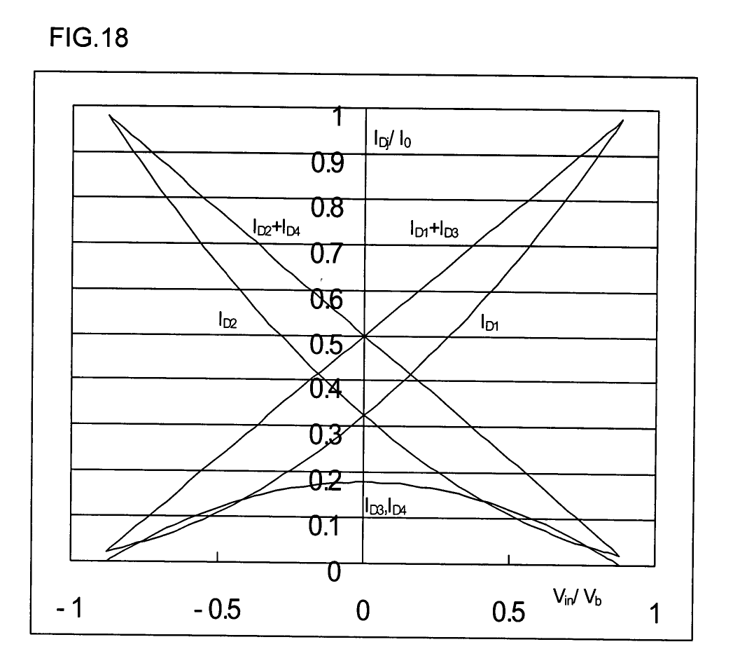

This relationship is illustrated in FIG. 18, in which

$$K = \frac{2}{2 \sqrt{2} - 1} ( = 1.09384 )$$

$$and$$

$${V}_{b} = \sqrt{\frac{{I}_{0}}{( K + 2 ) β}}$$

are set.

In case the currents flowing through the transistors M3 and M4 are square currents having input offsets, the equations (205) and (206) need to be changed to the following equations (209), (210), respectively:

$$\begin{matrix}{I}_{D 3} = {I}_{D 5} = \frac{{KI}_{0}}{2 ( K + 2 )} + β {γ}^{2} - {β ( γ + \frac{{V}_{i n}}{2} )}^{2} \\ and & ( 209 ) \\ {I}_{D 4} = {I}_{D 6} = \frac{{KI}_{0}}{2 ( K + 2 )} + β {γ}^{2} - {β ( γ - \frac{{V}_{i n}}{2} )}^{2} . & ( 210 )\end{matrix}$$

Even in the case of the equations (203), (204), (209) and (210), the condition for the tail current:
I₀=I_{D1}+I_{D2}+I_{D3}+I_{D4} (211)
is met.

From the equations (203), (204) and (209) and (210), the following equations:

$$\begin{matrix}{I}_{1} = {I}_{D 1} + {I}_{D 3} - \frac{{I}_{0}}{2} = ( \sqrt{\frac{β {I}_{0}}{K + 2}} - βγ ) {V}_{i n} \\ and & ( 212 ) \\ {I}_{2} = {I}_{D 2} + {I}_{D 4} - \frac{{I}_{0}}{2} = ( \sqrt{\frac{β {I}_{0}}{K + 2}} - βγ ) {V}_{i n} & ( 213 )\end{matrix}$$

may be derived.

Even though the transconductance is decreased in an amount corresponding to the input offset γ of the square current, the linear operation is ensured. It may be understood that, if we set K=K₁, the output current characteristic, shown in FIG. 17, approaches to the linear characteristic, thus verifying the superior linearity of the differential circuit shown in FIG. 16.

### THIRD EXAMPLE

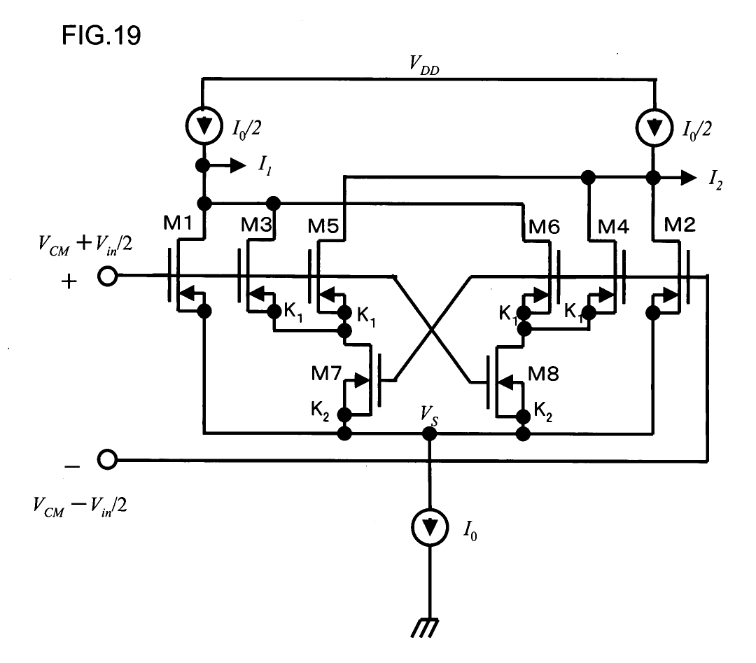

FIG. 19 shows a circuit configuration of an example of a differential circuit of the present invention (corresponding to claim 4).

Referring to FIG. 19, if the square currents obtained in the circuit shown in FIG. 16 are divided into two portions and added to respective outputs, the input offset γ of the square currents may be canceled out.

In FIG. 19, NMOS transistors M1 and M2 constitute a first transistor pair, to the gates of which is supplied the differential input signal (V_{CM}+Vᵢₙ/2, V_{CM}−Vᵢₙ/2). To the gates of the NMOS transistors M3 and M4, constituting a second transistor pair, there is also supplied the differential input signal (V_{CM}+Vᵢₙ/2, V_{CM}−Vᵢₙ/2). To the gates of the NMOS transistors M5 and M6, constituting a third transistor pair, there is similarly supplied the differential input signal (V_{CM}+Vᵢₙ/2, V_{CM}−Vᵢₙ/2).

An output of the first transistor pair (M1, M2) and an output of the second transistor pair (M3, M4) are connected in parallel with each other. The outputs of the first transistor pair (M1, M2) and the third transistor pair (M5, M6) are cross-coupled together to constitute an output pair. That is, the drains of the NMOS transistors M1, M3 and M6 are coupled together, whilst the drains of the NMOS transistors M2, M4 and M5 are coupled together, with the coupled drains constituting an output pair. Turning to the second transistor pair (M3, M4) and the third transistor pair (M5, M6), the sources of the NMOS transistor M3 and the NMOS transistor M5 are connected together, whilst the sources of the NMOS transistor M4 and the NMOS transistor M6 are connected together.

To the gates of the NMOS transistors M7 and M8, constituting a fourth transistor pair, is supplied differential input signal (V_{CM}−Vᵢₙ/2, V_{CM}+Vᵢₙ/2). The signal (V_{CM}−Vᵢₙ/2, V_{CM}+Vᵢₙ/2) is a reverse phase signal of the (V_{CM}+Vᵢₙ/2, V_{CM}−Vᵢₙ/2) supplied to the NMOS transistors M1 and M2 that constitute a first transistor pair. The NMOS transistor M7 has a drain connected to the coupled sources of the NMOS transistors M3 and M5, whilst the NMOS transistor M8 has a drain connected to the coupled sources of the NMOS transistors M4 and M6. The fourth transistor pair (M7, M8) is cascode-connected to the second transistor pair (M3, M4) and to the third transistor pair (M5, M6).

The sources of the first transistor pair (M1, M2) and the fourth transistor pair (M7, M8) are coupled together and driven by the constant current source Iₒ.

The operation of the present example is now described. It is assumed that, in FIG. 19, the transistor sizes of the second transistor pair (M3, M4) and the third transistor pair (M5, M6) are K₁ (>0) times the transistor size of the transistors of the first transistor pair (M1, M2), where K₁>1 is not essential.

A simple solution of the problem of the input offset of the square current in the differential circuit shown in FIG. 16 is to sum currents of the transistors M5 and M6 and to divide the sum in two. The reason for this is that input offsets of these transistors are reversed from those of the transistors M7 and M8 that generate the square currents.

That is, from the equations (209, 210), we have

$$\frac{{I}_{D 5} + {I}_{D 6}}{2} = \frac{{KI}_{0}}{2 ( K + 2 )} - β \frac{{V}_{i n}^{2}}{4} \qquad ( 214 )$$

so that there may be obtained the square currents equal to those of the equations (205) and (206) and which are free from the input offset.

Hence, the equations (207) and (208) hold to implement a linear class A operation.

That is, the second transistor pairs (M3, M4) in FIG. 16 are each divided into two to form the second transistor pair (M3, M4) and the third transistor pair (M5, M6), to each of which distributes two portions of the square current to the differential output pair. Hence, the transistors of the fourth transistor pair (M7, M8) each generate a square current.

It is now undertaken to confirm the characteristic of the circuit by SPICE simulation. Device parameters of the 0.35 μm are similarly used, provided that a back gate and a source of a P-ch transistor are connected together in order to reduce the substrate effect.

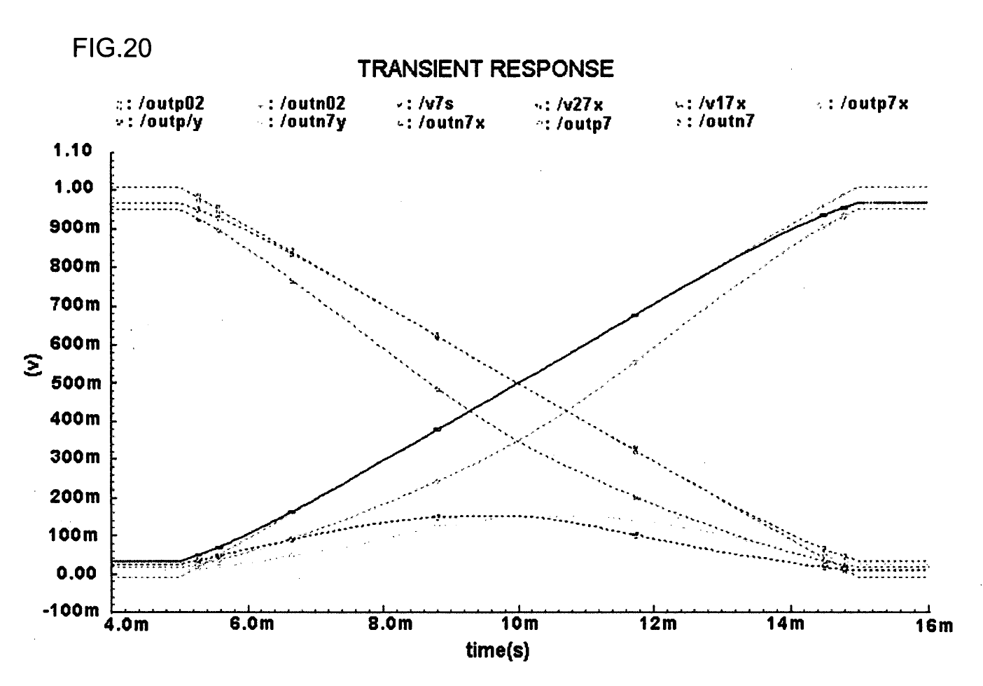

FIG. 20 shows values of the SPICE simulation. Thus, I₀ is set to 100 μA (I₀=100 μA), the W/L ratio of the transistors M1 and M2 is set to 6 μm/1 μm, the W/L ratio of the transistors M3, M4, M5 and M6 is set to 5 μm/1 μm and the W/L ratio of the transistors M7 and M8 is set to 2.5 μm/1 μm. This is equivalent to K₁=0.89 and K₂=0.42. Here, TRAN (transient) analysis is carried out and, as a differential input voltage, the voltage is linearly changed from 0.5V@5 mS to 1.5V@15 mS on the (+) side input terminal and from 1.5V@5 mS to 0.5V@15 mS on the (−) side input terminal. The current is converted via 10 kΩ resistor into a voltage, which is illustrated.

An input offset of the square currents generated by the transistors M5 and M6 is canceled out. Thus, the output current characteristic shows high linearity and may be confirmed to substantially overlap with a straight line, with the deviation from the straight line being on the order of −4% at the maximum (Vᵢₙ=0.5V@5 mS, 1.5V@15 mS, 1.5V@5 mS and 0.5V@15 mS).

### FOURTH EXAMPLE

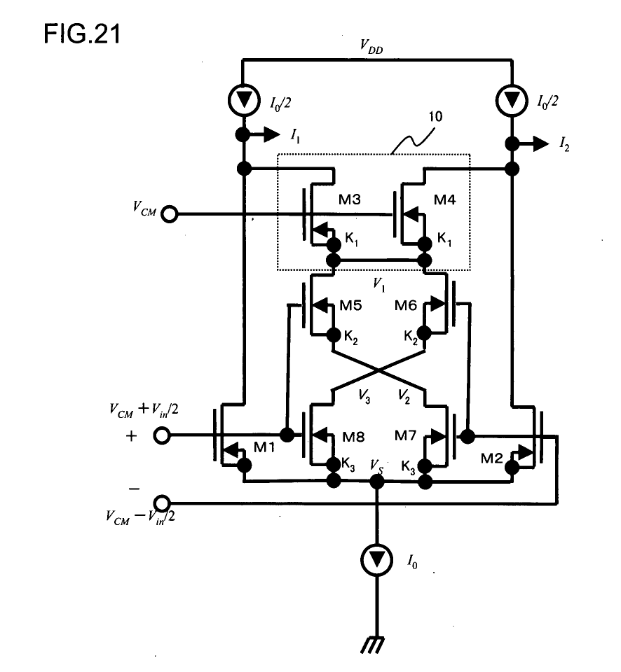

FIG. 21 shows a circuit configuration of an example of the present invention (corresponding to claim 5).

In FIG. 21, NMOS transistors M1 and M2 constitute a first transistor pair. To the gates of these transistors is supplied the differential input signal (V_{CM}+Vᵢₙ/2, V_{CM}−Vᵢₙ/2). To the gates of the NMOS transistors M3 and M4, constituting a second transistor pair, is supplied the common mode signal (V_{CM}) of the differential input signal.

Outputs of the first transistor pair (M1, M2) and the second transistor pair (M3, M4) are connected in parallel to constitute an output pair. The sources of the second transistor pair (M3, M4) are connected together. The transistors (M3, M4) compose a bypass current distributor 10.

The differential input signal (V_{CM}+Vᵢₙ/2, V_{CM}−Vᵢₙ/2) is also supplied to the gates of the NMOS transistors M5 and M6 constituting the third transistor pair. The drains of the transistors of the third transistor pair are connected to coupled sources of the second transistor pair (M3, M4). The third transistor pair (M5, M6) are cascode-connected to the second transistor pair (M3, M4).

The differential input signal (V_{CM}−Vᵢₙ/2, V_{CM}+Vᵢₙ/2) is supplied to the NMOS transistors M7 and M8 constituting the fourth transistor pair. The drains of the fourth transistor pair are connected to coupled sources of the third transistor pair (M5, M6). The fourth transistor pair (M7, M8) is cascode-connected to the third transistor pair (M5, M6).

The sources of the first transistor pair (M1, M2) and the fourth transistor pair (M7, M8) are coupled together and driven by the constant current source Iₒ.

The operation of the present example is now described. The transistors of the third transistor pair (M5, M6) and the fourth transistor pair (M7, M8), connected in cascode, are transistors that generate square currents.

The voltages applied to the two sets of the transistors, connected in cascode, are selected so that the differential input signal will be phase-reversed to eliminate an input offset.

To implement the square current, free of the offset, it is necessary to provide for a circuit symmetrical with respect to the input voltage.

In FIG. 21, the size of the transistors M1 and M2 is 1-fold, that of the transistors M3 and M4 is K₁-fold and, for simplicity, that of the transistors M5 to M8 is K₂-fold.

The respective drain currents may be expressed as

$$\begin{matrix}{I}_{D 1} = {β ( {V}_{CM} + \frac{{V}_{i n}}{2} - {V}_{S} - {V}_{TH} )}^{2} & ( 215 ) \\ {I}_{D 2} = {β ( {V}_{CM} + \frac{{V}_{i n}}{2} - {V}_{S} - {V}_{TH} )}^{2} & ( 216 ) \\ {I}_{D 3} = {I}_{D 4} = {K}_{1} {β ( {V}_{CM} - {V}_{1} - {V}_{TH} )}^{2} & ( 217 ) \\ {I}_{D 5} = 2 {K}_{2} β \{ {V}_{CM} + \frac{{V}_{i n}}{2} - {V}_{2} - {V}_{TH} - \frac{1}{2} ( {V}_{1} - {V}_{2} ) \} ( {V}_{1} - {V}_{2} ) & ( 218 ) \\ {I}_{D 6} = 2 {K}_{2} β \{ {V}_{CM} + \frac{{V}_{i n}}{2} - {V}_{3} - {V}_{TH} - \frac{1}{2} ( {V}_{1} - {V}_{3} ) \} ( {V}_{1} - {V}_{3} ) & ( 219 ) \\ {I}_{D 7} = 2 {K}_{2} β \{ {V}_{CM} + \frac{{V}_{i n}}{2} - {V}_{S} - {V}_{TH} - \frac{1}{2} ( {V}_{2} - {V}_{S} ) \} ( {V}_{2} - {V}_{S} ) \\ and & ( 220 ) \\ {I}_{D 8} = 2 {K}_{2} β \{ {V}_{CM} + \frac{{V}_{i n}}{2} - {V}_{S} - {V}_{TH} - \frac{1}{2} ( {V}_{3} - {V}_{S} ) \} ( {V}_{3} - {V}_{S} ) . & ( 221 )\end{matrix}$$

If we set
α=V_{CM}−V_{S}−V_{TH} (222)
the above equations may be rewritten to

$$\begin{matrix}{I}_{D 1} = {β ( \frac{{V}_{i n}}{2} + α )}^{2} & ( 223 ) \\ {I}_{D 2} = {β ( - \frac{{V}_{i n}}{2} + α )}^{2} & ( 224 ) \\ {I}_{D 3} = {I}_{D 4} = {K}_{1} β {\{ α - ( {V}_{1} - {V}_{S} ) \}}^{2} & ( 225 ) \\ {I}_{D 5} = 2 {K}_{2} β \{ \frac{{V}_{i n}}{2} + α - ( {V}_{2} - {V}_{S} ) - \frac{1}{2} ( {V}_{1} - {V}_{2} ) \} ( {V}_{1} - {V}_{2} ) & ( 226 ) \\ {I}_{D 6} = 2 {K}_{2} β \{ \frac{{V}_{i n}}{2} + α - ( {V}_{3} - {V}_{S} ) - \frac{1}{2} ( {V}_{1} - {V}_{3} ) \} ( {V}_{1} - {V}_{3} ) & ( 227 ) \\ {I}_{D 7} = 2 {K}_{2} β \{ - \frac{{V}_{i n}}{2} + α - \frac{1}{2} ( {V}_{2} - {V}_{S} ) \} ( {V}_{2} - {V}_{S} ) \\ and & ( 228 ) \\ {I}_{D 8} = 2 {K}_{2} β \{ - \frac{{V}_{i n}}{2} + α - \frac{1}{2} ( {V}_{3} - {V}_{S} ) \} ( {V}_{3} - {V}_{S} ) . & ( 229 )\end{matrix}$$

From the condition of the tail current,
I₀=I_{D1}+I_{D2}+I_{D7}+I_{D8}=I_{D1}+I_{D2}+I_{D3}+I_{D4} (230).

Substituting the equations (223) to (226) into the equation (230), and solving for (V1−VS), we have

$${V}_{1} - {V}_{S} = α - \sqrt{\frac{1}{{K}_{1}} ( \frac{{I}_{0}}{2 β} - {α}^{2} - \frac{{V}_{i n}^{2}}{4} )} . \qquad ( 231 )$$

Since I_{D5}=I_{D7}, if we put
V₁−V₂=(V₁−V_{S})−(V₂−V_{S}) (232)
in the equation (225) and solve for (V₂−V_{S}), we have

$${V}_{2} - {V}_{S} = α - \sqrt{{α}^{2} + \frac{1}{2} {( {V}_{1} - {V}_{S} )}^{2} - ( \frac{{V}_{i n}}{2} + α ) ( {V}_{1} - {V}_{S} )} = α - \sqrt{\begin{matrix} \frac{1}{ 2 {K}_{ 1}} \{ \frac{ {I}_{ 0}}{ 2 β} + ( {K}_{ 1} - 1 ) {α}^{2} - \frac{ {V}_{ i n}^{ 2}}{ 4} \} - \\ α \frac{ {V}_{ i n}}{ 2} + \frac{ {V}_{ i n}}{ 2} \sqrt{ \frac{1}{ {K}_{ 1}} ( \frac{ {I}_{ 0}}{ 2 β} - {α}^{2} - \frac{ {V}_{ i n}^{ 2}}{ 4} )}\end{matrix}} . \qquad ( 233 )$$

In similar manner, since I_{D6}=I_{D8}, if we put
V₁−V₃=(V₁−V_{S})−(V₃−V_{S}) (234)
In the equation (226) and solve for (V₃−V_{S}), we have

$${V}_{3} - {V}_{S} = α - \sqrt{{α}^{2} + \frac{1}{2} {( {V}_{1} - {V}_{S} )}^{2} - ( - \frac{{V}_{i n}}{2} + α ) ( {V}_{1} - {V}_{S} )} = α - \sqrt{\begin{matrix} \frac{1}{ 2 {K}_{ 1}} \{ \frac{ {I}_{ 0}}{ 2 β} + ( {K}_{ 1} - 1 ) {α}^{2} - \frac{ {V}_{ i n}^{ 2}}{ 4} \} + \\ α \frac{ {V}_{ i n}}{ 2} - \frac{ {V}_{ i n}}{ 2} \sqrt{\frac{1}{ {K}_{ 1}} ( \frac{ {I}_{ 0}}{ 2 β} - {α}^{2} - \frac{ {V}_{ i n}^{ 2}}{ 4} )}\end{matrix}} . \qquad ( 235 )$$

Also, since I_{D3}=(I_{D5}+I_{D6})/2=(I_{D7}+I_{D8})/2,

$$\begin{matrix}{I}_{D 3} = {I}_{D 4} = β ( \frac{{I}_{0}}{2 β} - {α}^{2} - \frac{{V}_{in}^{2}}{4} ) & ( 236 ) \\ {I}_{D 7} = {K}_{2} β [ - \frac{{V}_{in}}{2} α - \frac{1}{2 {K}_{1}} \{ \frac{{I}_{0}}{2 β} - ( {K}_{1} + 1 ) {α}^{2} - \frac{{V}_{in}^{2}}{4} \} - \frac{{V}_{in}}{2} \sqrt{\frac{1}{{K}_{1}} ( \frac{{I}_{0}}{2 β} - {α}^{2} - \frac{{V}_{in}^{2}}{4} )} + 2 \frac{{V}_{in}}{2} \sqrt{\begin{matrix}\frac{1}{2 {K}_{1}} \{ \frac{{I}_{0}}{2 β} + ( {K}_{1} - 1 ) {α}^{2} - \frac{{V}_{in}^{2}}{4} \} - \\ α \frac{{V}_{in}}{2} + \frac{{V}_{in}}{2} \sqrt{\frac{1}{{K}_{1}} ( \frac{{I}_{0}}{2 β} - {α}^{2} - \frac{{V}_{in}^{2}}{4} )}\end{matrix}} ] \\ and & ( 237 ) \\ {I}_{D 8} = {K}_{2} β [ \frac{{V}_{in}}{2} α - \frac{1}{2 {K}_{1}} \{ \frac{{I}_{0}}{2 β} - ( {K}_{1} + 1 ) {α}^{2} - \frac{{V}_{in}^{2}}{4} \} + \frac{{V}_{in}}{2} \sqrt{\frac{1}{{K}_{1}} ( \frac{{I}_{0}}{2 β} - {α}^{2} - \frac{{V}_{in}^{2}}{4} )} - 2 \frac{{V}_{in}}{2} \sqrt{\begin{matrix}\frac{1}{2 {K}_{1}} \{ \frac{{I}_{0}}{2 β} + ( {K}_{1} - 1 ) {α}^{2} - \frac{{V}_{in}^{2}}{4} \} + \\ α \frac{{V}_{in}}{2} - \frac{{V}_{in}}{2} \sqrt{\frac{1}{{K}_{1}} ( \frac{{I}_{0}}{2 β} - {α}^{2} - \frac{{V}_{in}^{2}}{4} )}\end{matrix}} ] . \\ Hence , & ( 238 ) \\ {I}_{D 7} + {I}_{D 8} = {K}_{2} β [ - \frac{1}{{K}_{1}} \{ \frac{{I}_{0}}{2 β} - ( {K}_{1} + 1 ) {α}^{2} - \frac{{V}_{in}^{2}}{4} \} + 2 \frac{{V}_{in}}{2} \{ \sqrt{\begin{matrix}\frac{1}{2 {K}_{1}} \{ \frac{{I}_{0}}{2 β} + ( {K}_{1} - 1 ) {α}^{2} - \frac{{V}_{in}^{2}}{4} \} - \\ α \frac{{V}_{in}}{2} + \frac{{V}_{in}}{2} \sqrt{\frac{1}{{K}_{1}} ( \frac{{I}_{0}}{2 β} - {α}^{2} - \frac{{V}_{in}^{2}}{4} )}\end{matrix}} - \sqrt{\begin{matrix}\frac{1}{2 {K}_{1}} \{ \frac{{I}_{0}}{2 β} + ( {K}_{1} - 1 ) {α}^{2} - \frac{{V}_{in}^{2}}{4} \} + \\ α \frac{{V}_{in}}{2} - \frac{{V}_{in}}{2} \sqrt{\frac{1}{{K}_{1}} ( \frac{{I}_{0}}{2 β} - {α}^{2} - \frac{{V}_{in}^{2}}{4} )}\end{matrix}} \} ] . & ( 239 )\end{matrix}$$

From the equations (236) and (239), we have

$$β ( \frac{{I}_{0}}{2 β} - {α}^{2} - \frac{{V}_{in}^{2}}{4} ) = {K}_{2} β [ - \frac{1}{2 {K}_{1}} \{ \frac{{I}_{0}}{2 β} - ( {K}_{1} + 1 ) {α}^{2} - \frac{{V}_{in}^{2}}{4} \} + \frac{{V}_{in}}{2} \{ \sqrt{\begin{matrix}\frac{1}{2 {K}_{1}} \{ \frac{{I}_{0}}{2 β} + ( {K}_{1} - 1 ) {α}^{2} - \frac{{V}_{in}^{2}}{4} \} - \\ α \frac{{V}_{in}}{2} + \frac{{V}_{in}}{2} \sqrt{\frac{1}{{K}_{1}} ( \frac{{I}_{0}}{2 β} - {α}^{2} - \frac{{V}_{in}^{2}}{4} )}\end{matrix}} - \sqrt{\begin{matrix}\frac{1}{2 {K}_{1}} \{ \frac{{I}_{0}}{2 β} + ( {K}_{1} - 1 ) {α}^{2} - \frac{{V}_{in}^{2}}{4} \} + \\ α \frac{{V}_{in}}{2} - \frac{{V}_{in}}{2} \sqrt{\frac{1}{{K}_{1}} ( \frac{{I}_{0}}{2 β} - {α}^{2} - \frac{{V}_{in}^{2}}{4} )}\end{matrix}} \} ] . \qquad ( 240 )$$

Here, it is sufficient if the equation (240) is solved for a. However, the equation (240) appears to be scarcely solvable.

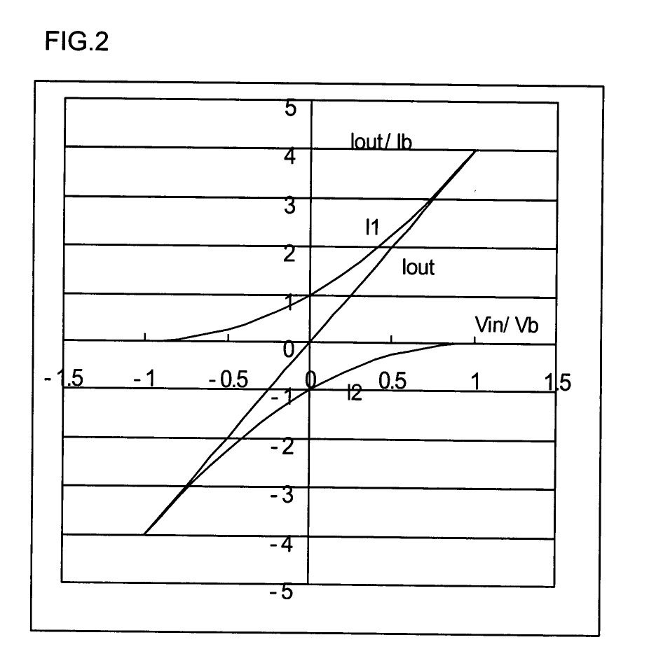

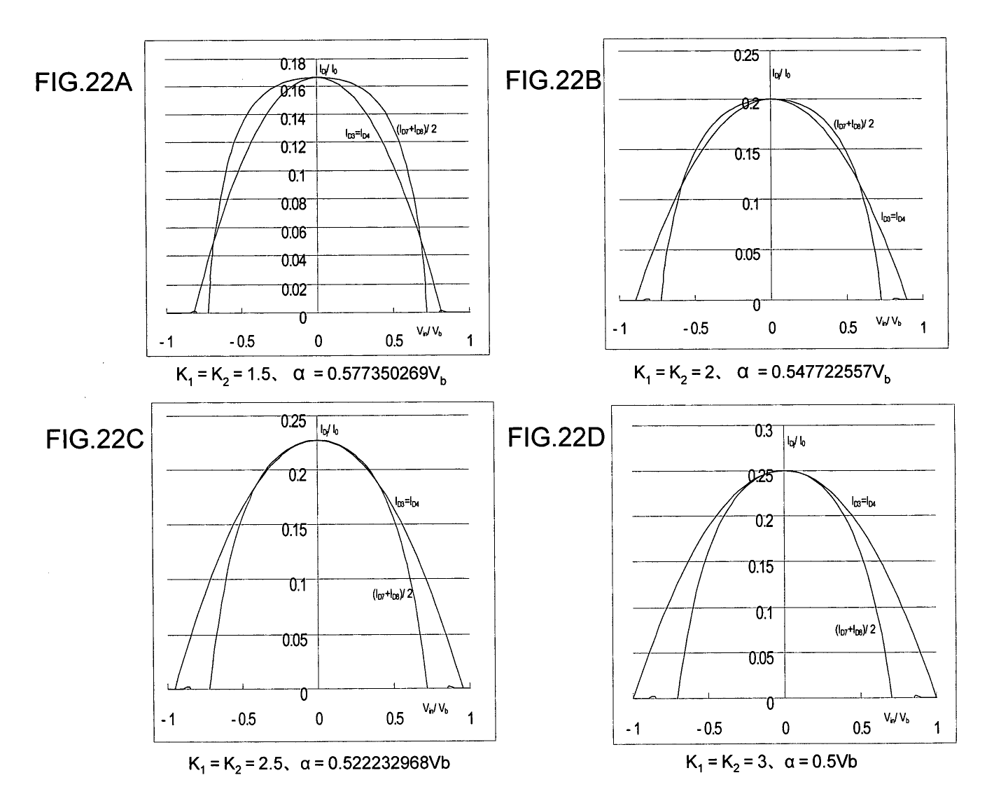

Optimum parameters are searched for so that I_{D3}=I_{D4} and (I_{D7} and I_{D8})/2 are rendered into an equivalent graph using Excel. In FIGS. 22A, 22B, 22C and 2D,
V_{b}=\sqrt{I₀/β}
is set. Also, (a) K₁=K₂=1.5, α=0.577350269 V_{b} (ca. equal to 1/√3) V_{b}, (b) K₁=K₂=2, α=0.547722557V_{b}, (c) K₁=K₂=2.5, α=0.522232968V_{b} and (d) K₁=K₂=3, α=0.5V_{b} are set.

It is seen from FIG. 22 that, for α=0.5Vb, the equation (69) substantially holds for the input voltage range of K2±0.2 V_{b}, and that, for Vᵢₙ=0, I_{D1}=I_{D2}=I_{D3}=I_{D4}. Also, for K₁<3, the transconductance has an equi-ripple characteristic due to intersection at three points. It may be estimated that the ripple will become small as K₁ approaches to 3.

It may further be expected that, under the condition of K₁=3, the maximally flat transconductance characteristic may be achieved.

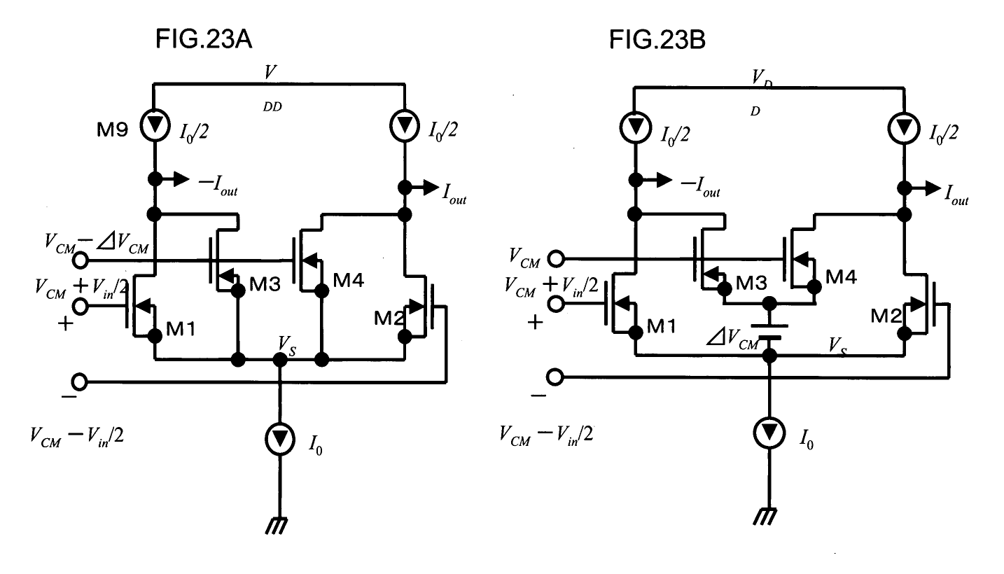

Qualitatively, the present example realizes the square current by varying the source voltage as shown in FIG. 23B in place of varying the gate voltage as in Toyoda OTA circuit shown in FIG. 23A.

$$\begin{matrix}If {I}_{D 1} = {β ( \frac{{V}_{in}}{2} + α )}^{2} \\ and & ( 241 ) \\ {I}_{D 2} = {β ( - \frac{{V}_{in}}{2} + α )}^{2} & ( 242 )\end{matrix}$$

hold, and also

$$\begin{matrix}{I}_{D 3} = {I}_{D 4} = {K}_{1} β {\{ α - ( {V}_{1} - {V}_{S} ) \}}^{2} \\ and & ( 243 ) \\ {V}_{1} - {V}_{S} = α - \sqrt{\frac{1}{{K}_{1}} ( \frac{{I}_{0}}{2 β} - {α}^{2} - \frac{{V}_{in}^{2}}{4} )} \\ hold , then & ( 244 ) \\ {I}_{D 3} = {I}_{D 4} = β ( \frac{{I}_{0}}{2 β} - {α}^{2} - \frac{{V}_{in}^{2}}{4} ) & ( 245 )\end{matrix}$$

holds.

If, in the equations (241), (242) and (245), α is a constant,

$$\begin{matrix}{I}_{D 1} + {I}_{D 3} = βα {V}_{in} + \frac{{I}_{0}}{2} \\ and & ( 246 ) \\ {I}_{D 2} + {I}_{D 4} = - βα {V}_{in} + \frac{{I}_{0}}{2} & ( 247 )\end{matrix}$$

hold and the output becomes linear.

If
α=(½)\sqrt{I₀/β}
then

$$\begin{matrix}{I}_{D 1} = {β ( \frac{{V}_{in}}{2} + \frac{1}{2} \sqrt{\frac{{I}_{0}}{β}} )}^{2} & ( 248 ) \\ {I}_{D 1} = {β ( \frac{{V}_{in}}{2} + \frac{1}{2} \sqrt{\frac{{I}_{0}}{β}} )}^{2} & ( 249 ) \\ {I}_{D 3} = {I}_{D 4} = β ( \frac{{I}_{0}}{4 β} - \frac{{V}_{in}^{2}}{4} ) & ( 250 ) \\ {I}_{D 1} + {I}_{D 3} = \frac{1}{2} \sqrt{β {I}_{0}} {V}_{in} + \frac{{I}_{0}}{2} \\ and & ( 251 ) \\ {I}_{D 2} + {I}_{D 4} = - \frac{1}{2} \sqrt{β {I}_{0}} {V}_{in} + \frac{{I}_{0}}{2} . & ( 252 )\end{matrix}$$

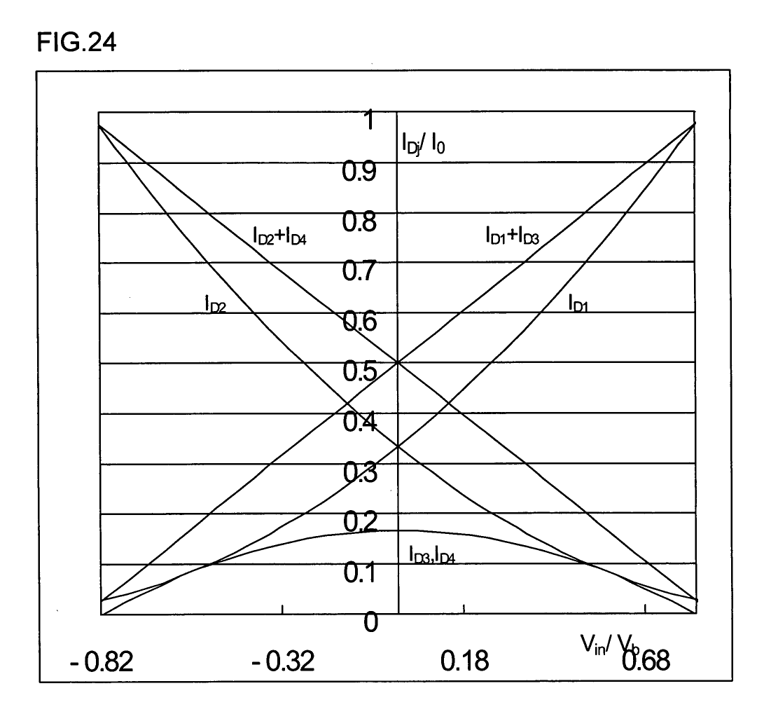

FIG. 24 shows the calculated values of I_{D1}, I_{D2}, I_{D3}, I_{D4}, (I_{D1}+I_{D3}) and (I_{D2}+I_{D4}) for a case where α=V_{b}/\sqrt{3}(=0.57735) (V_{b}=\sqrt{I₀/β}).

The characteristic is now to be verified by SPICE simulation. Here again, device parameters of 0.35 μm rule are used, provided that the back gate and the source of a P-ch transistor are connected together to reduce the substrate effect.

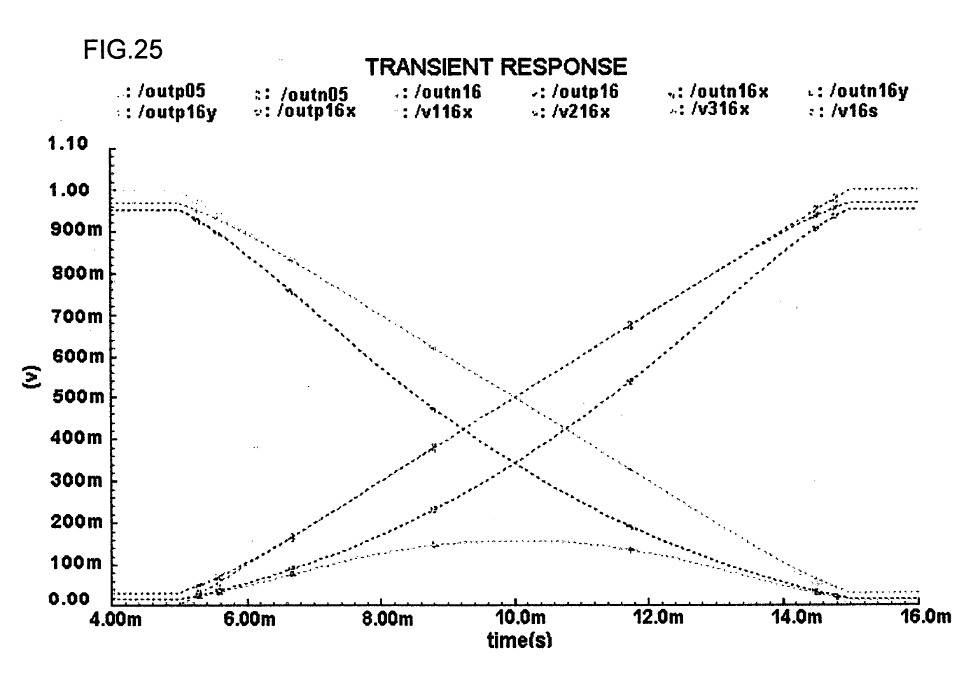

FIG. 25 shows SPICE simulation values in case K₁=3 and K₂=K₃=1 are set. I₀=100 μA, W/L of the transistors M1 and M2 is set to 10 μm/2 μm, W/L of the transistors M3 and M4 is set to 30 μm/2 μm and W/L of the transistors M5 and M6 is set to 10 μm/2 μm. Hence, K₁=3 and K₂=K₃=1. This setting is a setting changed from the setting of K₁=K₂=K₃=0 for which linearity has been deteriorated. Here, TRAN (transient) analysis is carried out and, as a differential input voltage, the voltage is linearly changed from 0.5V@5 mS to 1.5V@15 mS on the (+) side input terminal and from 1.5V@5 mS to 0.5V@15 mS on the (−) side input terminal. The current is converted via 10 kΩ resistor into a voltage, which is illustrated.

It may be confirmed that the output current characteristic of the circuit shows good linearity and substantially overlap with a straight line, with an offset from the straight line being on the order of −4% at the maximum (Vin=0.5V@15 mS, 1.5@15 mS, 1.5@5 mS and 0.5V@15 mS).

This differential circuit showed sufficient linearity even in case of setting to K₁=K₂=K₃=2. FIG. 2 shows the values of SPICE simulation in case of setting to K₁=K₂=K₃=2. It can be seen that the output current characteristic shows good linearity and substantially overlap with a straight line. The offset from the straight line is on the order of −4% at the maximum (Vᵢₙ=0.5V@5 mS, 1.5@15 mS, 1.5@5 mS and 0.5V@15 mS).

### FIFTH EXAMPLE

The differential circuit of FIG. 21 is in need of a common mode voltage of the input voltage. If the common mode voltage of the input voltage is unnecessary, the number of terminals may be decreased to improve ease in use further.

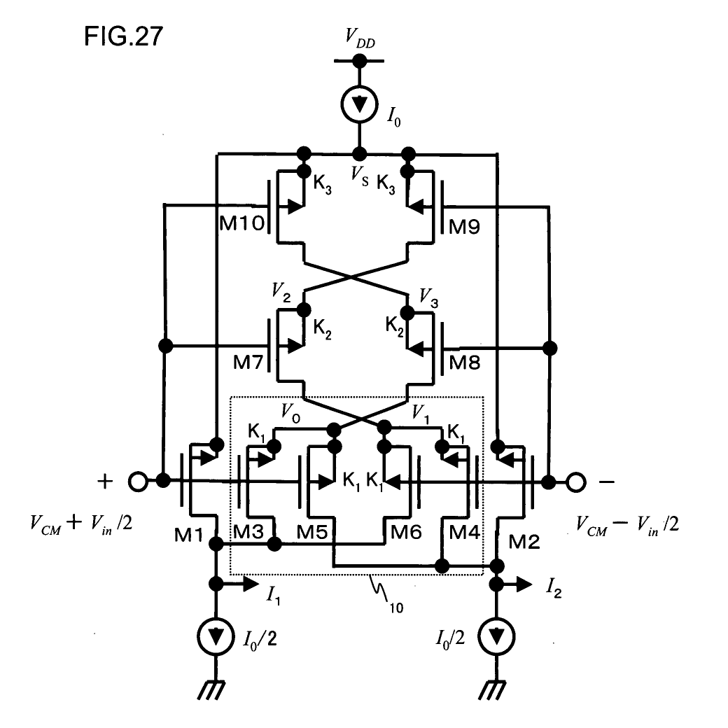

FIG. 27 shows a circuit configuration of an example of a differential circuit of the present invention (corresponding to claim 6).

In FIG. 27, PMOS transistors M1 and M2 constitute a first transistor pair. To the gates of these transistors is supplied the differential input signal (V_{CM}+Vᵢₙ/2, V_{CM}−Vᵢₙ/2). To the second transistor pair, made up by PMOS transistors M3 and M4, and to the third transistor pair, made up by PMOS transistors M5 and M6, is also supplied the differential input signal (V_{CM}+Vᵢₙ/2, V_{CM}−Vᵢₙ/2).

Outputs of the first transistor pair (M1, M2) and the second transistor pair (M3, M4) are connected in parallel, while outputs of the first transistor pair (M1, M2) and the third transistor pair (M5, M6) are cross-coupled to constitute an output pair. The sources of the transistors M3 and M5 are coupled together, while the sources of the transistors M4, M6 are also coupled together. The transistors (M3 to M6) compose a bypass current distributor 10.

To the gates of a PMOS transistor M7 and a PMOS transistor M8, making up a fourth transistor pair, is supplied the differential input signal (V_{CM}+Vᵢₙ/2, V_{CM}−Vᵢₙ/2). The PMOS transistor M7 has a drain connected to coupled sources of the PMOS transistors M4 and M6, whilst the PMOS transistor M8 has a drain connected to coupled sources of the PMOS transistors M3 and M5. The transistors M8 and M7 are cascode-connected to the transistors M3 and M5 and to the transistors M4 and M6, respectively.

To the gates of the fifth transistor pair, made up of the PMOS transistors M9 and M10, is supplied the differential input signal (V_{CM}−Vᵢₙ/2, V_{CM}+Vᵢₙ/2) that is in reverse phase with respect to the differential input signal (V_{CM}+Vᵢₙ/2, V_{CM}−Vᵢₙ/2). The drains of the PMOS transistors M9 and M10 are connected to the sources of the PMOS transistors M7 and M8. The PMOS transistors M9 and M10 are cascode-connected to the PMOS transistors M7 and M8, respectively.

The sources of the first transistor pair (M1, M2) and the fifth transistor pair (M9, M10) are coupled together and driven by a constant current source I_{O}.

The operation of the present example is now described. In the differential circuit of FIG. 27, circuit analysis is omitted and circuit characteristic is confirmed by SPICE simulation. Here again, device parameters of the 0.35 μm are used. It is noted that Pch transistors are used and back-gates and sources thereof are connected together to reduce the substrate effect. IO=100 μA, W/L of the transistors M1, M2 is 10 μm/2 μm, W/L of the transistors M3, M4 is 30 μm/2 μm and W/L of the transistors M5, M6 is 10 Mm/2 μm. Hence, K₁=3 and K₂=K₃=1. Here, TRAN (transient) analysis is carried out and, as a differential input voltage, the voltage is linearly changed from 1.5V@5 mS to 1.5V@15 mS on the (+) side input terminal and from 1.5V@5 mS to 0.5V@15 mS on the (−) side input terminal. The current is converted via 10 kΩ resistor into a voltage, which is illustrated.

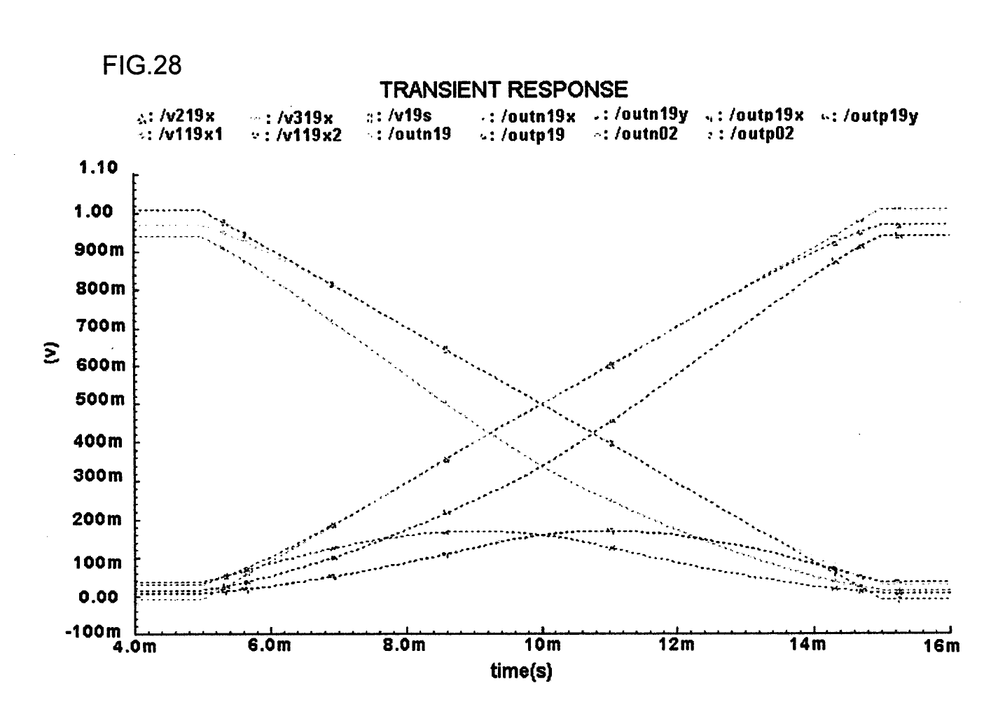

FIG. 28 shows SPICE simulation values in case of setting K₁=3 and K₂=K₃=1.

It can be seen that the output current characteristic shows good linearity and substantially overlap with a straight line. The offset from the straight line is on the order of −4% at the maximum (Vin=0.5V@5 mS, 1.5@15 mS, 1.5V@5 mS and 0.5V@15 mS).

### SIXTH EXAMPLE

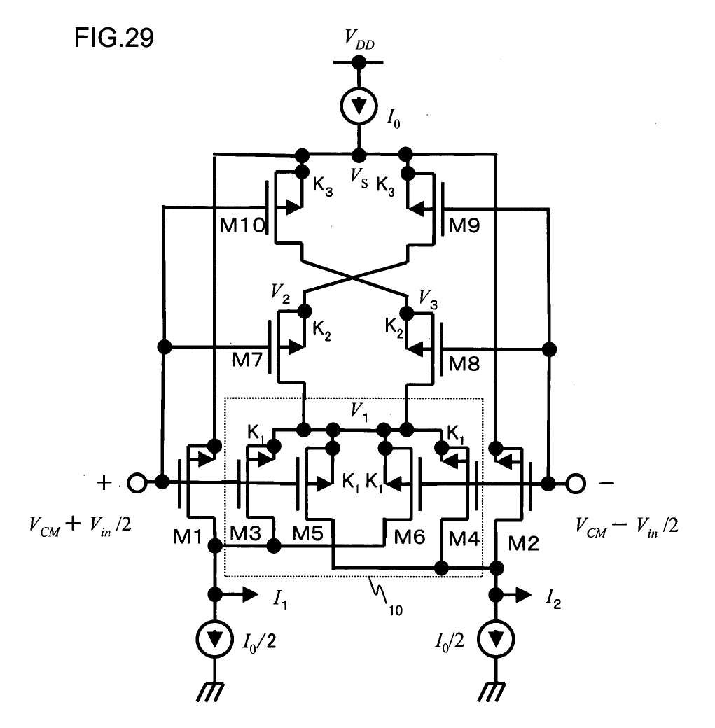

FIG. 29 shows a circuit configuration of an example of a differential circuit of the present invention (corresponding to claim 7).

In FIG. 29, PMOS transistors M1 and M2 constitute a first transistor pair. To the gates of these transistors is supplied the differential input signal (V_{CM}+Vᵢₙ/2, V_{CM}−Vᵢₙ/2). To a second transistor pair, made up by PMOS transistors M3 and M4, and to a third transistor pair, made up by PMOS transistors M5 and M6, is also supplied the differential input signal (V_{CM}+Vᵢₙ/2, V_{CM}−Vᵢₙ/2).

Outputs of the first transistor pair (M1, M2) and the second transistor pair (M3, M4) are connected in parallel, while outputs of the first transistor pair (M1, M2) and the third transistor pair (M5, M6) are cross-coupled to constitute an output pair. The sources of the transistors M3 to M6 are connected together. The transistors (M3 to M6) compose a bypass current distributor 10.

To the gates of a PMOS transistor M7 and a PMOS transistor M8, making up a fourth transistor pair, is supplied the differential input signal (V_{CM}+Vᵢₙ/2, V_{CM}−Vᵢₙ/2). The PMOS transistor M7 has a drain connected to coupled sources of the PMOS transistors M3, M4, M5 and M6, whilst the PMOS transistor M8 also has a drain connected to coupled sources of the PMOS transistors M3, M4, M5 and M6.

To a fifth transistor pair, made up of PMOS transistors M9 and M10, is supplied the differential input signal (V_{CM}−Vᵢₙ/2, V_{CM}+Vᵢₙ/2) that is in reverse phase with respect to the differential input signal (V_{CM}+Vᵢₙ/2, V_{CM}−Vᵢₙ/2) supplied to the first transistor pair (M1, M2). The drains of the PMOS transistors M9 and M10 are connected to the sources of the PMOS transistors M7 and M8. The transistors M9 and M10 are cascode-connected to the transistors M7 and M8.

The sources of the first transistor pair (M1, M2) and the fifth transistor pair (M9, M10) are coupled together and driven by a constant current source I_{O}.

The operation of the present example is now described. In the differential circuit of FIG. 29, circuit analysis is omitted and circuit characteristic is confirmed by SPICE simulation.

Here again, device parameters of the 0.35 μm are used. It is noted that Pch transistors are used and back-gates and sources thereof are connected together to reduce the substrate effect. Iₒ=100 μA, W/L of the transistors M1, M2 is 10 μm/2 μm, W/L of the transistors M3, M4 is 30 μm/2 μm and W/L of the transistors M5, M6 is 10 μm/2 μm. Thus, setting is K₁=3 and K₂=K₃=1. Here, TRAN (transient) analysis is carried out and, as a differential input voltage, the voltage is linearly changed from 0.5V@5 mS to 1.5V@15 mS on the (+) side input terminal and from 1.5V@5 mS to 0.5V@15 mS on the (−) side input terminal. The current is converted via 10 kΩ resistor into a voltage, which is illustrated.

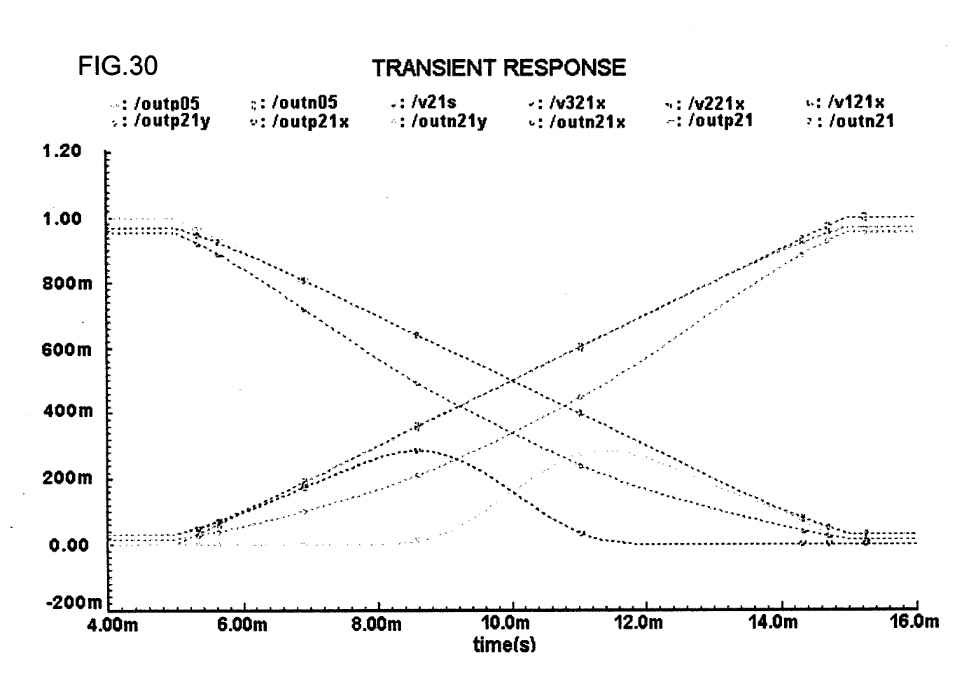

FIG. 30 shows SPICE simulation values in case of setting K₁=3 and K₂=K₃=1.

It can be seen that the output current characteristic shows good linearity and substantially overlap with a straight line. The offset from the straight line is on the order of −3% at the maximum (Vin=0.5V@5 mS, 1.5@15 mS, 1.5V@5 mS and 0.5V@15 mS).

### SEVENTH EXAMPLE

In a differential circuit, shown in FIG. 21, the transistors generating the square currents may be changed from the cascoded transistors to triple cascoded transistors.

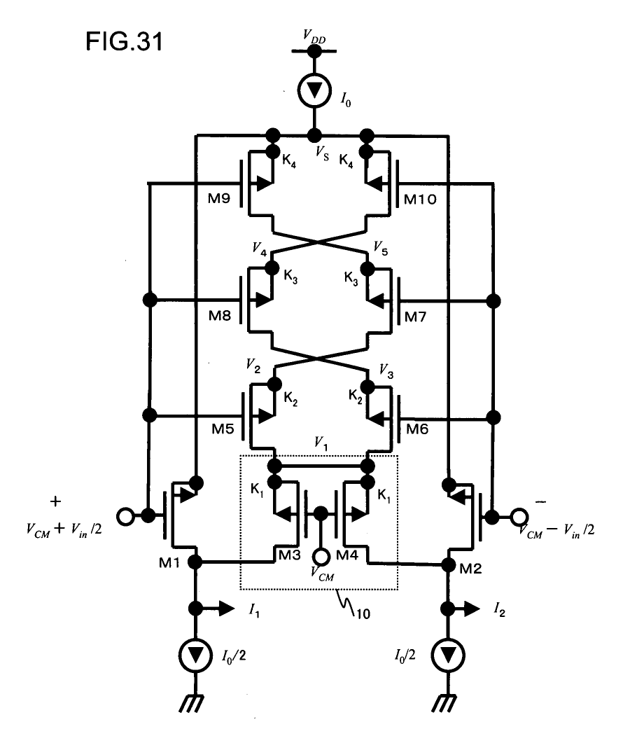

FIG. 31 shows a circuit configuration of an example of a differential circuit of the present invention (corresponding to claim 8). In FIG. 31, PMOS transistors M1 and M2 constitute a first transistor pair. To the gates of these transistors is supplied the differential input signal (V_{CM}+Vᵢₙ/2, V_{CM}−Vᵢₙ/2). To the gates of the second transistor pair, made up of the PMOS transistors M3 and M4, is supplied the common mode voltage (V_{CM}) of the differential input signal.

Outputs of the first transistor pair (M1, M2) and the second transistor pair (M3, M4) are connected in parallel to constitute an output pair. The sources of the transistors M3, M4 of the second transistor pair are connected to each other. The drains of the PMOS transistors M3 and M1 are coupled together, while the drains of the PMOS transistors M4 and M2 are also coupled together, with the coupled drains constituting an output pair. The transistors (M3, M4) compose a bypass current distributor 10.

To the gates of a PMOS transistor M5 and a PMOS transistor M6, making up a third transistor pair, is supplied the differential input signal (V_{CM}+Vᵢₙ/2, V_{CM}−Vᵢₙ/2). The drains of the PMOS transistor M5, P6, making up the third transistor pair, are connected to coupled sources of the PMOS transistors M3 and M4 of the second transistor pair. The transistors M5 and M6 of the third transistor pair are cascode-connected to the second transistor pair (M3, M4).

To the gates of PMOS transistors M7 and M8, making up a fourth transistor pair, also supplied the differential input signal (V_{CM}−Vᵢₙ/2, V_{CM}+Vᵢₙ/2). The sources of the PMOS transistors M7 and M8 are connected to the drains of the PMOS transistors M5 and M6. The transistors M5 and M6 are cascode-connected to the transistors M3 and M4 of the second transistor pair.

To the gates of PMOS transistors M9 and M10, making up a fifth transistor pair, is also supplied the differential input signal (V_{CM}+Vᵢₙ/2, V_{CM}−Vᵢₙ/2). The sources of the PMOS transistors M9 and M10 are connected to the drains of the PMOS transistors M7 and M8. The transistors M9 and M10 are cascode-connected to the transistors M7 and M8.

The sources of the first transistor pair (M1, M2) and the fifth transistor pair (M9, M10) are coupled together and driven by a constant current source I_{O}.

The operation of the present example is now described. In the differential circuit of FIG. 31, circuit analysis is omitted and circuit characteristic is confirmed by SPICE simulation. Here again, device parameters of the 0.35 μm are used. It is noted that Pch transistors are used and back-gates and sources thereof are connected together to reduce the substrate effect. I_{O}=100 μA, W/L of the transistors M1, M2 is 10 μm/2 μm, W/L of the transistors M3, M4 is 30 μm/2 μm and W/L of the transistors M5, M6 is 10 μm/2 μm. Hence, setting is K₁=3 and K₂=K₃=1. Here, TRAN (transient) analysis is carried out and, as a differential input voltage, the voltage is linearly changed from 0.5V@5 mS to 1.5V@15 mS on the (+) side input terminal and from 1.5V@5 mS to 0.5V@15 mS on the (−) side input terminal. The current is converted via 10 kΩ resistor into a voltage, which is illustrated.

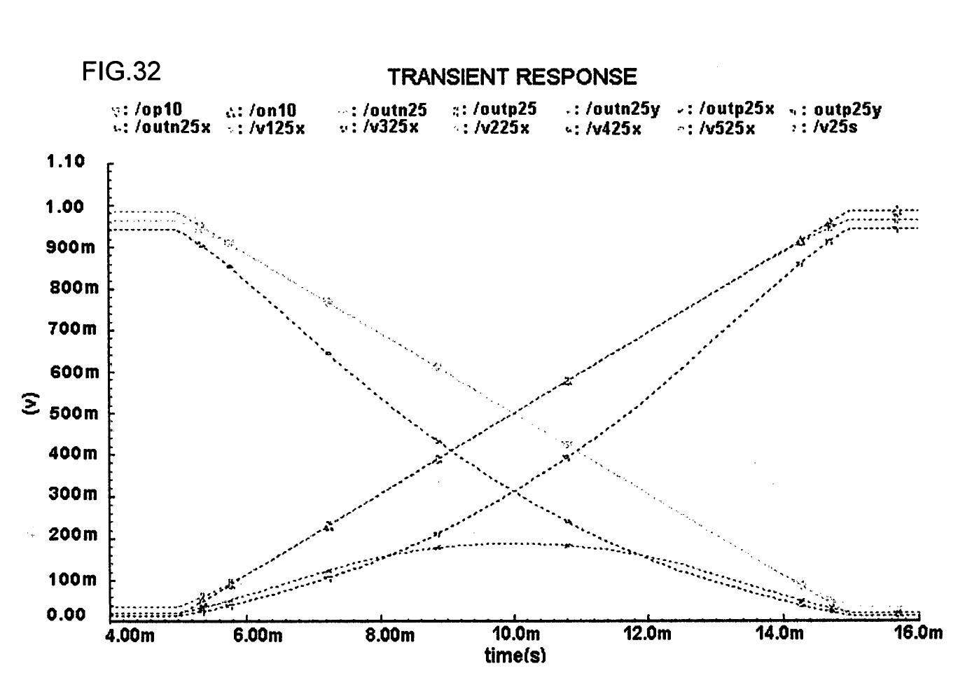

FIG. 32 shows the values of SPICE simulation in case of setting to K₁=3, K₂=1.8, K₃=2 and K₄= 1/9.

It can be seen that the output current characteristic shows good linearity and substantially overlap with a straight line. The offset from the straight line is on the order of −3% at the maximum (Vᵢₙ=0.5V@5 mS, 1.5@15 mS, 1.5V@5 mS and 0.5V@15 mS).

### EIGHTH EXAMPLE

In the differential circuit, shown in FIG. 27, the transistors generating the square currents may be changed from the cascoded transistors to triple cascoded transistors.

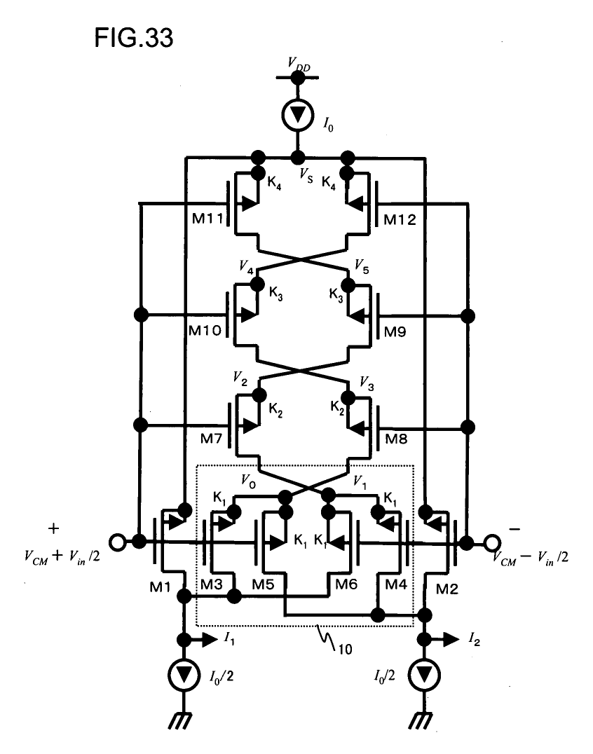

FIG. 33 shows a circuit configuration of an example of a differential circuit of the present invention (corresponding to claim 9).

In FIG. 33, PMOS transistors M1 and M2 constitute a first transistor pair. To the gates of these transistors is supplied the differential input signal (V_{CM}+Vᵢₙ/2, V_{CM}−Vᵢₙ/2). To a second transistor pair, made up by PMOS transistors M3 and M4, and to a third transistor pair, made up by PMOS transistors M5 and M6, is also supplied the differential input signal (V_{CM}+Vᵢₙ/2, V_{CM}−Vᵢₙ/2).

Outputs of the first transistor pair (M1, M2) and the second transistor pair (M3, M4) are connected in parallel, whilst outputs of the first transistor pair (M1, M2) and outputs of the third transistor pair (M5, M6) are cross-coupled to constitute an output pair. That is, the drains of the PMOS transistors M1, M3 and M6 are coupled together, while the drains of the PMOS transistors M2, M4 and M5 are also coupled together, with the commonly coupled drains constituting an output pair. Also, the sources of the transistors M3 and M5 are coupled together, whilst the sources of the transistors M4 and M6 are coupled together. The transistors (M3 to M6) compose a bypass current distributor 10.

To the gates of a PMOS transistor M7 and a PMOS transistor M8, making up a fourth transistor pair, is supplied the differential input signal (V_{CM}+Vᵢₙ/2, V_{CM}−Vᵢₙ/2). The drain of the PMOS transistor M7 is connected to coupled sources of the PMOS transistors M4 and M6, whilst the drain of the PMOS transistor M8 is connected to coupled sources of the PMOS transistors M3 and M5. The transistors M8 and M7 are cascode-connected to the transistors M3, M5 and M4, M6, respectively.

To the gates of PMOS transistors M9 and M10, making up a fifth transistor pair, is supplied the differential input signal (V_{CM}−Vᵢₙ/2, V_{CM}+Vᵢₙ/2) that in reverse phase with respect to the differential input signal (V_{CM}+Vᵢₙ/2, V_{CM}−Vᵢₙ/2) supplied to the first transistor pair. The sources of the PMOS transistors M7 and M8 are connected to the drains of the PMOS transistors M9 and M10. The transistors M9 and M10 are cascode-connected to the transistors M7 and M8.

To the gates of PMOS transistors M11 and M12, making up a sixth transistor pair, is also supplied the differential input signal (V_{CM}+Vᵢₙ/2, V_{CM}Vᵢₙ/2). The sources of the PMOS transistors M7 and M8 are connected to the drains of the PMOS transistors M11 and M12. The transistors M1 and M12 are cascode-connected to the transistors M9 and M10, respectively.

The sources of the first transistor pair (M1, M2) and the sixth transistor pair (M11, M12) are coupled together and driven by a constant current source I_{O}.

The operation of the present example is now described. In the differential circuit of FIG. 33, circuit analysis is similarly omitted and circuit characteristic is confirmed by SPICE simulation. Here again, device parameters of the 0.35 μm are used. It is noted that Pch transistors are used and back-gates and sources thereof are connected together to reduce the substrate effect. I_{O}=100 μA, W/L of the transistors M1, M2 is 10 μm/2 μm, W/L of the transistors M3, M4 is 30 μm/2 μm and W/L of the transistors M5, M6 is 10 μm/2 μm. Hence, setting is K₁=3 and K₂=K₃=1. Here, TRAN (transient) analysis is carried out and, as a differential input voltage, the voltage is linearly changed from 0.5V@5 mS to 1.5V@15 mS on the (+) side input terminal and from 1.5V@5 mS to 0.5V@15 mS on the (−) side input terminal. The current is converted via 10 kΩ resistor into a voltage, which is illustrated.

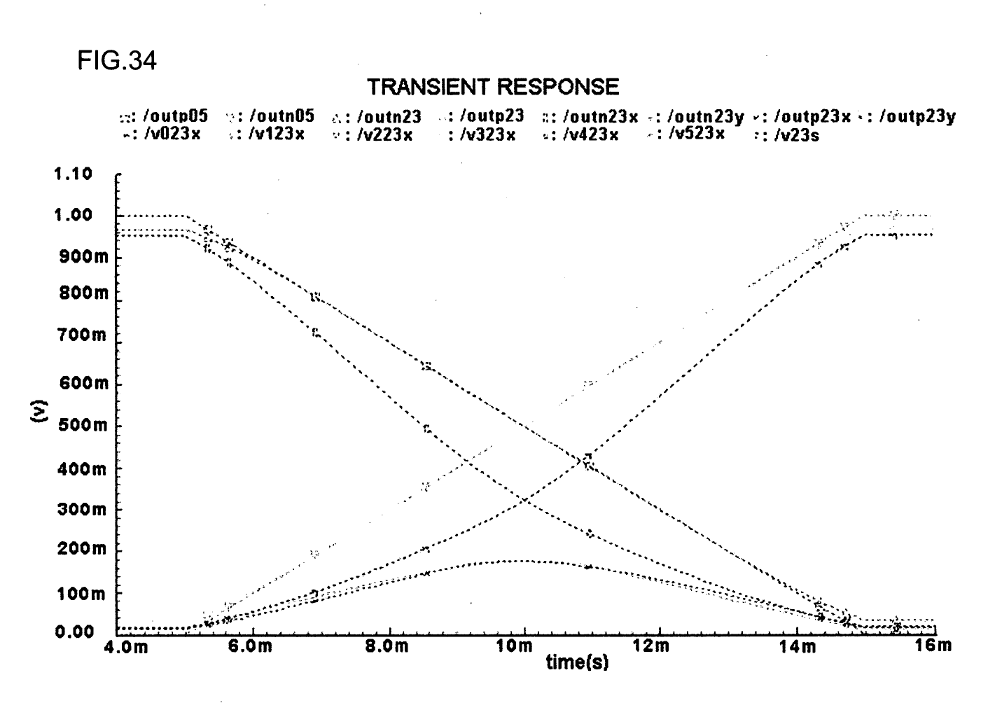

FIG. 34 shows values of SPICE simulation in case of setting K₁=K₂=K₃=1.732 (nearly equal to √3)

It can be seen that the output current characteristic shows good linearity and substantially overlap with a straight line. The offset from the straight line is on the order of −3% at the maximum (Vᵢₙ=0.5V@5 mS, 1.5V@15 mS, 1.5V@5 mS and 0.5V@15 mS).

### NINTH EXAMPLE

In the differential circuit, shown in FIG. 29, the transistors generating the square currents may be changed from the cascoded transistors to triple cascoded transistors.

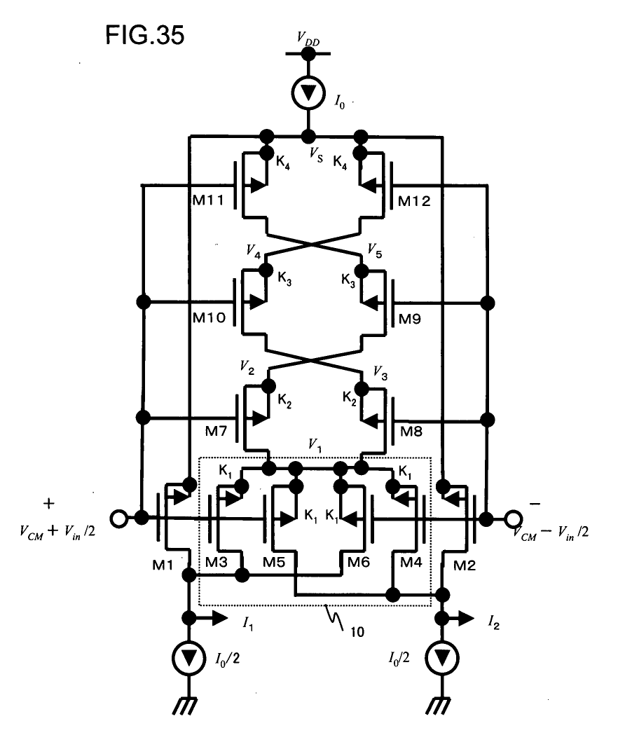

FIG. 35 shows a circuit configuration of an example of a differential circuit of the present invention (corresponding to claim 10). In FIG. 35, PMOS transistors M1 and M2 constitute a first transistor pair. To the gates of these transistors is supplied the differential input signal (V_{CM}+Vᵢₙ/2, V_{CM}−Vᵢₙ/2). To the gates of a second transistor pair, made up by PMOS transistors M3 and M4, and a third transistor pair, made up by PMOS transistors M5 and M6, is also supplied the differential input signal (V_{CM}+Vᵢₙ/2, V_{CM}−Vᵢₙ/2).

Outputs of the first transistor pair (M1, M2) and the second transistor pair (M3, M4) are connected in parallel, whilst outputs of the first transistor pair (M1, M2) and the third transistor pair (M5, M6) are cross-coupled to constitute an output pair. That is, the drains of the PMOS transistors M1, M3 and M6 are coupled together, while the drains of the PMOS transistors M2, M4 and M5 are also coupled together, with the commonly coupled drains constituting an output pair. The sources of the transistors M3, M4, M5 and M6 are coupled together. The transistors (M3 to M6) compose a bypass current distributor 10

To the gates of a PMOS transistor M7 and a PMOS transistor M8, making up a fourth transistor pair, is supplied the differential input signal (V_{CM}+Vᵢₙ/2, V_{CM}−Vᵢₙ/2). The drains of the PMOS transistor M7, M8 are connected to coupled sources of the PMOS transistors M3 to M6. The transistors M7 and M8 of the fourth transistor pair are cascode-connected to the second transistor pair (M3, M4) and to the third transistor pair (M5, M6), respectively.

To the PMOS transistors M9 and M10, making up the fifth transistor pair, is supplied the differential input signal (V_{CM}−Vᵢₙ/2, V_{CM}+Vᵢₙ/2) that is in reverse phase with respect to the differential input signal (V_{CM}+Vᵢₙ/2, V_{CM}−Vᵢₙ/2) supplied to the first transistor pair. The sources of the PMOS transistors M7 and M8 are connected to the drains of the PMOS transistors M9 and M10, respectively. The transistors M9 and M10 are cascode-connected to the transistors M7 and M8, respectively.

To the gates of the PMOS transistors M11 and M12, making up the sixth transistor pair, is also supplied the differential input signal (V_{CM}+Vᵢₙ/2, V_{CM}−Vᵢₙ/2). The sources of the PMOS transistors M9 and M10 are connected to the drains of the PMOS transistors M11 and M12, respectively. The transistors M11 and M12 are cascode-connected to the transistors M9 and M10, respectively.

The sources of the first transistor pair (M1, M2) and the sixth transistor pair (M11, M12) are coupled together and driven by a constant current source I_{O}.

The operation of the present example is now described. In the differential circuit of FIG. 35, circuit analysis is similarly omitted and circuit characteristic is confirmed by SPICE simulation. Here again, device parameters of the 0.35 μm are used. It is noted that Pch transistors are used and back-gates and sources thereof are connected together to reduce the substrate effect. I_{O}=100 μA, W/L of the transistors M1, M2 is 10 μm/2 μm, W/L of the transistors M3, M4 is 30 μm/2 μm and W/L of the transistors M5, M6 is 10 μm/2 μm. Hence, setting is K₁=3 and K₂=K₃=1. Here, TRAN (transient) analysis is carried out and, as a differential input voltage, the voltage is linearly changed from 0.5V@5 mS to 1.5V@15 mS on the (+) side input terminal and from 1.5V@5 mS to 0.5V@15 mS on the (−) side input terminal. The current is converted via 10 kΩ resistor into a voltage, which is illustrated.

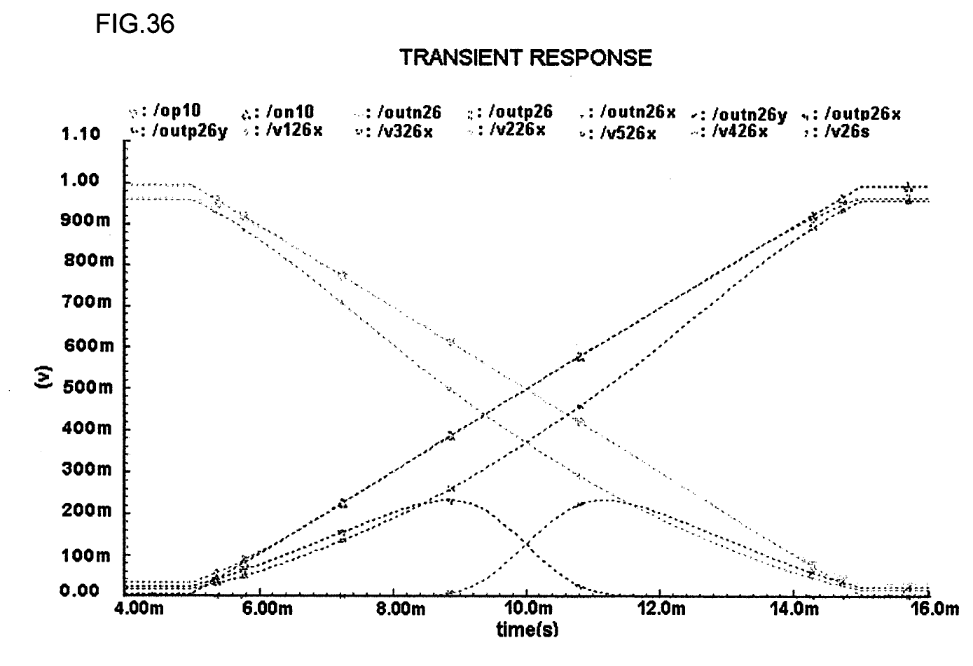

FIG. 36 shows SPICE simulation values in case of setting K₁=4 and K₂=K₃=K₄=1.5.

It can be seen that the output current characteristic shows good linearity and substantially overlap with a straight line. The offset from the straight line is on the order of −4% at the maximum (Vin=0.5V@5 mS, 1.5@15 mS, 1.5V@5 mS and 0.5V@15 mS).

### TENTH EXAMPLE

In the differential circuits, shown in FIGS. 31, 33 and 35, the transistors generating the square currents may be changed from the triple cascoded transistors to cascoded transistors of a larger number of stages of cascoded connection, provided that the voltage sufficient to permit connection of multiply cascoded transistors is ensured.

### ELEVENTH EXAMPLE

From the results of the circuit analyses of the Prodanov's OTA circuit, discussed above in connection with the related art, it may be seen that linearity can hardly be improved with the conditions stated in Prodanov's U.S. Pat. No. 6,577,170 B1.

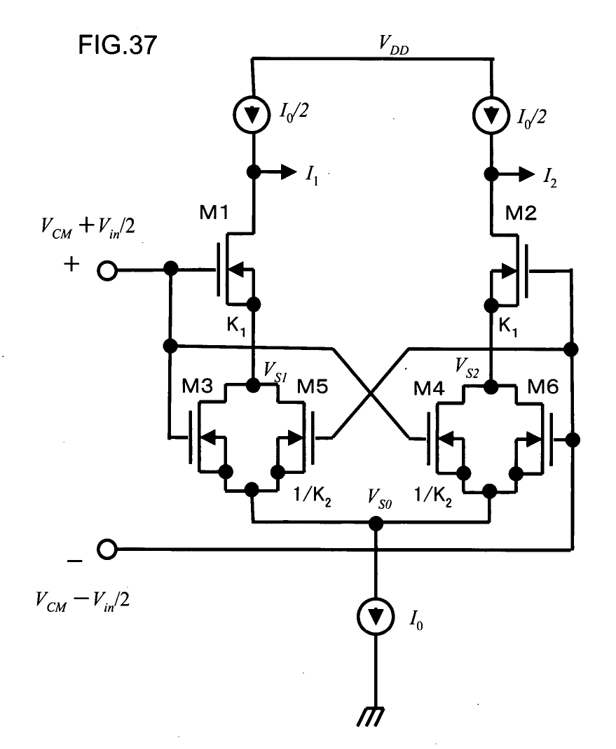

The optimum condition for improving linearity is now clarified from the results of analyses of the Prodanov's OTA circuit, and such circuit is described. FIG. 37 shows the constitution of an example of the present invention (corresponding to claim 12).

In FIG. 37, NMOS transistors M1 and M2 constitute a first transistor pair. To the gates of these transistors is supplied the differential input signal (V_{CM}+Vᵢₙ/2, V_{CM}−Vᵢₙ/2). To the gates of NMOS transistors M3 and M6 that constitute a second transistor pair and to the gates of NMOS transistors M4 and M5 that constitute a third transistor pair, there are similarly supplied the differential input signal (V_{CM}+Vᵢₙ/2, V_{CM}−Vᵢₙ/2).

The drains of the first transistor pair (M1, M2), a constant current source (I_{O}/2) is connected to constitute an output pair. The current of the constant current source is one-half the tail current of each of the transistors. The first transistor pair (M1, M2) and the second transistor pair (M3, M6) are connected in cascode, respectively, whilst the second transistor pair (M3, M6) and the third transistor pair (M4, M5) are connected in parallel. Hence, the sources of the transistors M3 to M6 are connected together and driven with the constant current I_{O}.

The operation of the present example is now described. If, in FIG. 37 the size of the second transistor pair (M3, M6) is 1, the size K₁ of the first transistor pair (M1, M2) is K and the size 1/K₂ of the third transistor pair (M4, M5) is 1, the circuit analyses of the conventional Prodanov's OTA circuit of may be used unchanged.

The second transistor pair (M3, M6) and the third transistor pair (M4, M5), connected in parallel with each other, play the role of degeneration resistors. These transistors operate in the linear region as long as the amplitude of the differential input voltage Vᵢₙ is small. With increase in the differential input voltage Vᵢₙ one of the transistors of the third transistor pair (M4, M5) transitions to the operation in the saturation region. Hence, transconductance increases with change (increase) in the value of the current caused to flow through the degeneration resistance, resulting in the increased amplitude value of the differential input voltage Vin for which the offset from a constant transconductance value is comprised within a preset range.

Specifically, the transistor M5 transitions to the operation in the saturation region in case Vin>>0, whereas the transistor M4 transitions to the operation in the saturation region in case Vin <<0.

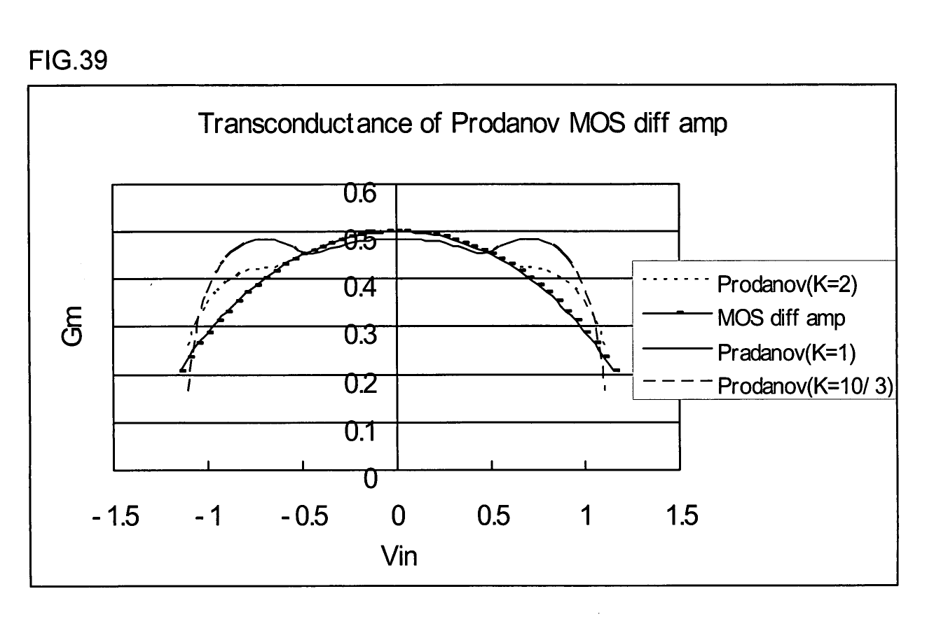

The transconductance characteristic was found from the equation of circuit analysis of the conventional Prodanov's OTA, as shown in FIG. 39. The linearity is improved most outstandingly when the transconductance characteristic represents an equi-ripple characteristic. The value of K that yields this is K=10/3.

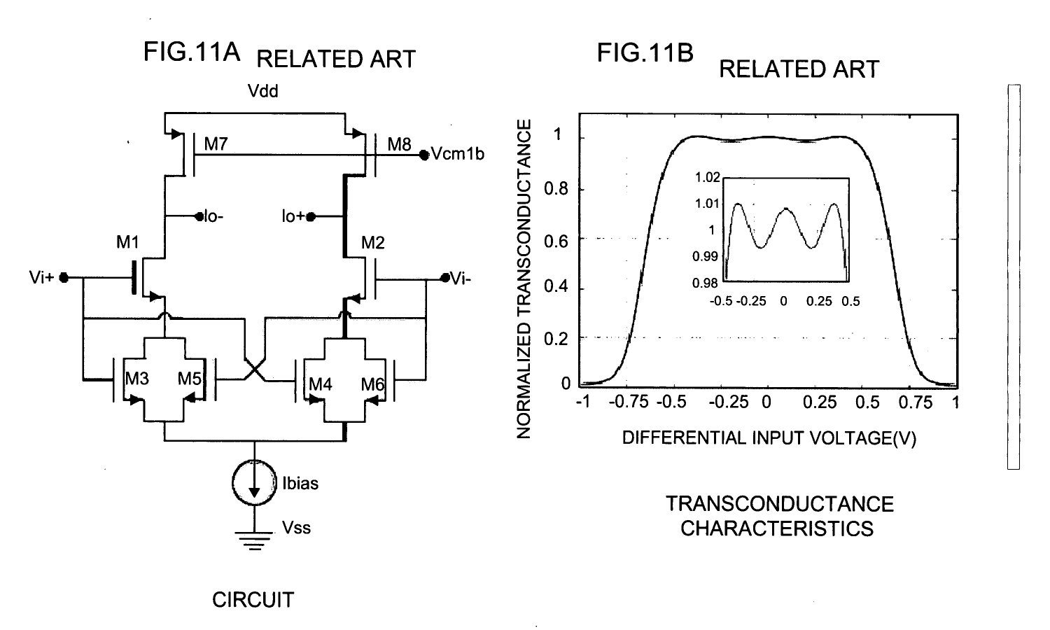

The peaks of left and right ripples are equal in height to the peak of the center ripple, though such is the matter of course. Differentiation of the valleys of these ripples gives differential coefficients of discrete values. As actual natural or physical phenomenon, the valleys of these ripples become somewhat smoothed such that characteristic shown in FIG. 11B may be expected to be achieved.

In FIG. 39, the valley is −7% in case K=10/3, which is larger than −2% shown in FIG. 11B.

The result of circuit analysis by the present inventor indicates that linearity can hardly be improved with the condition of K=2, stated in Prodanov's U.S. Pat. No. 6,577,170 B1, as shown in FIG. 30. The value of K should be set so that K is in the vicinity of 10/3 (=3.33333). This (not K=2 but K=10/3 (=3.3333)) may be confirmed by SPICE simulation.

Only by way of reference, the present inventor has had an impression that the equi-ripple transconductance characteristic for K=10/3, shown in FIG. 39, is very close to the transconductance characteristic of MOS OTA shown in the JP Patent Kokoku JP-B-8-8457, the inventor of which is the same as the present inventor.

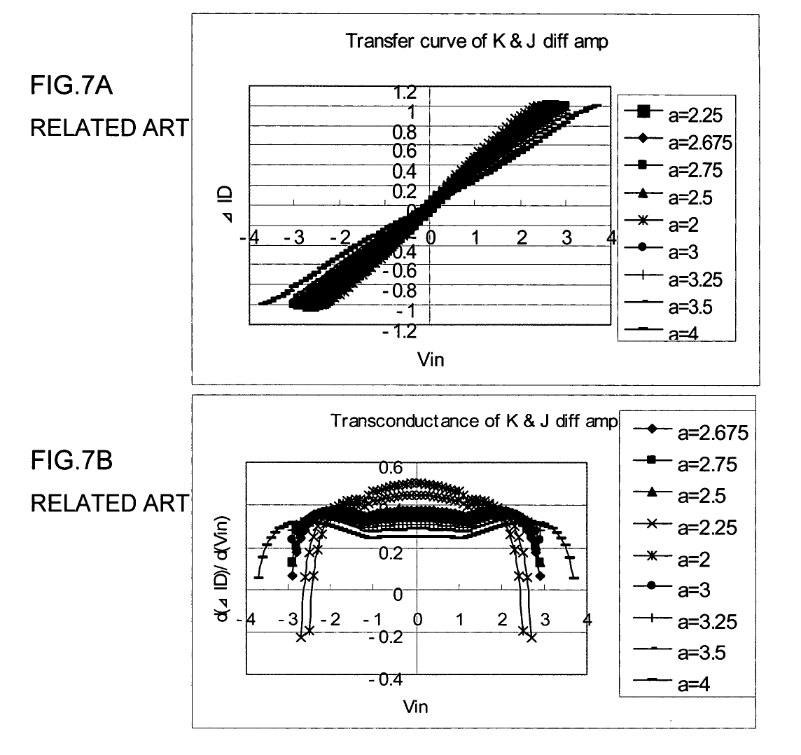

It should be remarked that the ripple value of the transconductance characteristic shown in FIG. 39 has been reduced to approximately one-half of the ripple value of the transconductance characteristic shown in FIG. 7 of JP Patent Kokoku JP-B-8-8457.

In case of using a parallel connected transistors as equivalent resistors, there is no necessity for parallel connected transistors to be of equal transistor size.

The operation of the present example is now described. In FIG. 37, the transistor sizes of the transistor pairs (M3, M6), (M1, M2) and (M4), (M5) are set to 1, K, and 1/K₂, respectively. In this case, the circuit analysis of the Prodanov's OTA circuit cannot be applied as is.

The transistor pairs (M3, M6) and (M4, M5), connected parallel to each other, play the role of degeneration resistors. These transistors operate in the linear region as long as the amplitude of the differential input voltage Vᵢₙ is small. With increase in the differential input voltage Vᵢₙ, one of the transistors of the third transistor pair (M4, M5) transitions to the operation in the saturation region. Hence, transconductance increases with change (increase) in the value of the current caused to flow through the degeneration resistance, resulting in the increased amplitude value of the differential input voltage Vᵢₙ for which the offset from a constant transconductance value is comprised within a preset range. Specifically, the transistor M5 transitions to the operation in the saturation region in case Vᵢₙ>>0, whereas the transistor M4 transitions to the operation in the saturation region in case V_{in<}0.

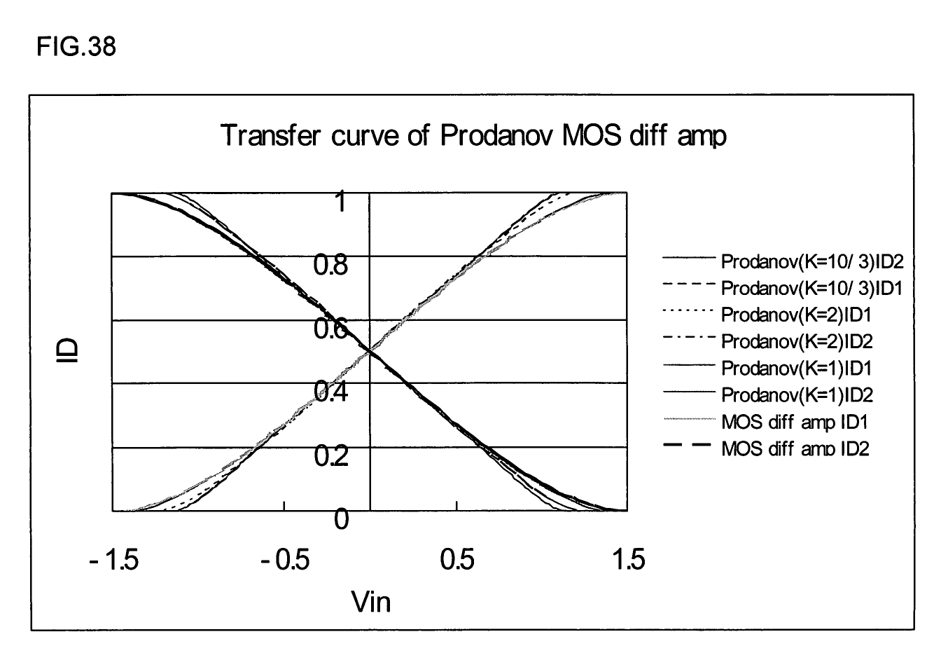

FIG. 38 shows the input/output characteristic (calculated values) of the input voltage Vᵢₙ and the output current ID of the differential circuit of the present example shown in FIG. 37. FIG. 39 shows the transconductance characteristic (calculated values) of the differential circuit of the present example shown in FIG. 37. In the SPICE simulation of the differential circuit of FIG. 37, it has been confirmed that, if, with K1=10/3 (=3.33333), 1/K₂=0.433 and 1/K₂=0.666, linearity may be improved more prominently than if K=10/3 shown in FIG. 38. The range of optimum values of K₂ is on the order of 1.5 to 2.5, that may be rounded to an integer from 1 to 3. It is noted that the case where K₂=1 is no other than the case of K=10/3 shown in FIG. 38.

Among examples of possible use of the differential circuit of the present invention, there are an LPF (Low Pass Filter) or a BPF (Band pass Filter), implementing a reception bandwidth selecting filter in a wireless unit chip, integrated on an LSI, and an OTA circuit for implementing a complex filter by a gm-C filter. With recent progress towards further miniaturization of the integrated circuit process, the frequency response is improved, and the demand imposed on an RF-MOS integrated on one chip is becoming severer. The circuit of the present invention may respond to such demand because it is improved in linearity and in the output current efficiency.

The circuit according to the present invention contributes to the improvement in characteristic, performance, accuracy and in output current efficiency. The circuit according to the present invention is simplified in the circuit configuration and small in circuit size and reduction in operation voltage and in current consumption can be achieved.

Although the present invention has so far been described with reference to preferred examples, the present invention is not to be restricted to the examples. It is to be appreciated that those skilled in the art can change or modify the examples without departing from the scope and spirit of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A differential circuit comprising:
a first transistor pair including first and second transistors having gates for receiving a differential input signal;
a third transistor having a gate for receiving a common mode voltage of the differential input signal, said third transistor being connected to a first constant current source as a load;
an inverting amplifier that receives an output signal of the third transistor; and
a second transistor pair including forth and fifth transistors having gates for commonly receiving an output signal of said inverting amplifier and having drains coupled with drains of said first and second transistors, respectively;
wherein coupled drains of said first and fourth transistors and coupled drains of said second and fifth transistors constitute a differential output pair; and
sources of said first to fifth transistors are coupled together and driven by a second constant current source.

2. The differential circuit according to claim 1, wherein the inverting amplifier includes:
a sixth transistor and
a third constant current source connected to said sixth transistor as a load.

3. A differential circuit comprising:
a first transistor pair including first and second transistors having gates for receiving a differential input signal;
a second transistor pair including third and fourth transistors having gates for receiving the differential input signal and having drains connected to drains of said first and second transistors, respectively; and
a third transistor pair including fifth and sixth transistors having gates for receiving the differential input signal in reverse phase and cascode-connected to said third and fourth transistors, respectively;
wherein coupled drains of the first and third transistors and coupled drains of the second and fourth transistors constitute a differential output pair; and
sources of said first, second, fifth and sixth transistors are coupled together and driven by a constant current source.

4. A differential circuit comprising:
a first transistor pair including first and second transistors having gates for receiving a differential input signal;
a second transistor pair including third and fourth transistors having gates for receiving the differential input signal and having drains connected to drains of said first and second transistors, respectively;
a third transistor pair including fifth and sixth transistors having gates for receiving the differential input signal, having drains connected to drains of said second and first transistors, respectively, and having sources connected to sources of said third and fourth transistors, respectively; and
a fourth transistor pair including seventh and eighth transistors having gates for receiving the differential input signal in reverse phase, and cascode-connected to said fifth and sixth transistors, respectively;
wherein coupled drains of the first, third and sixth transistors and coupled drains of the second, fourth and fifth transistors constitute a differential output pair; and
sources of said first, second, seventh and eighth transistors are coupled together and driven by a constant current source.

5. A differential circuit comprising:
first and second input terminals for receiving a differential input signal;
first and second output terminals for outputting a differential output signal;
a constant current source;
a first transistor pair including first and second transistors having gates connected to the first and second input terminals, respectively, drains connected to the first and second output terminals, respectively, and sources coupled together and connected to the constant current source;
a bypass current distributor connected to the first and second output terminals; and
n stages of cascode transistor pairs cascode-connected between the bypass current distributor and the constant current source, said n being an integer greater or equal to 2; wherein n stages of cascode transistors on one side of said n stage cascode transistor pairs have respective gates connected alternately to said first and second input terminals, while n stages of cascode transistors on the other side of said n stage cascode transistor pairs have respective gates connected alternately to said second and first input terminals;
said bypass current distributor comprising a second transistor pair including third and fourth transistors having gates coupled together and connected to a third input terminal for receiving a common mode voltage of the differential input signal, drains connected to the first and second output terminals, respectively, and sources coupled together and connected to coupled drains of one transistor and the other transistor constituting the cascode transistor pair provided at the nth stage from the constant current source;
wherein said n stages of cascode transistor pairs are composed by 2 stages of cascode transistor pairs.

6. The differential circuit according to claim 5, wherein said bypass current distributor comprises:
a second transistor pair including third and fourth transistors having gates connected to the first and second input terminals, respectively, drains connected to the first and second output terminals, respectively, and sources connected to drains of one transistor and the other transistor constituting the cascode transistor pair provided at the nth stage from the constant current source, respectively; and
a third transistor pair including fifth and sixth transistors having gates connected to the first and second input terminals, respectively, drains connected to the second and first output terminals, respectively, and sources connected to drains of the one transistor and the other transistor constituting the cascode transistor pair provided at the nth stage from the constant current source, respectively;
wherein said n stages of cascode transistor pairs are composed by 2 stages of cascode transistor pairs.

7. The differential circuit according to claim 5, wherein said bypass current distributor comprises:
a second transistor pair including third and fourth transistors having gates connected to the first and second input terminals, respectively, drains connected to the first and second output terminals, respectively, and sources coupled together and connected to coupled drains of one transistor and the other transistor constituting the cascode transistor pair provided at the nth stage from the constant current source, respectively; and
a third transistor pair including fifth and sixth transistors having gates connected to the first and second input terminals, respectively, drains connected to the second and third output terminals, respectively, and sources coupled together and connected to the coupled drains of the one transistor and the other transistor constituting the cascode transistor pair provided at the nth stage from the constant current source;
wherein said n stages of cascode transistor pairs are composed by 2 stages of cascode transistor pairs.

8. The differential circuit according to claim 5, wherein said bypass current distributor comprises:
a second transistor pair including third and fourth transistors having gates coupled together and connected to a third input terminal for receiving a common mode voltage of the differential input signal, drains connected to the first and second output terminals, respectively, and sources coupled together and connected to coupled drains of one transistor and the other transistor constituting the cascode transistor pair provided at the nth stage from the constant current source;
wherein said n stages of cascode transistor pairs are composed by 3 stages of cascode transistor pairs.

9. The differential circuit according to claim 5, wherein said bypass current distributor comprises:
a second transistor pair including third and fourth transistors having gates connected to the first and second input terminals, respectively, drains connected to the first and second output terminals, respectively, and sources connected to drains of one transistor and the other transistor constituting the cascode transistor pair provided at the nth stage from the constant current source, respectively; and
a third transistor pair including fifth and sixth transistors having gates connected to the first and second input terminals, respectively, drains connected to the second and first output terminals, respectively, and sources connected to drains of the one transistor and the other transistor constituting the cascode transistor pair provided at the nth stage from the constant current source, respectively;
wherein said n stages of cascode transistor pairs are composed by 3 stages of cascode transistor pairs.

10. The differential circuit according to claim 5, wherein said bypass current distributor comprises:
a second transistor pair including third and fourth transistors having gates connected to the first and second input terminals, respectively, drains connected to the first and second output terminals, respectively, and sources coupled together and connected to coupled drains of one transistor and the other transistor constituting the cascode transistor pair provided at the nth stage from the constant current source, respectively; and
a third transistor pair including fifth and sixth transistors having gates connected to the first and second input terminals, respectively, drains connected to the second and third output terminals, respectively, and sources coupled together and connected to the coupled drains of one transistor and the other transistor constituting the cascode transistor pair provided at the nth stage from the constant current source;
wherein said n stages of cascode transistor pairs are composed by 3 stages of cascode transistor pairs.

11. The differential circuit according to claim 8, wherein relating said n stages of cascode transistor pairs, in case one of two neighboring transistor pairs cascode-connected upside down, respectively, receives the differential input signal, the other transistor pair receives the differential input signal in reverse phase, and
the coupled sources of said first transistor pair and the coupled sources of the cascode transistor pair located at the top among said plural cascode connected transistor pairs are connected, and the coupled sources are driven by a constant current source.

12. A differential circuit comprising:
a first transistor pair including first and second transistors having gates for receiving a differential input signal;
a second transistor pair including third and fourth transistors having gates for receiving the differential input signal and having drains connected to sources of first and second transistors, respectively; and
a third transistor pair including fifth and sixth transistors having gates for receiving the differential input signal in reverse phase and having drains connected to drains of said third and fourth transistors;
wherein sources of said third, fourth, fifth and sixth transistors are connected together and driven by a constant current source; and
the transistor size of the first and second transistors is thrice or four times as large as that of the third and fourth transistors.

13. The differential circuit according to claim 12, wherein the transistor size of the fifth and sixth transistors is smaller than that of the third and fourth transistors and being approximately 1 or ⅓ times the size of the third and fourth transistors.
